(19) United States
(12) Patent Application Publication
(10) Pub. No.: US 2009/0084500 A1
(43) Pub. Date: Apr. 2, 2009

(54) PROCESSING APPARATUS, EXHAUST PROCESSING PROCESS AND PLASMA PROCESSING PROCESS

(75) Inventors: Tadashi Sawayama, Kyoto (JP); Yasushi Fujioka, Kyoto (JP); Masahiro Kanai, Kyoto (JP); Shotaro Okabe, Nara-shi (JP); Yuzo Kohda, Kyoto (JP); Tadashi Hori, Nara-shi (JP); Koichiro Moriyama, Kyoto (JP); Hiroyuki Ozaki, Kyoto (JP); Yukito Aota, Yokohama-shi (JP); Atsushi Koike, Kawasaki-shi (JP); Mitsuyuki Niwa, Nara-shi (JP); Yasuyoshi Takai, Nara-shi (JP); Hidetoshi Tsuzuki, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/326,238

(22) Filed: Dec. 2, 2008

Related U.S. Application Data
(63) Continuation of application No. 11/776,265, filed on Jul. 11, 2007.
Application No. 11/776,265 is a division of application No. 10/776,173, filed on Feb. 12, 2004, now abandoned.
Application No. 10/776,173 is a division of application No. 09/294,367, filed on Apr. 20, 1999, now abandoned.

(30) Foreign Application Priority Data
Apr. 20, 1998 (JP) 10-108877
Apr. 19, 1999 (JP) 11-110239
Apr. 19, 1999 (JP) 11-110240
Apr. 19, 1999 (JP) 11-110241
Apr. 19, 1999 (JP) 11-110242
Apr. 19, 1999 (JP) 11-110283
Apr. 19, 1999 (JP) 11-110284
Apr. 19, 1999 (JP) 11-110285
Apr. 19, 1999 (JP) 11-110286

(51) Int. Cl. C23F 1/08; C23C 16/00; C23C 14/34

(52) U.S. Cl. 156/345.1; 118/715; 204/298.02

(57) ABSTRACT

There is disclosed an exhaust processing process of a processing apparatus for processing a substrate or a film, which comprises after the processing of the substrate or the film, introducing a non-reacted gas and/or a by-product into a trap means comprising a filament comprised of a high-melting metal material comprising as a main component at least one of tungsten, molybdenum and rhenium; and processing the non-reacted gas and/or the by-product inside the trap means. This makes it possible to prevent lowering in exhaust conductance, to lengthen the maintenance cycle of the processing apparatus, and to provide a high-quality product (processed substrate or film).

### BACKGROUND OF THE INVENTION

1. Field of the Invention

The present invention relates to a processing apparatus in a manufacture process of semiconductor elements or the like, such as a plasma CVD apparatus, thermal CVD apparatus, photo CVD apparatus, sputtering apparatus and another substrate processing apparatus for use in forming films, or a dry etching apparatus or another film processing apparatus for use in processing the films, particularly to a processing apparatus characterized by its exhaust processing means and an exhaust processing process therefor.

2. Related Background Art

A plasma CVD process, thermal CVD process, and photo CVD process are general processes as processes of forming amorphous semiconductor thin films or microcrystalline semiconductor thin films.

In the plasma CVD process, a source gas is introduced in a chamber, or pressure is reduced by an exhaust pump. A direct current power, or a high-frequency or microwave power is applied to ionize, dissociate and excite the source gas in plasma, so that a deposited film is formed on a substrate. In the conventional plasma CVD process, parallel plate electrodes are used, and a glow discharge or an RF discharge using high frequencies is employed. In addition to the discharge process using the parallel plate electrodes, a process of decomposing and depositing a compound gas by thermal energy has been used. Examples of the process using the thermal energy include Hot Wall process in which as a raw material Si₂H₆ or another gas relatively low in decomposition temperature is used and a deposited film forming chamber itself is heated to perform gas decomposition, a thermal CVD process of heating the substrate to obtain similar effects, further a hot wire CVD process in which tungsten filaments or other metal filaments heated to a melting point of a silicon crystal or a higher temperature are used to deposit thin films. Moreover, there is a photo CVD process in which ultraviolet rays or other rays are radiated to a substrate surface to decompose a source gas and form a deposited film.

In a dry etching process, after an amorphous semiconductor thin film, microcrystalline semiconductor thin film, insulator thin film, or another film is once formed, the film is processed to provide a desired pattern and film thickness. This is a general deposited film processing process.

When an amorphous silicon thin film or a microcrystalline semiconductor thin film is formed, SiH₄, Si₂H₆, SiF₄, Si₂F₆ or the like is used as source gas. Moreover, BF₃, B₂H₆, PH₃ or the like is used as doping gas. Furthermore, when a silicon germanium amorphous thin film or a microcrystalline thin film is formed, in addition to the above-mentioned gas, GeH₄ gas is often used as the source gas. In supplying direct-current and high-frequency powers a (plasma) pressure in the chamber is about 0.1 Torr to 10 Torr. In supplying the microwave power, the pressure is about 0.001 Torr to 1 Torr. Moreover, a substrate is heated to a temperature within the range of 200 to 400° C.

Here, FIG. 2 is a schematic sectional view showing a plasma CVD apparatus as one typical deposited film forming apparatus. A manufacture example of an amorphous silicon thin film by a general plasma CVD process using the apparatus will be described. In the drawing, numeral 1 denotes a deposited film forming chamber, 2 denotes an exhaust pump (rotary pump and mechanical booster pump), 3 denotes an exhaust piping, 4 denotes a valve, 5 denotes a conductance adjusting valve, 6 denotes a controller of the conductance adjusting valve, 7 denotes a cathode electrode, 8 denotes a high-frequency power supply, 9 denotes a matching unit, 10 denotes a high-frequency introducing section, 11 denotes a substrate holder, 12 denotes a substrate, 13 denotes a heater, 14 denotes a heater controller, 15 denotes a heater power supply, 16 denotes a gas cylinder, 17 denotes a gas flow rate controller, 18 denotes a gas introducing section, 19 denotes a pressure gauge, 20 denotes a discharge (plasma) region, and 21 denotes a trap.

The substrate 12 is fixed to the substrate holder 11, a substrate inlet/outlet (not shown) of the chamber 1 is closed, and air is exhausted by the exhaust pump 2 to reduce the pressure. The substrate 12 is heated to a temperature of a deposited film forming condition by the heater 13 fixed to the substrate holder 11. A plurality of deposited film forming source gases (SiH₄, Si₂H₆, H₂, doping gas) fed from the gas cylinders 16 are controlled in flow rate by the gas flow rate controller 17, and supplied in a mixed state into the discharge region 20 of the chamber 1 through the gas introducing section 18. A high frequency (13.56 MHz) is applied to the cathode electrode 7 from the high-frequency power supply 8, and the substrate 12 and substrate holder 11 opposite to the cathode electrode 7 are used as anode electrodes to cause discharge in the discharge region 20 between the electrodes. The discharge is adjusted by the matching unit 9. The gas in the chamber 1 is exhausted via the exhaust piping 3 by the exhaust pump 2, and constantly replaced with a newly supplied gas. The pressure of the discharge region 20 is monitored by the pressure gauge 19. The pressure signal is transmitted to the controller 6 of the conductance adjusting valve 5 provided in the exhaust piping 3, and the opening degree of the conductance adjusting valve 5 is adjusted, to keep constant the pressure of the discharge region 20. The deposited film forming source gas is dissociated, ionized, and excited in plasma in the discharge region 20 to form a deposited film on the substrate.

The conductance adjusting valve 5 is useful in obtaining a desired pressure irrespective of the flow rate of the source gas. The conductance adjusting valve 5 varies a sectional area of the exhaust piping 3 to increase/decrease an exhaust conductance.

After completing the formation of the deposited film, the supply of the source gas is stopped, a new purge gas (He, Ar or the like) is introduced, and the source gas remaining in the deposited film forming chamber 1 and exhaust pump 2 is sufficiently replaced. After the purging is completed, and the deposited film forming chamber 1 is cooled, an atmospheric pressure is returned, and the substrate 12 is removed.

Moreover, in the trap 21 disposed on the exhaust piping 3 leading to the exhaust pump 2 from the deposited film forming chamber 1, by a temperature drop, a by-product is deposited/agglomerated and removed. The term “by-product” used herein means powder which is generated in a plasma by discharge conditions (pressure, gas flow rate, power value) when a SiH₄ type source gas is used, and is stuck (or adheres) or deposited onto the electrodes, substrate holder, chamber wall, exhaust piping wall, and valve surface by a wall surface temperature. In a conventional process, the by-product is removed by depositing/aggregating it by a temperature drop at the trap 21. Moreover, in a process disclosed in Japanese Patent Application Laid-Open No. 8-218174, the trap is disposed on the exhaust piping, and a gap between the deposited film forming chamber and the trap is heated to prevent the by-product from sticking (or adhering) to the exhaust piping wall, so that the by-product is deposited/agglomerated in the trap. Furthermore, in a process disclosed in Japanese Patent Application Laid-Open No. 7-130674, opposite electrodes are disposed in the trap on the exhaust piping and a discharge is caused to deposit non-reacted gas and by-product as a hard film on a trap wall surface.

In the plasma CVD process, thermal CVD process, photo CVD process or another deposited film forming or substrate processing process, or a dry etching process or another film processing process (hereinafter generically referred to as the processing process as the case may be), the by-product is generated during processing and stuck/deposited onto portions other than a base (substrate). The influence of inclusion of the by-product in the film onto a film quality, and handling of the by-product adhering to the exhaust piping or the valve in apparatus maintenance have raised problems.

The by-product sticking into the chamber absorbs the gas, flies up in the chamber, is taken as dust or contaminant, for example, into the deposited film on the substrate, and may have adverse effects on properties of the deposited film.

Moreover, the by-product, when conveyed to the exhaust pump, remarkably increases a viscosity of rotary pump oil, and sticks to rotors of a mechanical booster pump, which places the rotors in contact with each other and causes operational defects. Moreover, as described above, the by-product sticking to the exhaust piping wall or the valve grows. As effective sectional areas of the exhaust piping and valve are gradually decreased, the exhaust conductance is gradually reduced. In some case, a desired discharge pressure (deposited film forming condition, deposited film processing condition) in the chamber cannot be obtained. Furthermore, there is a case where an operational defect of the conductance adjusting valve is caused.

In the apparatus of FIG. 2 described above, the by-product is deposited/agglomerated by cooling in the trap 21. In a known process of removing the by-product sticking to the trap, the trap is removed from the exhaust piping to directly remove the by-product. The operation requires a large number of processes and long time.

As the process of removing the by-product, a dry etching process is also known. The dry etching process includes a process of generating a discharge in the deposited film forming chamber to etch the by-product in the exhaust piping by radicals of long-life etching gas, and a process of generating the discharge in the exhaust piping to perform etching. To perform the etching, however, a corrosion resistance of a chamber member, exhaust piping material or pump needs to be considered. Moreover, an influence of contamination of the deposited film by the etching residues or the by-products needs to be considered. Furthermore, in a process, parallel plate electrodes are disposed in the trap, and a glow discharge or an RF discharge using high frequencies is used to decompose and deposit non-reacted compound gas in the trap. However, since the non-reacted compound gas is decomposed and deposited on the trap wall surface at a slow speed, the by-product is conveyed to the exhaust pump, which becomes a problem. Moreover, since the parallel plate electrodes are disposed inside the trap, some degree of space is necessary, and there is no degree of freedom in disposing the trap. Furthermore, in a process, a heating coil is disposed inside the trap, and the non-reacted gas is pyrolytically decomposed and deposited on the trap wall surface. However, since the non-reacted compound gas is decomposed and deposited on the trap wall surface at a slow speed, the by-product is conveyed to the exhaust pump, which becomes a problem. A heating temperature of the heating coil for use is usually about 400° C., and the by-product is stuck or deposited onto a heating coil surface dependent on the type of the introduced source gas, which causes a problem that an exhaust gas flow path is sometimes blocked.

At present the plasma CVD process or the like for preparing the semiconductor thin film has been developed for industrial application. However, since area enlargement and long-time film formation are increasingly requested for, an increase of accumulated by-products in an exhaust system is feared. In the above-mentioned conventional example, however, there is a case where the by-product is insufficiently removed.

An object of the present invention is to provide an exhaust processing process and a processing apparatus for processing a substrate or a film in which there is employed exhaust processing means small in size, easy in maintenance and able to sufficiently and efficiently remove a large amount of non-reacted gas or by-products generated when film formation or processing is performed in a large area, for a long time and at a high speed, so that adverse effects on a deposited film are eliminated.

### SUMMARY OF THE INVENTION

To solve the above-mentioned problems, according to a first aspect of the present invention, there is provided an apparatus for performing a plasma CVD process, thermal CVD process, photo CVD process, dry etching process or another substrate or film processing process, in which during processing of a substrate or a film, exhaust processing is constituted as follows:

Specifically, the present invention provides an exhaust processing process of a processing apparatus for processing a substrate or film, comprising the steps of: after processing a substrate or film, introducing a non-reacted gas and/or a by-product into a trap means having therein a filament comprising a high-melting metal material containing as a main component at least one of tungsten, molybdenum and rhenium; and processing the non-reacted gas and/or the by-product inside the trap means. Here, by setting the temperature of the filament preferably to 500° C. or more, more preferably to 1400° C. or more, the by-product and the like can be removed more effectively.

In the present invention, the configuration of the filament preferably comprises a single linear shape, a plurality of linear shapes, or a linear shape wound in spirals.

The present invention is preferably applied when the film is a thin film comprising a silicon-based amorphous or silicon-based microcrystalline material.

Moreover, the present invention is preferably applied when the non-reacted gas and/or the by-product mainly comprises silicon or a compound thereof.

In the apparatus of the present invention, for a preferable constitution, an inner wall surface of the trap on which the film is deposited by the exhaust processing is easily detached. For example, a double structure is preferably provided to facilitate the detachment.

According to a second aspect of the present invention, there is provided a processing apparatus having a processing space for processing a substrate or a film therein and an exhaust means for exhausting a gas from the processing space, comprising between the processing space and the exhaust means, means for causing a chemical reaction in a non-reacted gas and/or a by-product during processing of the substrate or the film, wherein the means comprises a heat generating member containing phosphorus (P) atoms.

The heat generating member containing phosphorus atoms preferably contains at least one of chromium (Cr), molybdenum (Mo), tungsten (W), vanadium (V), niobium (Nb), tantalum (Ta), titanium (Ti), zirconium (Zr) and hafnium (Hf).

The amount of phosphorus atoms contained in the heat generating member is preferably 0.1% or more in an atomic composition ratio relative to total atomic components constituting the heat generating member.

The apparatus of the present invention is preferably used in a temperature range in which the temperature of the heat generating member is 500° C. or higher.

The apparatus preferably comprises the means for causing the chemical reaction in an exhaust gas flow path in an exhaust pipe disposed between the processing space and the exhaust means.

According to a third aspect of the present invention, there is provided a processing apparatus having a processing space for processing a substrate or film therein and exhaust means for exhausting a gas from the processing space, comprising between the processing space and the exhaust means, means for causing a chemical reaction in a non-reacted gas and/or a by-product during processing of a substrate or film, wherein the means comprises a heat generating member containing silicon (Si) atoms.

The heat generating member containing the silicon atoms preferably contains at least one of chromium (Cr), molybdenum (Mo), tungsten (W), vanadium (V), niobium (Nb), tantalum (Ta), titanium (Ti), zirconium (Zr) and hafnium (Hf).

The amount of the silicon atoms contained in the heat generating member is preferably 0.1% or more in an atomic composition ratio relative to total atomic components constituting the heat generating member.

The apparatus of the present invention is preferably used in a temperature range in which the temperature of the heat generating member is 500° C. or higher.

The apparatus preferably comprises the means for causing the chemical reaction in an exhaust gas flow path in an exhaust pipe disposed between the processing space and the exhaust means.

According to a fourth aspect of the present invention, there is provided a processing apparatus comprising a chemical reaction causing means provided in an exhaust path connecting a processing chamber for processing a processing object therein and an exhaust means for exhausting a gas from the processing chamber, for causing a chemical reaction in a non-reacted gas and a by-product exhausted from the processing chamber, and a recovering means provided within a distance of 5 cm from the chemical reaction causing means, for recovering a chemical reaction product generated by the chemical reaction causing means.

The recovering means of the chemical reaction product generated by the chemical reaction causing means of the present invention preferably also serves as a wall surface of the exhaust path, and may comprise a louver or the like.

The chemical reaction causing means of the present invention is, for example, a high-melting metal filament.

Moreover, it is preferred that the high-melting metal filament of the present invention comprises at least one of tungsten, molybdenum and rhenium. For example, it is possible to use a simple substance of these metals or an alloy thereof, or a modified alloy containing an additive, or a modified metal, or the like.

Here, the non-reacted gas and by-product fine powder contained in an exhaust gas exhausted from the processing chamber are passed through the exhaust path comprising the chemical reaction causing means constituted as described above, and the chemical reaction is caused in the non-reacted gas and by-product fine powder exhausted from the processing chamber by the chemical reaction causing means to collect a deposited film on a wall surface of the exhaust path.

According to a fifth aspect of the present invention, there is provided a process of processing an exhaust gas exhausted from a processing space for processing a substrate or a film therein, which comprises exhausting the exhaust gas so as to be in contact with a heat generating member provided in an outlet of the processing space and controlled so as to have a current density within the range of 5 to 500 A/mm², whereby a chemical reaction is caused in a non-reacted gas and a by-product contained in the exhaust gas.

Here, a current within the range of 20 to 150 A/mm² is preferably applied to the heat generating member to cause the chemical reaction in the non-reacted gas and fine powder, which are collected as a film.

Moreover, when power supply to the heat generating member is started or stopped, the current density is preferably raised or lowered gradually to prevent the heat generating member from being broken and to lengthen the service life of the heat generating member.

Furthermore, a plurality of heat generating members are preferably used, and at least one heat generating member is preferably used so as to have a difference of 10 A/mm² or more in current density distribution from the other heat generating members to thereby control the chemical reaction.

Additionally, in the power supply to the heat generating member, there is preferably provided a function of controlling a predetermined current density to be constant, so that the chemical reaction is stabilized and the service life of the heat generating member is extended.

It is preferred that the heat generating member comprises at least one of tungsten, molybdenum and rhenium. For example, it is possible to use a simple substance of these metals or an alloy thereof, or a modified alloy containing an additive, or a modified metal, or the like.

According to a sixth aspect of the present invention, there is provided a processing apparatus having a processing chamber and an exhaust means for exhausting a gas from the processing chamber, comprising a region with a different mean velocity of the gas from that of the processing chamber provided in an exhaust path connecting the processing chamber and the exhaust means, and a chemical reaction causing means provided in the region, for causing a chemical reaction in a non-reacted gas and/or a by-product exhausted from the processing chamber. The chemical reaction causing means preferably comprises a heated high-melting metal filament. Moreover, the material of the high-melting metal filament is preferably a metal or an alloy comprising as a main component at least one of tungsten, molybdenum and rhenium.

According to a seventh aspect of the present invention, there is provided a plasma processing process which uses a plasma processing apparatus having a processing chamber for plasma-processing a substrate or a film and an exhaust means for exhausting a gas from the processing chamber, the process comprising using a chemical reaction causing means provided in an exhaust piping connecting the processing chamber and the exhaust means, for causing a chemical reaction in a non-reacted gas and/or a by-product exhausted from the processing chamber, wherein the emission intensity of a plasma on the side of the exhaust means of the chemical reaction causing means is smaller than the emission intensity of a plasma on the side of the processing chamber.

The chemical reaction causing means is preferably disposed adjacent the processing chamber at a downstream side thereof, so that the atmosphere gas in the processing chamber is introduced into the chemical reaction causing means while a plasma state is kept. Moreover, extension of the plasma to the side of the exhaust means from the processing chamber is preferably attenuated or inhibited by the chemical reaction causing means. Furthermore, the chemical reaction causing means preferably comprises at least one of a reaction means by a catalyst, a reaction means by a heated catalyst, and a reaction means by a heat generating member. Additionally, the non-reacted gas and/or the by-product exhausted from the processing chamber preferably contains silicon. Moreover, the plasma processing preferably comprises at least one of film deposition, doping, etching, and H₂ plasma processing.

According to an eighth aspect of the present invention, there is provided a processing apparatus having a processing space and an exhaust means for exhausting a gas from the processing space, comprising a chemical reaction causing means provided in an exhaust path connecting the processing chamber and the exhaust means, for causing a chemical reaction in a non-reacted gas and/or a by-product during processing, and a cooling means provided on the side of the exhaust means of the chemical reaction causing means.

Here, the cooling means preferably uses a liquid or gas as a cooling medium.

There is preferably provided a heat insulating means between the chemical reaction causing means for causing the chemical reaction in the non-reacted gas and/or the by-product during the processing and the processing space.

An heat insulating means is preferably provided between the means for causing the chemical reaction in the non-reacted gas and/or the by-product during the processing and a processing object.

There is preferably provided means for controlling the temperature of a member forming the processing space to be constant.

An heat insulating means is preferably provided adjacent the chemical reaction causing means for causing the chemical reaction in the non-reacted gas and/or the by-product during the processing, on the side of the exhaust means thereof.

The means for causing the chemical reaction in the non-reacted gas and/or the by-product during the processing preferably comprises passing the non-reacted gas and/or the by-product through a flow path in which a catalyst acting on the non-reacted gas and/or the by-product is disposed, or passing the non-reacted gas and/or the by-product through a flow path in which a heat generating member is disposed.

The non-reacted gas and/or the by-product preferably comprises silicon.

According to a ninth aspect of the present invention, there is provided a processing apparatus having a processing space and an exhaust means for exhausting a gas from the processing space, comprising a chemical reaction causing means disposed at least in an exhaust path between the processing space in a chamber having the processing space and the exhaust means, for causing a chemical reaction in a non-reacted gas and/or a by-product during processing, and a cooling means provided in at least a part of the exhaust path between the processing space and the exhaust means.

### BRIEF DESCRIPTION OF THE DRAWINGS

FIG. 1 is a schematic sectional view of an embodiment of a plasma CVD apparatus of the present invention;

FIG. 2 is a schematic sectional view of an example of a conventional high-frequency plasma CVD apparatus;

FIG. 3 is a partially cut-away perspective view showing an embodiment of a high-melting metal filament according to the present invention;

FIG. 4 is a partially cut-away perspective view showing a double structure of an embodiment of a trap according to the present invention;

FIG. 5 is a schematic sectional view showing another embodiment of the plasma CVD apparatus of the present invention;

FIG. 6 is a schematic partially sectional view showing further embodiment of the plasma CVD apparatus of the present invention;

FIG. 7 is a schematic sectional view showing an embodiment of a thermal CVD apparatus of the present invention;

FIG. 8 is a schematic sectional view showing an embodiment of a photo CVD apparatus of the present invention;

FIG. 9 is a schematic sectional view showing an example of a structure of a deposited film processing apparatus of the present invention;

FIGS. 10A, 10B, 10C and 10D are schematic perspective views showing examples of heat generating member structures of the present invention;

FIG. 11 is a schematic sectional view showing an embodiment of the plasma CVD apparatus of the present invention;

FIG. 12 is a schematic sectional view showing an embodiment of an exhaust duct as a part of the exhaust means of the present invention;

FIG. 13 is a schematic perspective view showing an embodiment of the high-melting metal filament of the present invention;

FIG. 14 is a schematic sectional view showing another embodiment of the exhaust duct as a part of the exhaust means of the present invention;

FIG. 15 is a circuit diagram showing an embodiment of a power application circuit structure of the heat generating member;

FIG. 16 is a circuit diagram showing an embodiment of a circuit structure for controlling the current density of the heat generating member of the present invention;

FIG. 17 is a schematic sectional view showing an example of a deposited film forming apparatus of the present invention;

FIG. 18 is an enlarged schematic sectional view of a trap (type A) used in an apparatus of Examples 26 and 27 of the present invention;

FIG. 19 is an enlarged schematic sectional view of a trap (type B) used in an apparatus of Comparative Example 1 of the present invention;

FIG. 20 is a graph showing a change in opening percentage of a conductance adjusting valve in Example 26 and Comparative Example 1 of the present invention;

FIG. 21 is a schematic sectional view of a deposited film forming apparatus used in Example 27 of the present invention;

FIG. 22 is a schematic sectional view of a deposited film forming apparatus used in Example 28 of the present invention;

FIG. 23 is a schematic sectional view of a deposited film forming apparatus used in Example 29 of the present invention;

FIG. 24 is a schematic sectional view showing an embodiment of a plasma processing apparatus of the present invention;

FIG. 25 is a schematic sectional view showing another example of the plasma processing apparatus;

FIG. 26 is a graph showing a location-dependence of a plasma emission intensity according to Examples 30 and 31;

FIG. 27 is a graph showing the location-dependence of the plasma emission intensity according to Examples 30 and 32;

FIG. 28 is a graph showing the location-dependence of the plasma emission intensity according to Examples 33 and 34;

FIG. 29 is a graph showing a change of the opening percentage of the conductance adjusting valve by the number of film forming times;

FIG. 30 is a schematic sectional view showing an example of the processing apparatus of the present invention;

FIGS. 31 and 32 are enlarged sectional views showing examples of the processing apparatus of the present invention; and

FIGS. 33 and 34 are schematic sectional views showing other examples of the processing apparatus of the present invention.

### DETAILED DESCRIPTION OF THE PREFERRED EMBODIMENTS

In a process of heating a filament and thermally decomposing a reaction gas, powder and the like by thermal energy to deposit a film, in accordance with a process of forming a deposited film, processing process or conditions, and a filament material, an optimum filament heating temperature needs to be selected. When as the filament (high-melting metal filament) material a high-melting metal containing as a main component at least one of tungsten, molybdenum and rhenium or an alloy thereof is used, under forming conditions or processing conditions such that a relatively small amount of a by-product is generated, an effect is exhibited from a filament temperature of about 500° C., so that a non-reacted gas and a by-product are efficiently decomposed and can be deposited as a hard film on a trap wall surface. Furthermore, under more drastic forming conditions with a higher deposition rate of the deposited film, when the temperature of the high-melting metal filament is set to a higher temperature of 1400° C. or more, the non-reacted gas and by-product are efficiently decomposed and can be deposited as the hard film on the trap wall surface. Furthermore, by performing heating to the melting point of the simple substance of a substance of the reaction gas or a higher temperature, the powder of the by-product can also be decomposed, a high deposition rate can easily be obtained in a trap, and the non-reacted gas and by-product can efficiently be decomposed and deposited as the hard film on the trap wall surface.

In the present invention, power is supplied to the high-melting metal filament to be heated. The filament is formed of the high-melting metal. Therefore, when the processing process by a substrate processing apparatus or a film processing apparatus is continued for several hours to several dozens of hours, operation needs to be performed at a melting point of each material used in the filament or a lower temperature so that the material of the filament is prevented from being evaporated by the heating of the filament. Specifically, the melting point of tungsten is 3410° C., the melting point of molybdenum is 2620° C., and the melting point of rhenium is 3180° C.

In the present invention the heating temperature of the high-melting metal filament depends on the material thereof and the type and flow rate of the non-reacted gas, but to use the filament stably for a long time, control is preferably performed at a temperature lower than the melting point by 100° C. or more. The heating temperature of the high-melting metal filament is preferably in the range of 500° C. to 2200° C., more preferably 1400° C. to 2200° C. If the filament temperature is excessively low, the decomposition rate of non-reacted gas and by-product is lowered. Moreover, if the filament temperature is excessively high, there is a possibility that a vacuum seal of the apparatus is influenced. Therefore, it is preferable to select an optimum temperature in accordance with the processing conditions.

In the present invention, the configuration of the high-melting metal filament preferably comprises a single or a plurality of linear shapes, or linear shapes wound in spirals. The degree of freedom in a place where the apparatus can be installed can be raised in accordance with the configuration for use. For example, when the filament of the single linear shape is used, the trap can easily be installed even in a narrow exhaust path. Moreover, when a contact area of the non-reacted gas and the by-product is to be enlarged, the linear shape wound in the spiral is used, or a plurality of linear shapes or the liner forms wound in spirals are preferably arranged in the direction of an exhaust flow.

For example, when silane (SiH₄), disilane (Si₂H₆) or another amorphous silicon forming source gas is used as a film forming source gas, in the conventional process, the by-product sticking to an exhaust piping needs to be periodically removed, but the operation of removing the by-product after film formation requires a large number of processes and much time. In the present invention, since the powder of the by-product is decomposed and deposited as a stable film, it can safely and easily be removed.

In the present invention, to remove the film deposited on an inner wall of the trap, after the deposited film formation or another substrate processing or the film processing is completed, nitrogen (N₂), helium (He) or another inert gas is flown to purge the source gas. After the gas is leaked to an atmospheric pressure, the trap inner wall is taken out to remove the film by a physical process (honing or the like) or a chemical process (etching or the like). In this case, when the trap wall is of a double structure, and only the inner wall is detachably provided, the inner wall can easily be removed. Moreover, when the inner wall surface is formed of a metal, the deposited film can easily be removed, and time required for maintenance can be shortened. As the metal material, stainless steel, aluminum or another metal, or an alloy containing any one of the metals can preferably be used.

Examples of the source gas for use in a deposited film forming apparatus as an embodiment of the substrate processing apparatus include silane (SiH₄), disilane (Si₂H₆) and another amorphous silicon forming source gas, germane (GeH₄) and another source gas, and a mixture gas thereof.

Moreover, examples of a diluting gas of the source gas include H₂, Ar, He and the like.

Furthermore, for the purpose of doping, diborane (B₂H₆), boron fluoride (BF₃), phosphine (PH₃) or another dopant gas may simultaneously be introduced into a discharge space (film forming space).

Additionally, examples of an etching gas for use in an etching apparatus as an embodiment of the film processing apparatus of the present invention include CF₄O₂, CHₓF₍₄₋ₓ₎, SiHₓF₍₄₋ₓ₎, SiHₓCl₍₄₋ₓ₎, CHₓCl₍₄₋ₓ₎ (in which x=0, 1, 2, 3, or 4), ClF₃, NF₃, BrF₃, IF₃ and another etching gas and a mixture gas thereof.

As a base (substrate) material, for example, stainless steel, Al, Cr, Mo, Au, In, Nb, Te, V, Ti, Pt, Pd, Fe or another metal, alloy thereof, polycarbonate or another synthetic resin having a conductivized surface, glass, ceramic, paper or the like is used.

In the apparatus of the present invention, during the processing, the substrate temperature is not especially limited, preferably not lower than 20° C. but no higher than 500° C., more preferably in the range of 50° C. to 450° C.

A specific embodiment of the apparatus will next be described with reference to the drawings.

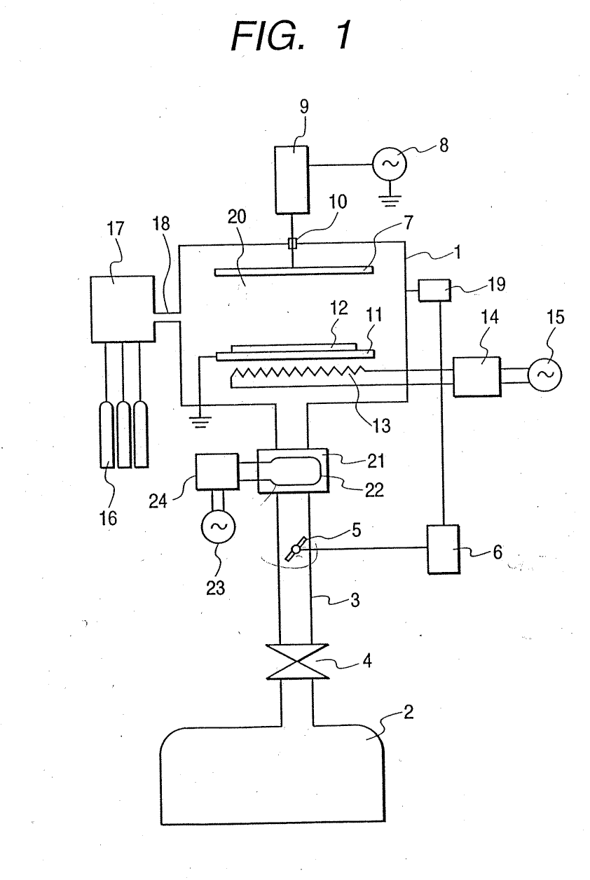

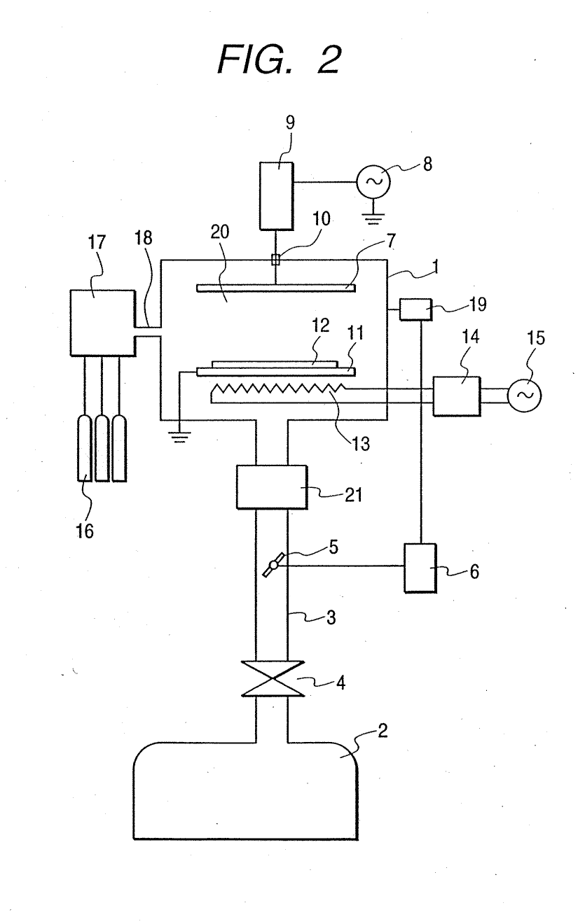

FIG. 1 is a schematic sectional view of an embodiment of a plasma CVD apparatus as one deposited film forming apparatus of the present invention. In the drawing, reference numerals 1 to 20 denote the same members as those of the above-mentioned apparatus of FIG. 2, and description thereof is omitted. Moreover, numeral 21 denotes a trap of the present invention, 22 denotes a high-melting metal filament, 23 denotes a filament power supply, and 24 denotes a controller.

In the embodiment, a non-reacted gas and a CVD by-product generated while the deposited film is formed are removed as follows:

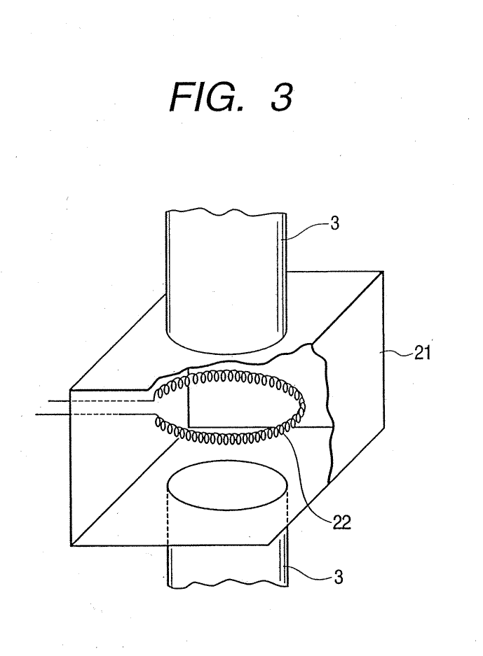

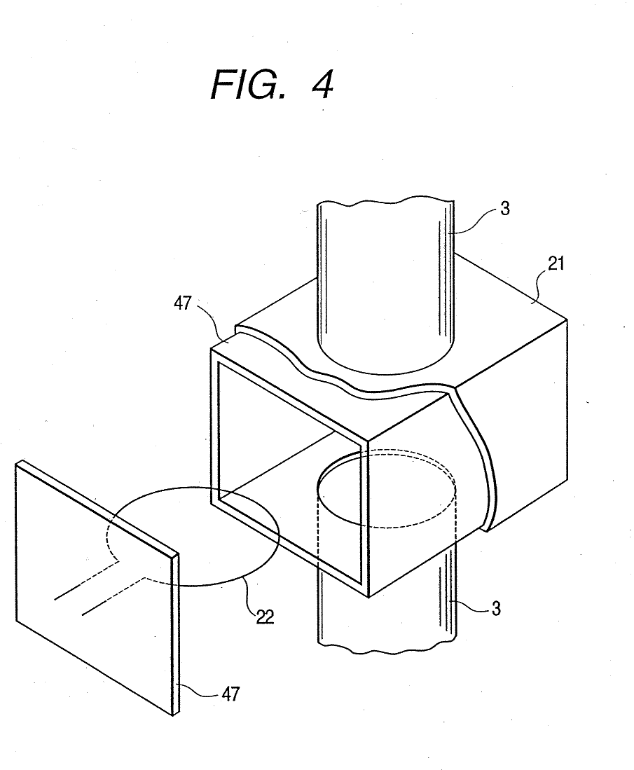

First in the same manner as the procedure described for the apparatus of FIG. 2, the deposited film is formed on the substrate 12 by plasma CVD in the deposited film forming chamber 1. Before plasma is generated in the deposited film forming chamber 1, power is supplied to the high-melting metal filament 22 having a circular arc shape from the filament power supply 23 via the controller 24, so that heating is performed to a desired temperature. Since air is exhausted from the deposited film forming chamber 1 to a desired pressure by the exhaust piping 3 and the exhaust pump 2, the non-reacted gas and by-product in the deposited film forming chamber 1 reach the trap 21 disposed in the exhaust path, decomposed by thermal energy of the high-melting metal filament 22, and deposited as a hard film on an inner wall of the trap 21. FIG. 3 is a partially cut perspective view showing another embodiment of the high-melting metal filament, in which the filament of a linear shape is formed into a spiral form. Moreover, FIG. 4 is a partially cut exploded perspective view showing another embodiment of the trap, in which a wall surface is of a double structure and an inner wall is detachably provided. Reference numeral 47 denotes a metal plate, which forms inner wall surfaces.

While the deposited film is formed using the apparatus of the embodiment of FIG. 1, the non-reacted gas and by-product are decomposed and deposited as the hard film on the inner wall of the trap. Results are shown in Table 1.

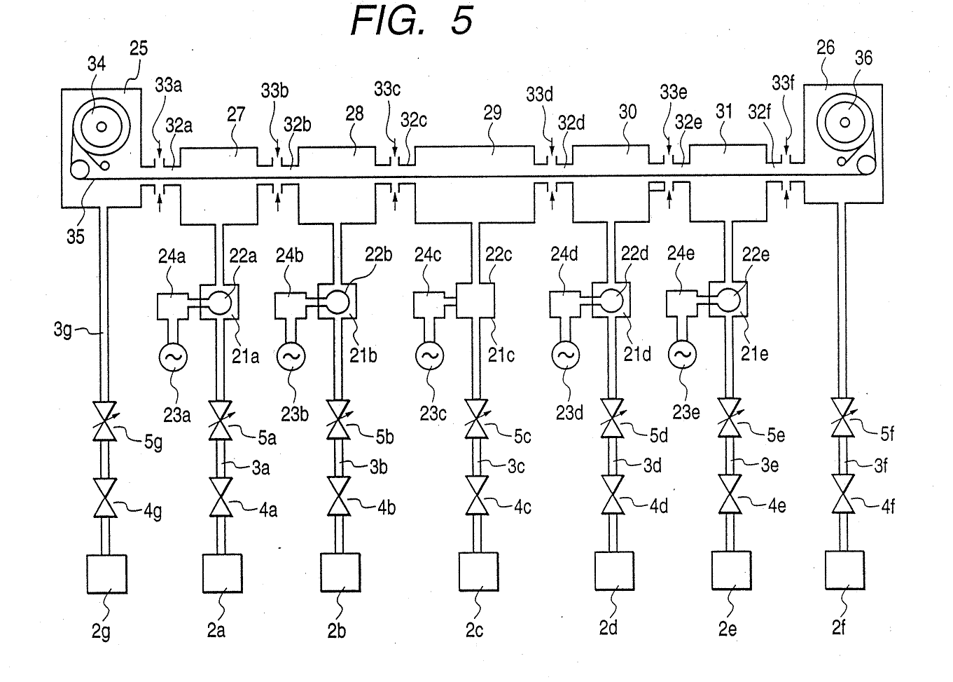

FIG. 5 shows another embodiment of the present invention. In the embodiment, the present invention is applied to a deposited film forming apparatus using a roll to roll system where film forming chambers are arranged via gas gates. In the roll to roll system, a longitudinal belt-like substrate is used. While the substrate is continuously fed and supplied to a plurality of deposited film forming chambers, the deposited film is successively stacked and wound up.

Each member of the apparatus of FIG. 5 will be described. Between a feed chamber 25 for continuously feeding a belt-like substrate 35 wound on a bobbin 34 therein and a wind-up chamber 26 for winding the belt-like substrate 35 with the deposited film formed thereon onto a bobbin 36, a plurality of deposited film forming chambers 27 to 31 are arranged along a straight line. Adjacent chambers are connected via gas gates 32a to 32f. Each of the chambers 27 to 31 is provided with a discharge power supply mechanism and a source gas supply mechanism, which are not shown. A gate gas is introduced to the gas gates 32a to 32f from gate gas introducing means 33a to 33f, so that interdiffusion between the adjacent deposited film forming chambers is prevented to maintain independence of the deposited film forming conditions. Moreover, each of the chambers 25 to 31 has an independent exhaust mechanism. Conductance adjusting valves 5a to 5g provided in exhaust pipings 3a to 3g function to control the pressure of each deposited film forming chamber. By adjusting the conductance adjusting valves 5a to 5g, the pressure of each deposited film forming chamber can independently be controlled.

In the embodiment, traps 21a to 21e are arranged in the exhaust pipings 3a to 3e between the chambers 27 to 31 and exhaust pumps 2a to 2e. Inside the traps, high-melting metal filaments 22a to 22e are provided in circular arc forms. The high-melting metal filaments 22a to 22e are connected to power supplies 23a to 23e via controllers 24a to 24e, and supplied with power. Reference numerals 4a to 4g are valves.

A deposited film forming procedure will be described by illustrating a case in which an nip type amorphous semiconductor layer of a photovoltaic element.

The longitudinal belt-like substrate 35 of stainless steel on which a back surface light reflecting layer is formed beforehand and which is wound around the bobbin is mounted in the feed chamber 25. The belt-like substrate 35 is passed through the deposited film forming chambers 27 to 31 and the gas gates 32a to 32f from the feed chamber 25, fixed to the bobbin 36 of the wind-up chamber 26, and extended with a tension.

Subsequently, air is exhausted from each chamber by the exhaust means provided on each chamber to reduce the pressure to the order of 10⁻³ Torr. The deposited film forming chambers 27 to 31 are once placed in inert gas atmosphere, and discharge furnaces of the chambers 27 to 31 are heated to the deposited film forming conditions. After the furnaces are sufficiently heated, in order to maintain the independence of the deposited film forming conditions of the deposited film forming chambers 27 to 31, hydrogen gas as a gate gas is introduced to the gas gates 32a to 32f via the gate gas introducing means 33a to 33f. A deposited film forming source gas is introduced to the deposited film forming chambers 27 to 31 by gas supply means.

While the pressure in the chambers 27 to 31 is controlled to be constant by the conductance adjusting valves 5a to Se, an RF power or a microwave power is supplied to discharge regions in the deposited film forming chambers 27 to 31. The discharge is caused and maintained, and the deposited film forming source gas is decomposed to form a deposited film on the belt-like substrate 35 which is continuously moved/supplied.

On the belt-like substrate 35 continuously supplied from the feed chamber 25 at a constant speed and moved through the deposited film forming chambers 27 to 31, different deposited films are formed in succession. Specifically, an n-type semiconductor layer, i-type semiconductor (buffer) layer, i-type semiconductor layer, i-type semiconductor (buffer) layer, and p-type semiconductor layer are stacked and formed. Finally, the substrate is wound onto the bobbin 36 of the wind-up chamber 26. After the deposited films are completely formed on the belt-like substrate 35, an inert gas is passed through the chambers 25 to 31, exhaust pipings 3a to 3g and exhaust pumps 2a to 2g to sufficiently purge residual source gas, so that the chambers 25 to 31 are returned to the atmospheric pressure. The belt-like substrate 35 removed from the wind-up chamber 26 is further subjected to an upper electrode and module formation process to be formed into the photovoltaic element.

The removal of the non-reacted gas and/or the by-product generated during the deposited film formation is performed by the traps 21a to 21e attached to the chambers 27 to 31. The procedure is the same as in the apparatus of FIG. 1. Before starting the discharge in the discharge regions of the deposited film forming chambers 27 to 31, the power is supplied to heat the high-melting metal filaments 22a to 22e inside the traps 21a to 21e. Since air is exhausted from the deposited film forming chambers 27 to 31 by the exhaust pipings 3a to 3e and exhaust pumps 2a to 2e to provide a desired pressure, the non-reacted gas and CVD by-product in the deposited film forming chambers 27 to 31 reach the traps 21a to 21e provided in the exhaust path, are decomposed by the thermal energy of each high-melting metal filament, and deposited as hard films on inner walls of the traps 21a to 21e.

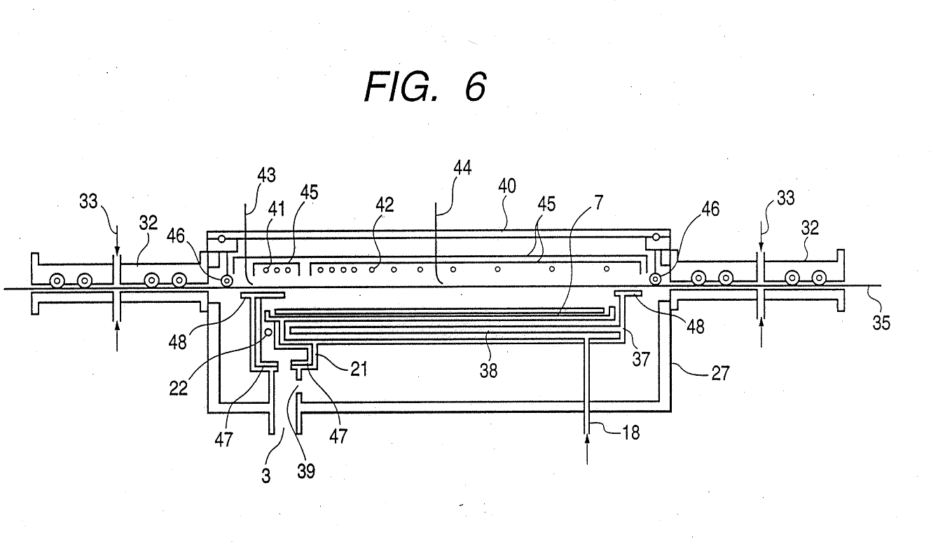

FIG. 6 shows a further embodiment of the present invention. FIG. 6 is a schematic partial sectional view of a high-frequency plasma CVD apparatus.

The embodiment is different in the above embodiment of FIG. 5, in that the trap is disposed between a deposited film forming space and the exhaust piping inside each deposited film forming chamber.

In the apparatus of FIG. 6, a deposited film forming space 37 is provided in the deposited film forming chamber 27. By supplying a high-frequency power between the electrically grounded belt-like substrate 35 and the cathode electrode 7 from a high-frequency power supply (not shown), plasma is formed in the deposited film forming space 37 to form a deposited film on a lower face (surface) of the belt-like substrate 35. The deposited film forming space 37 is provided with a source gas introducing section 18 connected to a source gas supply system (not shown) and the exhaust piping 3 connected to an exhaust apparatus (not shown) to form a gas flow in parallel with the direction in which the belt-like substrate 35 moves.

In a flow path of source gas, a block heater 38 is provided for preheating the source gas before plasma decomposition and heating the deposited film forming space 37 to promote the decomposition of the source gas in the vicinity of a venting section and to reduce the amount of CVD by-products sticking to an inner wall of the deposited film forming space 37. In an exhaust gas path, a deposited film forming space outer exhaust vent 39 is provided for exhausting outer gas (gate gas flowing from the gas gate 32 via a gate gas introducing means 33, gas discharged from the inner wall of the deposited film forming chamber 27 and the like) of the deposited film forming space 37 to the exhaust piping 3 without passing the gas through the deposited film forming space 37, so that impurities are prevented from being included into the deposited film.

Moreover, above the deposited film forming space 37, in an inlet and outlet and at opposite ends in a width direction of the belt-like substrate 35, plasma leak guards 48 are disposed for inhibiting the plasma in the deposited film forming chamber 27 from leaking to the outside.

On an upper face (back surface) of the belt-like substrate 35 in the deposited film forming chamber 27, lamp heaters 41, 42 are fixed to an openable/closable lid 40 of the deposited film forming chamber 27, so that the belt-like substrate 35 is heated to a predetermined temperature from its back surface by thermocouples 43, 44 with their faces abutting on the back surface of the belt-like substrate while the temperature is monitored. The belt-like substrate 35 has its temperature lowered before passing through the gas gate 32, and is heated to the predetermined temperature suitable for the film formation by the lamp heater 41 disposed before the deposited film forming space 37, before reaching the deposited film forming space 37. The lamp heater 42 disposed on the deposited film forming space 37 maintains the temperature to provide a constant temperature during the deposited film formation. Moreover, the lamp heaters 41, 42 are provided with reflectors 45 of a double structure, so that light radiated from the lamp is collected onto the belt-like substrate 35 to increase heating efficiency and to prevent the lid 40 of the deposited film forming chamber 27 from being heated.

In the vicinity of the inlet and outlet in the deposited film forming chamber 27, support rollers 46 are attached for rotatably supporting the back surface of the belt-like substrate 35, so that the belt-like substrate 35 is linearly extended in the deposited film forming chamber 27 and supported from the back surface with an interval from the cathode electrode 7 kept constant. Furthermore, inside the support rollers 46, permanent magnets (not shown) having a high Curie point are provided for generating magnetic forces to a degree to which the plasma is not influenced. When the belt-like substrate formed of ferrite stainless steel or another magnetic material is used, the support rollers 46 closely abut on the belt-like substrate 35.

In the embodiment, the trap 21 is disposed between the deposited film forming space 37 and the exhaust piping 3. Inside the trap 21, the high-melting metal filament 22 is disposed like a straight line, and connected to a power supply (not shown) via a controller (not shown), so that power is supplied. Moreover, an inner wall surface of the trap 21 is of a double structure, and has a metal plate 47 attached thereto.

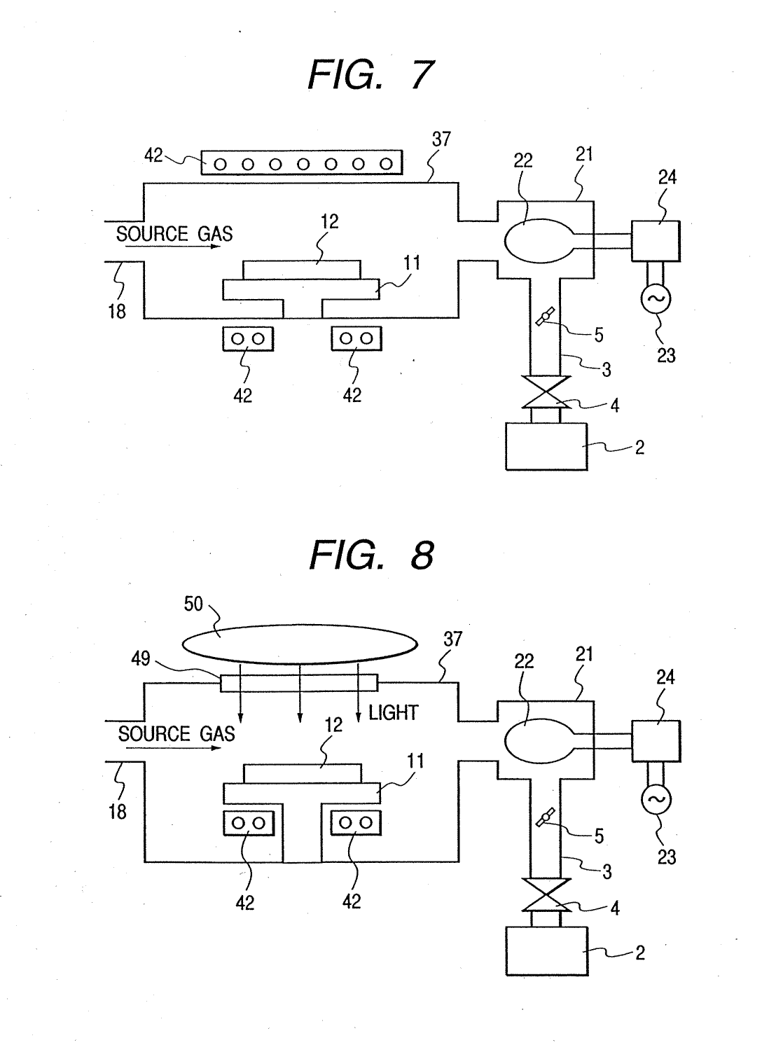

FIG. 7 shows a still further embodiment of the present invention. FIG. 7 is a schematic sectional view of a thermal CVD apparatus.

In FIG. 7, a wafer substrate 12 fixed to a substrate holder 11 is installed in a deposited film forming space 37 defined by quartz, whose pressure can be reduced by an exhaust pump 2. Outside and close to the deposited film forming space 37, halogen lamp haters 42 are vertically opposed to each other via the wafer substrate 12. After the pressure of the deposited film forming space 37 is reduced to a desired pressure by the exhaust pump 2, the wafer substrate 12 is heated to a desired temperature by the halogen lamp heaters 42. Subsequently, SiH₄, Si₂H₆ or another source gas is introduced from a gas introducing section 18, and excited and decomposed by heat of the substrate. After a gas phase reaction or a surface reaction on the substrate, a deposited film is formed on the substrate 12. A non-reacted gas and by-product are introduced to a trap 21 provided with a high-melting metal filament 22. The non-reacted gas and by-product are removed in the same manner as in the aforementioned embodiment.

FIG. 8 shows another embodiment of the present invention. FIG. 8 is a schematic sectional view of a photo CVD apparatus.

In the drawing, numeral 49 denotes a quartz window, and 50 denotes a light source. Outside and close to a deposited film forming space 37, a mercury lamp or another light source 50 is provided. The quartz window 49 is disposed so that ultraviolet rays emitted from the light source are radiated on a substrate 12 arranged in the deposited film forming space 37. After the pressure of the deposited film forming space 37 is reduced to a desired pressure, the substrate 12 is heated to a desired temperature by the heater 42. Subsequently, N₂O (nitrous oxide), Si₂H₆ or another source gas is introduced, while the ultraviolet rays emitted from the light source 50 are transmitted through the quartz window 49 and radiated onto the substrate 12. The source gas on the substrate 12 is excited and decomposed by the ultraviolet rays. After a gas phase reaction or a surface reaction on the substrate, a deposited film is formed on the substrate 12. A non-reacted gas and by-product are introduced to a trap 21 provided with a high-melting metal filament 22. The non-reacted gas and by-product are removed in the same manner as in the aforementioned embodiment.

A processing apparatus according to a second aspect of the present invention will be described hereinafter by way of specific examples, but the scope of the present invention is not limited to the following description.

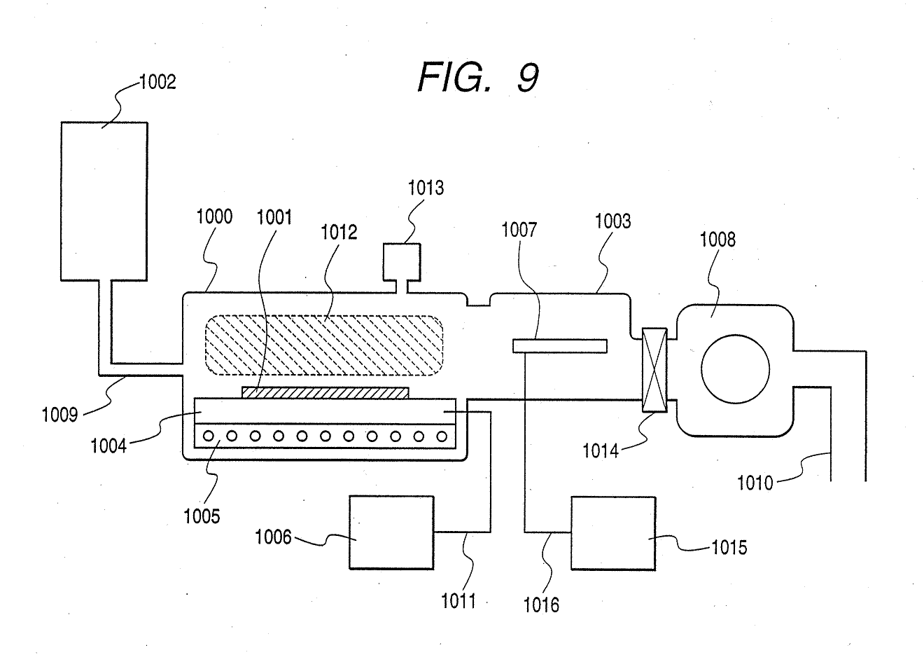

An example of CVD apparatus as the processing apparatus of the present invention will be described. For example, to form an amorphous silicon film, an amorphous silicon alloy film, or another non-monocrystalline semiconductor thin film, a plasma CVD process is used. In one example of the apparatus of the present invention or apparatus shown in FIG. 9, as a processing space, a reaction chamber 1000 formed of a stainless steel, quartz or the like is used. Via a gas mixing unit 1002 constituted of a mass flow controller or the like, a source gas formed by mixing silane gas (SiH₄) and hydrogen gas (H₂) at a desired ratio is introduced to the reaction chamber 1000 through a gas introducing pipe 1009. Thereafter, a high-frequency power as decomposition energy is applied to a cathode electrode 1004 from a high-frequency power supply 1006 via a high-frequency applying cable 1011 to generate a discharge in a processing space (discharge space) 1012, so that the source gas in the reaction chamber is decomposed, and a deposited film is formed on a desired processing substrate 1001 of stainless steel, glass or the like. A heater unit 1005 is provided on a back surface of the cathode electrode 1004, thereby heating the substrate 1001. Moreover, the pressure in the reaction chamber 1000 is monitored by a pressure gauge 1013. Residual gas not formed into the deposited film (non-reacted gas, by-product) is passed as an exhaust gas through an exhaust pipe 1003 and a conductance valve 1014, and exhausted to the outside of the reaction chamber via an exhaust gas piping 1010 by an exhaust pump unit 1008. In this case, inside the exhaust pump 1003, to cause a chemical reaction in the non-reacted gas or the by-product, there is provided a heating unit 1007 comprising phosphorus (P) atoms. The heating unit 1007 is connected to AC power supply 1015 via AC applying cable 1016. The main component of the heat generating member is preferably at least one selected from the so-called high-melting metals consisting of chromium (Cr), molybdenum (Mo), tungsten (W), vanadium (V), niobium (Nb), tantalum (Ta), titanium (Ti), zirconium (Zr), hafnium (Hf) and the like, to which main component are added phosphorus (P) atoms for use. The content of phosphorus atoms is preferably not less than 0.1% in an atomic composition ratio relative to total atomic components constituting the heat generating member.

An effect of adding phosphorus atoms to the main component will next be described. For example, when a pure metal is selected as the material of the heat generating member, and heated and continued to be used as the heat generating member, a thermal processing effect of the heat generating member itself is produced dependent on the type of the metal. As a result, there is a case where a crystal grain diameter or another inner structure of the metal is varied, a high-temperature strength is lowered, and the metal becomes very brittle. Especially, even when the source gas to be introduced to the processing space contains no oxygen (O) atom, in an ordinary vacuum processing apparatus, an apparatus maintenance is performed in an open atmosphere in many cases. In this case, moisture (H₂O) or oxygen (O) is adsorbed to a surface of a member constituting an inner wall of the processing space exposed to the atmosphere. Therefore, to start the processing after the maintenance, the processing space is evacuated to vacuum, then the wall surface member or the like is heated to perform baking, or high-purity gas containing no oxygen (O) atom is used to perform purging several times. Even in this case, there is a gas containing at least oxygen (O) atoms of the order of ppm or more inside the processing space. The present gas containing the oxygen (O) atoms easily reacts with high-melting metal atoms constituting the heat generating member heated to a high temperature to oxidize the high-melting metal atoms. As a result, there is a case where properties of the heat generating member material are changed, tenacity is lowered and the member becomes brittle. To solve the problem, when the heat generating member containing phosphorus (P) atoms is used, the oxygen (O) atoms easily combine with the phosphorus (P) atoms rather than with the high-melting metal atoms. As a result, the high-melting metal atoms constituting the heat generating member are largely inhibited from being oxidized. Therefore, the high-temperature strength of the main component (metal) can be maintained and, as a result, the function of the heat generating member can be maintained longer, so that the present invention is effective even when the formation of amorphous silicon films or another processing is continuously performed over a long time as much as several hundreds of hours. Moreover, it can be said that since a damage cycle of heat generating member can be lengthened, the frequency of maintenance is decreased, and an operating efficiency of deposition apparatus can be enhanced.

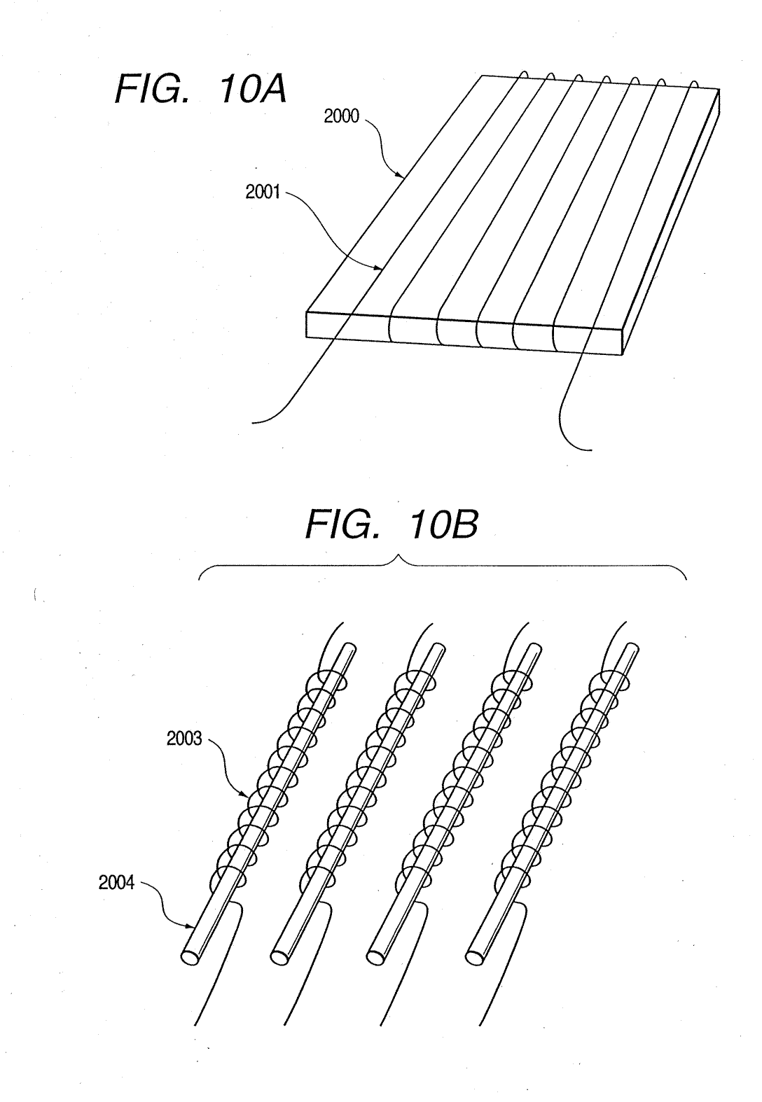

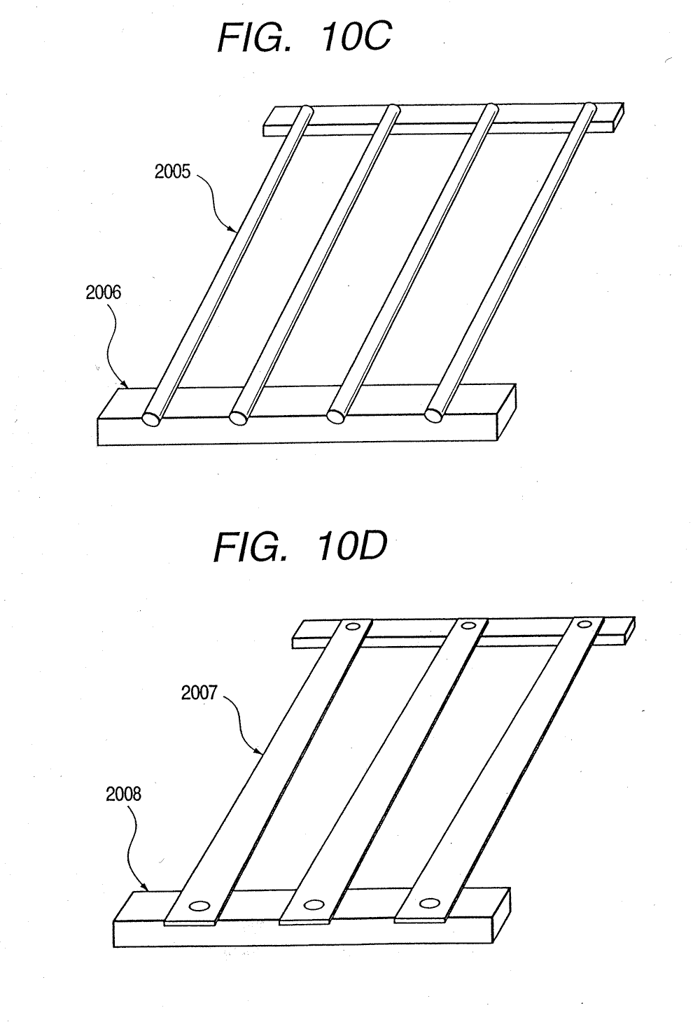

For a position (location) where the heat generating member is installed, a section in the exhaust pipe 1003 disposed between the reaction chamber 1000 as the processing space and the exhaust pump unit 1008 such as a rotary pump and the like, i.e., the inside of an exhaust gas flow path is preferable. For example, as shown in FIG. 10A, a wire-like heat generating member 2001 is wound around an insulating plate 2000 a plurality of times, and at least one heating unit can be installed inside the exhaust pipe. Here, AC power or another power is applied to opposite ends of the wire-like heat generating member 2001. If necessary, a voltage value of AC power may be adjusted by a voltage adjusting converter such as Slidac and the like. Moreover, as shown in FIG. 10B, the heat generating member is formed as a coil-like heat generating member 2003, and supported by an insulating rod member 2004 inserted through the heat generating member. At least one heat generating member is positioned across a gas flow direction inside the exhaust pipe, and AC power or the like may be applied to opposite ends of the coil-like heat generating member 2003 for use. Furthermore, as shown in FIG. 10C, at least one rod-like heat generating member 2005 is used, and separate conductive electrodes 2006 are provided on opposite ends of the rod-like heat generating member so as to connect the rod-like heat generating members in parallel. AC power or the like may be applied to the conductive electrodes on opposite ends for use. Additionally, as shown in FIG. 10D, at least one tape-like heat generating member 2007 is used, and separate conductive electrodes 2008 are provided on opposite ends of the tape-like heat generating member so as to connect the tape-like heat generating members in parallel. AC power or the like may be applied to the conductive electrodes on opposite ends for use. In any case, the heating unit is installed inside the exhaust pipe between the processing space and the exhaust means without obstructing the exhaust gas flow path. If such conditions are satisfied, the mode of installation is not limited.

In a method of heating the heat generating member, for the heat generating member of line, rod, coil or any other form, heat may be generated by applying AC power or DC power to opposite ends to pass an electric current through the heat generating member itself. If necessary, power may be applied via a temperature adjusting controller.

For the temperature of the heat generating member, for example, at the time of forming an amorphous silicon film, since the reaction for discharging a large amount of hydrogen (H) atoms contained in polysilane (SiₓH_{y}: x, y being integers) deposited in the exhaust pipe is promoted and, as a result, the film is changed to a silicon film piece, it is preferable to raise the temperature to 500° C. or more for use.

A processing apparatus according to a third aspect of the present invention will be described hereinafter by way of specific examples, but the scope of the present invention is not limited to the following description.

An example of CVD apparatus as the processing apparatus of the present invention will be described. For example, to form an amorphous silicon film, an amorphous silicon alloy film, or another non-monocrystalline semiconductor thin film, the plasma CVD process is used. In one example of the apparatus of the present invention or apparatus shown in FIG. 9, as the processing space, the reaction chamber 1000 formed of stainless steel, quartz or the like is used. Via the gas mixing unit 1002 constituted of the mass flow controller or the like, a source gas formed by mixing silane gas (SiH₄) and hydrogen gas (H₂) at the desired ratio is introduced to the reaction chamber 1000 through the gas introducing pipe 1009. Thereafter, the high-frequency power as decomposition energy is applied to the cathode electrode 1004 from the high-frequency power supply 1006 via the high-frequency applying cable 1011 to generate a discharge in the processing space (discharge space) 1012, so that the source gas in the reaction chamber is decomposed, and the deposited film is formed on the desired processing substrate 1001 of stainless steel, glass or the like. The heater unit 1005 is provided on a back surface of the cathode electrode 1004, thereby heating the substrate 1001. Moreover, the pressure in the reaction chamber 1000 is monitored by the pressure gauge 1013. Residual gas not formed into the deposited film (non-reacted gas, by-product) is passed as the exhaust gas through the exhaust pipe 1003 and the conductance valve 1014, and exhausted to the outside of the reaction chamber via the exhaust gas piping 1010 by the exhaust pump unit 1008. In this case, inside the exhaust pump 1003, to cause the chemical reaction in the non-reacted gas or the by-product, there is provided a heating unit 1007 comprising silicon (Si) atoms. The heating unit 1007 is connected to AC power supply 1015 via AC applying cable 1016. The main component of the heat generating member is preferably at least one selected from the so-called high-melting metals consisting of chromium (Cr), molybdenum (Mo), tungsten (W), vanadium (V), niobium (Nb), tantalum (Ta), titanium (Ti), zirconium (Zr), hafnium (Hf) and the like, to which main component are added silicon (Si) atoms for use. The content of silicon atoms is preferably not less than 0.1% in the atomic composition ratio relative to the total atomic components constituting the heat generating member.

An effect of adding silicon atoms to the main component will next be described. For example, when a pure metal is selected as the material of the heat generating member, and heated and continued to be used as the heat generating member, the thermal processing effect of the heat generating member itself is produced dependent on the type of the metal. As a result, there is a case where the crystal grain diameter or another inner structure of the metal is varied, the high-temperature strength is lowered, and the metal becomes very brittle. To solve the problem, when the heat generating member containing the silicon (Si) atoms is used, the high-temperature strength of the main component (metal) can be increased and, as a result, the function of the heat generating member can be maintained longer, so that the present invention is effective even when the formation of amorphous silicon films or another processing is continuously performed over a long time as much as several hundreds of hours. Moreover, it can be said that since the damage cycle of heat generating member can be lengthened, the frequency of maintenance is decreased, and the operating efficiency of deposition apparatus can be enhanced.

For the position (location) where the heat generating member is installed, a section in the exhaust pipe 1003 disposed between the reaction chamber 1000 as the processing space and the exhaust pump unit 1008 such as the rotary pump and the like, i.e., the inside of the exhaust gas flow path is preferable. As shown in FIG. 10A, the wire-like heat generating member 2001 is wound around the insulating plate 2000 a plurality of times, and at least one heating unit can be installed inside the exhaust pipe. Here, AC power or another power is applied to opposite ends of the wire-like heat generating member 2001. If necessary, the voltage value of AC power may be adjusted by the voltage adjusting converter such as Slidac and the like. Moreover, as shown in FIG. 10B, the heat generating member is formed as the coil-like heat generating member 2003, and supported by the insulating rod member 2004 inserted through the heat generating member. At least one heat generating member is positioned across the gas flow direction inside the exhaust pipe, and AC power or the like may be applied to opposite ends of the coil-like heat generating member 2003 for use. Furthermore, as shown in FIG. 10C, at least one rod-like heat generating member 2005 is used, and separate conductive electrodes 2006 are provided on opposite ends of the rod-like heat generating member so as to connect the rod-like heat generating members in parallel. AC power or the like may be applied to the conductive electrodes on opposite ends for use. Additionally, as shown in FIG. 10D, at least one tape-like heat generating member 2007 is used, and separate conductive electrodes 2008 are provided on opposite ends of the tape-like heat generating member so as to connect the tape-like heat generating members in parallel. AC power or the like may be applied to the conductive electrodes on opposite ends for use. In any case, the heating unit is installed inside the exhaust pipe between the processing space and the exhaust means without obstructing the exhaust gas flow path. If such conditions are satisfied, the mode of installation is not limited.

In the method of heating the heat generating member, for the heat generating member of line, rod, coil or any other form, heat may be generated by applying AC power or DC power to opposite ends to pass electric currents through the heat generating member itself. If necessary, power may be applied via the temperature adjusting controller.

For the temperature of the heat generating member, for example, at the time of forming the amorphous silicon film, since the reaction for discharging a large amount of hydrogen (H) atoms contained in polysilane (SiₓH_{y}: x, y being integers) deposited in the exhaust pipe is promoted and, as a result, the film is changed to a silicon film piece, it is preferable to raise the temperature to 500° C. or more for use.

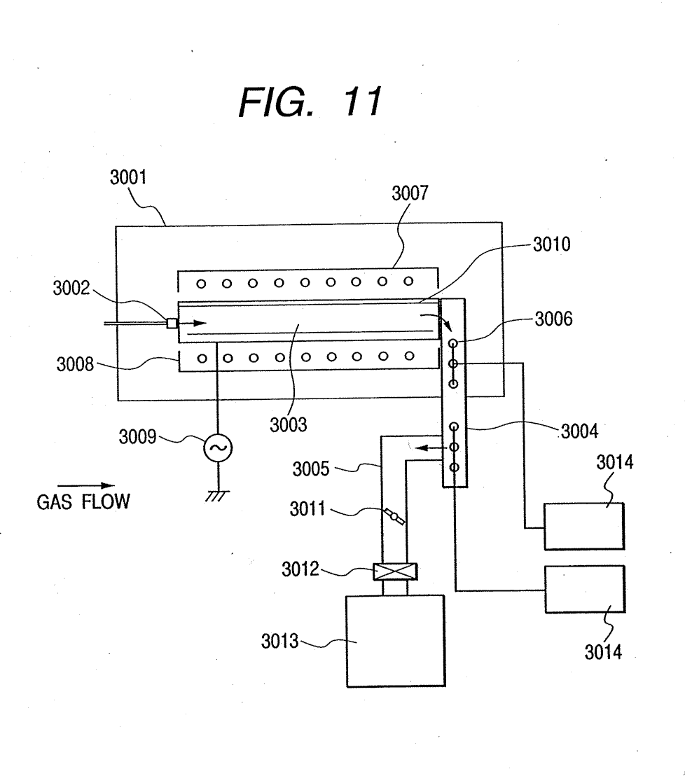

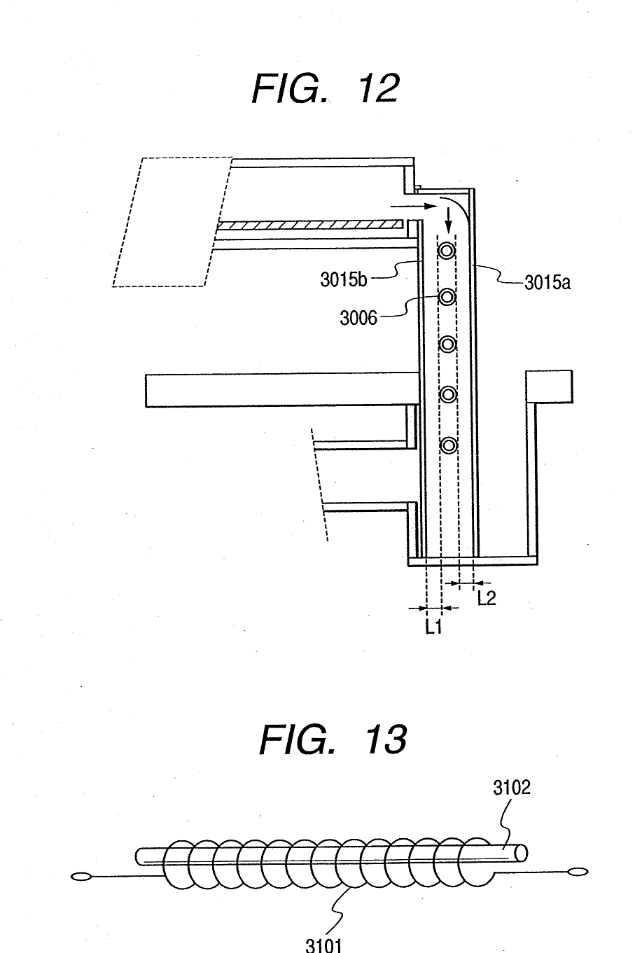

FIG. 11 is a schematic sectional view showing an example of a deposited film forming apparatus as an example of a processing apparatus according to fourth and fifth aspects of the present invention. In the apparatus shown in FIG. 11, a vacuum container 3001 contains a processing chamber (plasma CVD chamber) 3003. A source gas is supplied from gas supply means 3002 provided on one side of the plasma CVD chamber 3003 to perform a deposited film forming process by high-frequency glow discharge in the plasma CVD chamber 3003. Furthermore, after the deposited film is formed, non-reacted gas and fine powder are discharged to exhaust means (vacuum pump) 3013 via an exhaust path (exhaust duct) 3004 and an exhaust piping 3005 provided on the other side of the plasma CVD chamber 3003. A high-melting metal filament 3006 is disposed inside the exhaust duct 3004 between the processing chamber 3003 and the exhaust means 3013. Here, as shown in FIG. 12, intervals between exhaust duct wall surfaces 3015a, 3015b and the high-melting metal filament 3006 are L1, L2. In the embodiment the exhaust duct also serves as recovering means, but recovering means may be provided separately from the exhaust duct. Examples of such a recovering means include members in the shape of a plate, tray, net or rod, or a member also functioning as the chemical reaction causing means. The high-melting metal filament 3006 heated by supplying power from power controllers 3014 serves as chemical reaction causing means. Moreover, the exhaust duct wall surfaces 3015a, 3015b serve as recovering means of chemical reaction products. Formed between a plasma region in the processing chamber 3003 and the high-melting metal filament 3006 is a structure having no concave/convex portions, in order to produce no stagnation in gas flow. Moreover, provided inside the exhaust piping 3005 are a pressure adjusting valve 3011 and a gate valve 3012. Here, a diluting gas is supplied together with source gas SiH₄ to deposit an amorphous film on a substrate (not shown) set on a substrate holder 3010 in the plasma CVD chamber 3003. In this case, the plasma CVD chamber 3003 is heated by a plasma CVD chamber heater 3008, while the substrate is heated by a substrate heater 3007. Moreover, power is supplied from RF power supply 3009. The non-reacted gas and by-product exhausted from the processing chamber 3003 are stuck/collected as deposited films onto the exhaust duct inner wall surfaces.

Therefore, the attachment or deposition of the powder in the exhaust piping 3005, valves 3011, 3012 and pump 3013 as the exhaust means behind the exhaust duct is significantly reduced. Furthermore, reverse diffusion of the powder deposited in the exhaust duct 3004 is eliminated, and no defect occurs in products obtained by processing an article to be processed (substrate), so that a high-quality product can be formed by processing the article (substrate).

Additionally, in FIG. 11, six filaments 3006 exist: three out of the filaments on the side of the plasma CVD chamber 3003 form a first stage and the remaining three form a second stage.

A sixth aspect of the present invention will next be described.

In a method of decomposing and depositing a non-reacted gas, powder and the like by the chemical reaction causing means, the chemical reaction causing means is disposed in an exhaust path connecting a processing chamber and exhaust means, thereby producing a region having the chemical reaction causing means whose mean velocity of gas is different from that in the processing chamber. Since powder of CVD by-product is also decomposed, the non-reacted gas and CVD by-product are efficiently and sufficiently decomposed, and can be deposited on members constituting the chemical reaction causing means and peripheral members.

In the present invention, the heating temperature of the high-melting metal filament depends on its material and the type and flow rate of the non-reacted gas. To use the filament stably for a long time, the temperature is preferably controlled to a temperature lower by at least 100° C. than the melting point. Furthermore, if the heating temperature is too high, there is a possibility that the vacuum seal of the processing (film forming) apparatus is influenced.

The configuration of the high-melting metal filament preferably comprises a single or a plurality of linear shapes, or linear shapes wound in spirals. Depending on the configuration for use and the place of installation, the mean velocity of the gas in the region having the chemical reaction causing means can easily be changed. For example, a plurality of linear shapes or linear shaped wound in spirals are arranged in the exhaust flow direction. Moreover, by introducing a diluting gas (helium, argon, hydrogen or the like) into the region having the chemical reaction causing means from the processing (film forming) container, the mean velocity of the gas in the region having the chemical reaction causing means is made higher than the mean velocity in the processing (film forming) chamber. In the method, the mean velocity of the gas in the region having the chemical reaction causing means becomes higher than the mean velocity of the processing (film forming) chamber, stagnated flow of gas is eased, and the chemical reaction in the region having the chemical reaction causing means is promoted. Therefore, the CVD by-product can be prevented from being deposited in the processing (film forming) chamber and back and forth sections thereof. Moreover, since the total amount of CVD by-products sticking to the exhaust piping and conductance adjusting valve is reduced, during the exhaust operation of the chamber from the atmospheric pressure to a low pressure, the total amount of CVD by-products scattered to the pump from the exhaust piping can be reduced, so that a period elapsed until pump oil replacement and overhauling are required can remarkably lengthened (the frequency of the oil replacement and overhauling can be reduced).

After the functional deposited film is formed, the film deposited on the wall surface of the trap is removed after flowing nitrogen (N₂), helium (He) and another inert gas to purge the source gas until air is leaked to the atmospheric pressure. The trap wall is removed, and the film deposited thereon is removed by a physical process (honing or the like) or a chemical process (etching or the like). In this case, the trap wall may be of a double structure to be easily detached. When a metal plate is used, the film on the trap inner wall surface can easily be removed, and time required for maintenance can be shortened. As the material of the detachable metal plate, stainless steel, aluminum or another metal, or an alloy thereof can be used.

Other constituting elements of the present invention will next be described.

In the present invention, examples of the deposited film source gas include silane (SiH₄), disilane (Si₂H₆) and another amorphous silicon forming source gas, germane (GeH₄) and another functional deposited film forming source gas, and a mixture gas thereof. As the diluting gas, hydrogen (H₂), argon (Ar), helium (He) or the like is exemplified.

Furthermore, for the purpose of doping, diborane (B₂H₆), boron fluoride (BF₃), phosphine (PH₃) or another dopant gas may simultaneously be introduced into the discharge (film forming) chamber to efficiently perform processing.

As a substrate material, for example, stainless steel, Al, Cr, Mo, Au, In, Nb, Te, V, Ti, Pt, Pd, Fe or another metal, alloy thereof, polycarbonate or another synthetic resin having a conductivized surface, glass, ceramic, paper or the like is usually used in the present invention.

In the present invention, during the deposited film formation, any temperature is effective as the substrate temperature, which is preferably not lower than 20° C. but not higher than 500° C., more preferably in the range of 50° C. to 450° C. for obtaining good results.

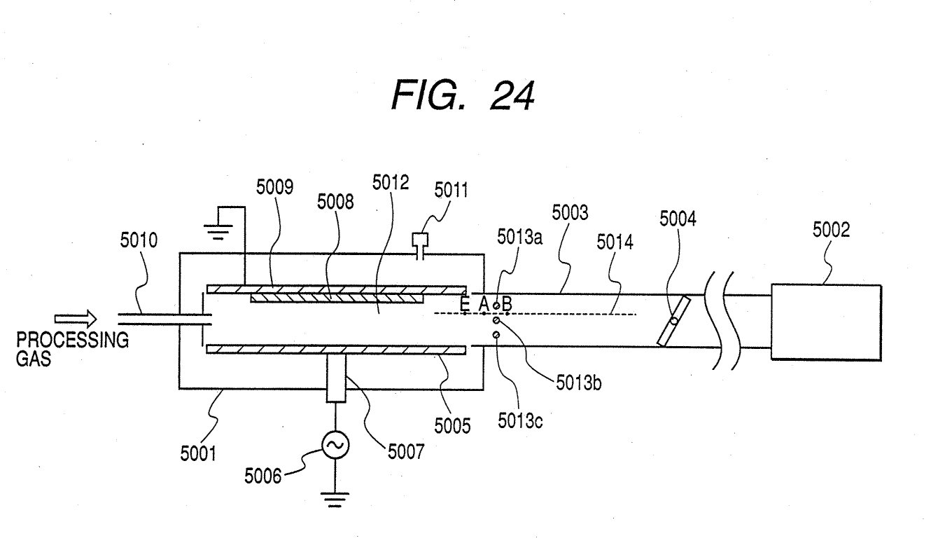

An embodiment according to a seventh aspect of the present invention will be described hereinafter with reference to the drawings. FIG. 24 is a schematic sectional view showing one embodiment of an apparatus using a plasma CVD process out of plasma processing processes of the present invention.

In the drawing, numeral 5001 denotes a plasma processing chamber, 5002 denotes exhaust means (rotary pump, and mechanical booster pimp), 5003 denotes an exhaust piping, 5004 denotes a conductance adjusting valve, 5005 denotes a cathode electrode, 5006 denotes a high-frequency power supply, 5007 denotes a high-frequency introducing section, 5008 denotes a substrate, 5009 denotes a substrate holder, 5010 denotes a gas introducing section, 5011 denotes a pressure gauge, and 5012 denotes a discharge region.

Numerals 5013a to 5013c denote chemical reaction causing means of the present invention. The chemical reaction causing means 5013a to 5013c are provided to cause chemical reaction in the non-reacted gas and/or by-product exhausted from the processing chamber. As a member constituting the chemical reaction causing means 5013a to 5013c, a catalyst, heated catalyst, or heat generating member is used. For example, a material of tungsten, molybdenum, rhenium, platinum or the like may be disposed in the form of a filament, rod, plane or spirally wound filament. Electromagnetic waves, ultrasonic waves or the like may be applied from the outside to heat the material, or AC, DC, high-frequency powers or the like may directly be supplied to heat the material.

The substrate 5008 is fixed to the substrate holder 5009, a substrate inlet/outlet (not shown) of the plasma processing chamber 5001 is closed, and the chamber is evacuated by the exhaust means 5002 to reduce the pressure. The substrate 5008 is heated to a temperature as a deposited film forming condition by a substrate heater (not shown) fixed to the substrate holder 5009. Into the discharge region 5012 of the plasma processing chamber 5001, a plurality of mixed deposited film forming source gases (SiH₄, Si₂H₆, H₂, doping gas) from gas cylinders (not shown) are controlled in flow rate by gas flow rate controllers (not shown), and supplied through the gas introducing section 5010. A high frequency (13.56 MHz) is applied to the cathode electrode 5005 from the high-frequency power supply 5006, and the substrate 5008 and substrate holder 5009 opposite to the cathode electrode 5005 are used as anode electrodes to cause a discharge in the discharge region 5012 between the electrodes. The gas in the chamber is exhausted via the exhaust piping 5003 by the exhaust means 5002, and constantly replaced with newly supplied gas. The pressure of the discharge region 5012 is monitored by the pressure gauge 5011. Based on the pressure signal, an open degree of the conductance adjusting valve 5004 provided in the path of the exhausting piping 5003 is adjusted to control constant the pressure in the discharge region 5012. The deposited film forming source gas is dissociated, ionized, and excited in the plasma generated in the discharge region 5012 to form a deposited film on the substrate.

The conductance adjusting valve 5004 is useful in making adjusting to provide a desired pressure irrespective of the flow rate of the source gas. The conductance adjusting valve 5004 varies a sectional area of the exhaust piping 5003 to increase/decrease the exhaust conductance.

After completing the formation of the deposited film, the supply of the source gas is stopped, a new purge gas (He, Ar or the like) is introduced, and the source gas remaining in the plasma processing chamber 5001 and exhaust means 5002 is sufficiently replaced. After the purging is completed, and the plasma processing chamber 5001 is allowed to cool, the pressure is returned to an atmospheric pressure, and the substrate is removed.

Electromagnetic waves are supplied to the discharge region 5012 for performing the plasma processing using parallel plate electrodes 5005, 5008, 5009, but a rod-like antenna may be installed in the discharge region to supply the electromagnetic waves, or the electromagnetic waves may be supplied through a window from a waveguide (or means other than the electromagnetic waves may be used as plasma generating source).

When the deposited film is formed by plasma CVD, e.g., when silane (SiH₄), disilane (Si₂H₆) or another processing gas is used to deposit an amorphous silicon film, in the conventional process, the by-product on the exhaust piping needs to be periodically removed, but the operation of removing the by-product after the film formation requires to be specially devised. In the present invention, since the non-reacted gases and/or the by-products introduced into the chemical reaction causing means 5013a to 5013c are subjected to a chemical reaction by catalysis, pyrolysis, thermionic radiation, electron radiation or another chemical reaction, and deposited as stable hard films on a wall surface of the exhaust piping 5003 around the chemical reaction causing means 5013a to 5013c, they can safely and easily be removed.

The discharge region 5012 is between the cathode electrode 5005 and the substrate 5008 and substrate holder 5009 as the anode electrode, and the plasma is mainly generated in the discharge region 5012, but in relation to the plasma life, gas velocity, amount of electromagnetic waves turned to portions other than the discharge region 5012 and the like, the plasma is extended at least to the side of the exhaust piping 5003.

The inventors et al. have found that the positional relation of the plasma extended from the discharge region 5012 and the chemical reaction causing means 5013a to 5013c largely influences the ability of processing the non-reacted gas and by-product.

Specifically, when the apparatus is constituted in such a manner that the plasma exists on the side of the discharge region 5012 of the chemical reaction causing means 5013a to 5013c while no plasma exists on the side of the exhaust means 5002, the introduced non-reacted gas and by-product are deposited as the films on the exhaust piping near the chemical reaction causing means 5013a to 5013c or inactivated, so that the exhaust path including the exhaust piping and exhaust means can be prevented from being damaged by the by-product and non-reacted gas sticking thereto.

The plasma mentioned herein is a portion of the processing gas formed into a plasma and emitting light.

The wavelength of the plasma emission mentioned herein indicates a visible range, and the emission intensity can easily be measured with a spectroscope. The emission intensity is measured by transmitting to the atmosphere via a quartz fiber (not shown) a sample light taken out via a plurality of micro through holes formed along a measurement line 5014 in a side face of the exhaust piping 5003, and recording an integrated intensity in the wavelength range with a spectroscope (not shown).

An intersection of the measurement line 5014 and an end face of the discharge region 5012 on the side of the exhaust means 5002 is set to point E, the side of the discharge region 5012 of the chemical reaction causing means 5013a to 5013c is set to point A, and the side of the exhaust means 5002 is set to point B. The present invention is effectively operated by providing the chemical reaction causing means 5013a to 5013c of the present invention close to the discharge region 5012 such that the plasma extended from the discharge region 5012 sufficiently reaches the side of the discharge region 5012 of the chemical reaction causing means 5013a to 5013c, i.e., the point A, and by constructing and operating such that the plasma does not transmit the chemical reaction causing means to the side of the exhaust means 5002 of the chemical reaction causing means 5013a to 5013c, i.e., the point B.

Moreover, in the present invention, the plasma emission intensity on the side of the exhaust means 5002 of the chemical reaction causing means 5013a to 5013c does not need to be zero, may be ½ or less (i.e., reduction percentage of at least 50%) of the emission intensity on the side of the discharge region 5012, preferably 1/10 or less (i.e., reduction percentage of at least 90%) to maximize the effect of the present invention.

Furthermore, the chemical reaction causing means 5013a to 5013c of the present invention are preferably arranged within 150 mm from the end of the discharge region 5012 so as to allow the means to efficiently function. If the chemical reaction causing means 5013a to 5013c are excessively distant from the end of the discharge region 5012, depending on the film forming conditions (processing conditions), there is a case where by-products are deposited between the end of the discharge region 5012 and the chemical reaction causing means 5013a to 5013c to change the exhaust conductance.

For the constitutions of the chemical reaction causing means 5013a to 5013c, for example, AC power is supplied to a single or a plurality of tungsten filaments wound in spirals, so that the plasma transmission is cut off. Moreover, by increasing the AC power to raise the temperature of the filament, the cut-off ability can be enhanced.

Examples of the source gas for use in the plasma processing apparatus of the present invention include silane (SiH₄), disilane (Si₂H₆) and another amorphous silicon forming source gas, germane (GeH₄) and another source gas, and a mixture gas thereof. Moreover, examples of a diluting gas of the source gas include H₂, Ar, He and the like. Furthermore, for the purpose of doping, diborane (B₂H₆), boron fluoride (BF₃), phosphine (PH₃) or another dopant gas may simultaneously be introduced into the discharge space (film forming space).

Additionally, examples of an etching gas for use in the plasma processing apparatus of the present invention include CF₄O₂, CHₓF₍₄₋ₓ₎, SiHₓF₍₄₋ₓ₎, SiHₓCl₍₄₋ₓ₎, CHₓCl₍₄₋ₓ₎ (in which x=0, 1, 2, 3, or 4), ClF₃, NF₃, BrF₃, IF₃ and another etching gas and a mixture gas thereof.

As a substrate material, for example, stainless steel, Al, Cr, Mo, Au, In, Nb, Te, V, Ti, Pt, Pd, Fe or another metal, alloy thereof, polycarbonate or another synthetic resin having a conductivized surface, glass, ceramic, paper or the like is used in the present invention.

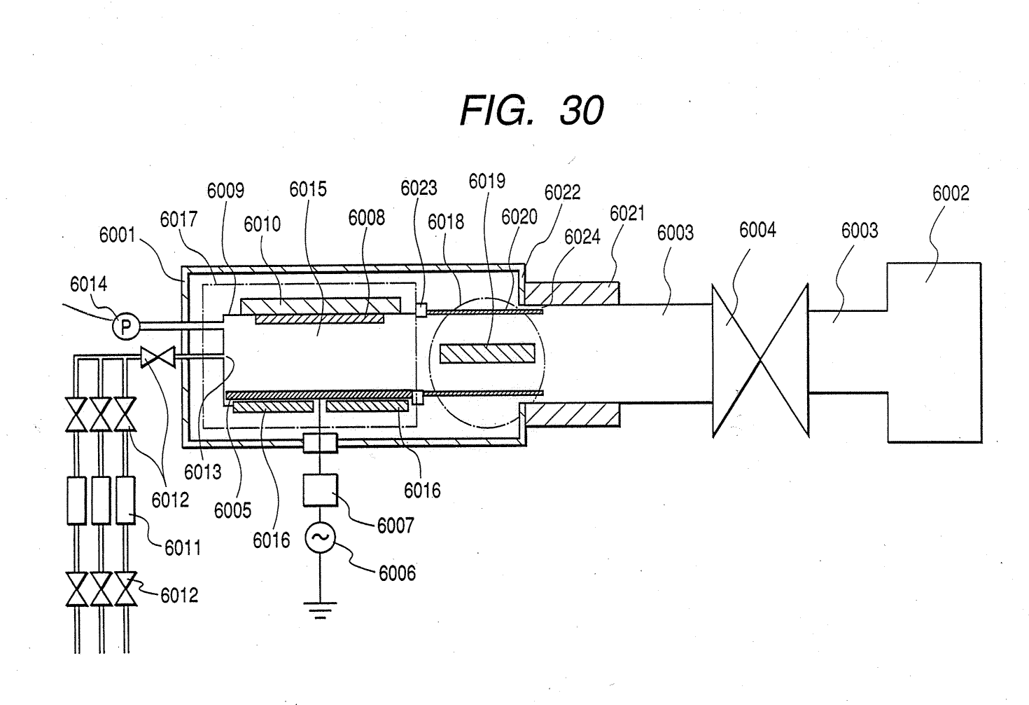

An embodiment according to an eighth aspect of the present invention will be described based on a deposited film forming apparatus by plasma CVD process of FIG. 30.

FIG. 30 is a schematic sectional view showing an embodiment in which the present invention is applied to a deposited film forming apparatus by the plasma CVD process. In the drawing, numeral 6001 denotes a processing chamber; 6002 an exhaust pump (rotary pump and mechanical booster pump) as the exhaust means; 6003 an exhaust piping corresponding to an exhaust path connecting the processing chamber 6001 and the exhaust pump 6002; 6004 a conductance adjusting valve; 6005 a cathode electrode for applying a high frequency; 6006 a high-frequency power supply, 6007 a matching unit; 6008 a base (substrate); 6009 an anode electrode grounded and having a function of holding the substrate; 6010 a heater for heating the substrate; 6011 gas flow rate controllers; 6012 gas introducing valves; 6013 a gas introducing section; 6014 a pressure gauge; 6015 a discharge space (processing space); 6016 a heater for heating the member forming the discharge space 6015; and 6017 a processing furnace housing the discharge space. Disposed in an exhaust path (exhaust piping) 6003 leading to exhaust means 6002 from a processing chamber 6001 is by-product removing/recovering means 6018 for removing/recovering non-reacted source gas exhausted from a discharge space 6015 and by-products formed in the discharge space 6015. The by-product removing/recovering means 6018 is constituted of a filament 6019 as the chemical reaction causing means for causing a chemical reaction in the non-reacted gas and by-product, and an exhaust path 6020 disposed around the filament and serving as chemical reaction product recovering means for attaching/depositing and trapping chemical reaction products generated by the chemical reaction. A voltage can be applied to the filament from an external power supply. Disposed around the exhaust piping 6003 on the side of the exhaust means of the by-product removing/recovering means 6018 is cooling means 6021 using water coolant. Moreover, disposed between the by-product removing/recovering means 6018 and a processing chamber member 6022, exhaust piping 6003 and processing furnace 6017 are heat insulating means 6023, 6024. A sintered body low in thermal conductivity is swamped in the insulating means 6023. Moreover, in the insulating means 6024, there is a gap between the recovering means 6020 and the processing chamber member 6022 or the exhaust piping 6003. The processing furnace 6017 is provided with processing furnace temperature control means 6016 for controlling the temperature of members constituting the processing furnace.

The deposited film forming apparatus by the plasma CVD process of FIG. 30 is constituted based on the following findings:

During the processing for forming the deposited film onto the substrate by the plasma CVD process, the non-reacted gases and/or by-products exhausted from the processing space are chemically reacted and decomposed by catalytic action and/or pyrolytic action. The material having the catalytic action on the non-reacted gas and/or the by-product, or the heat generating member is disposed in the exhaust path between the processing space as the chemical reaction causing means and the exhaust means. When during the processing the non-reacted gases and/or the by-products flow around the chemical reaction causing means, the chemical reaction is induced, thereby generating chemical reaction products. The products are stuck/deposited and recovered on the exhaust path constituting member (recovering means) around the chemical reaction causing means (the exhaust path constituting member to which the chemical reaction products are stuck/deposited will hereinafter be referred to as the chemical reaction product recovering means). The catalyst is appropriately heated to an adequate temperature to enhance its action.

When the non-reacted gas and by-product contain silicon, as the chemical reaction causing means, a filament containing as a main component at least one of tungsten, molybdenum and rhenium is disposed in the exhaust path. A direct-current or alternate-current voltage is applied to the filament to generate heat.

Moreover, the exhaust path constituting member for attaching/recovering the chemical reaction products needs to be heated to enhance its recovery effect. For example, when silane or another non-reacted gas containing silicon, or polysilane or another by-product is chemically reacted, and stuck and recovered as a deposited film, the temperature of the member to which the products stick is preferably a high temperature of 250° C. or more, more preferably 400° C. or more. The exhaust path constituting member is heated by thermal radiation or conduction from the filament as energized.

In order to prevent the heat of the filament as chemical reaction causing means and the chemical reaction product recovering means around the filament from being extended to the exhaust path member and processing chamber member on the exhaust means side of the chemical reaction causing means and recovering means by radiation or conduction, the cooling means is disposed in the exhaust path in the vicinity of the chemical reaction causing means on the exhaust means side thereof. The cooling means cools the exhaust path and processing chamber on the exhaust means side of the chemical reaction causing means. The cooling means allows a cooling medium to flow through a flow path provided in the exhaust path member to substitute the heat of the exhaust path member. The cooling medium may be a liquid such as water, oil and the like, or a gas.

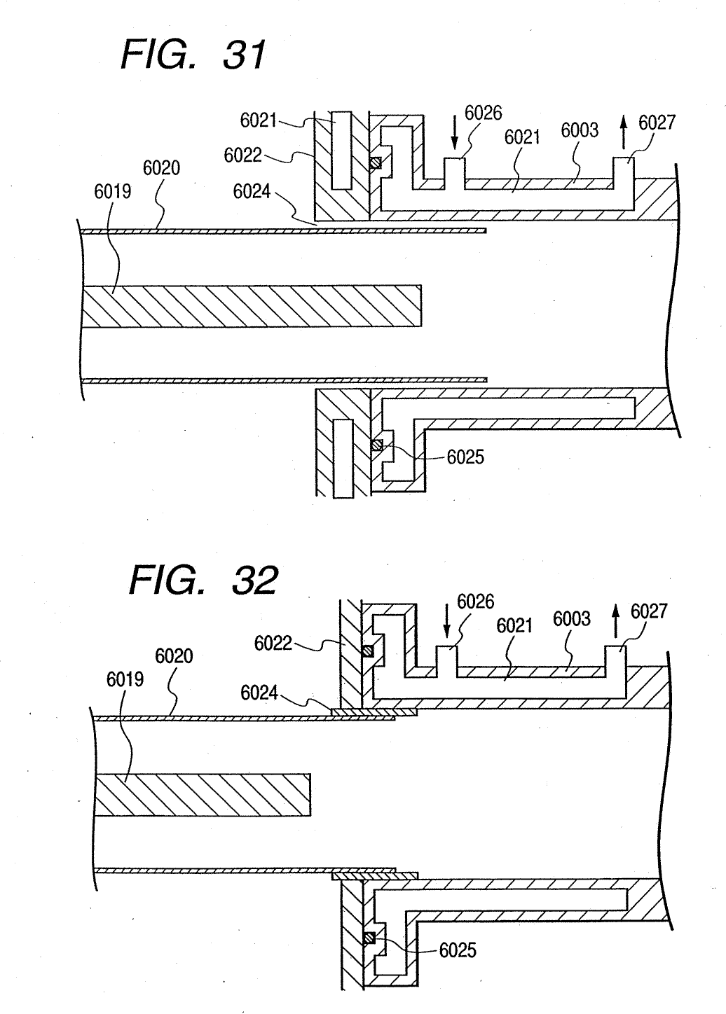

FIG. 31 is an enlarged schematic view showing a structure of the cooling means of the apparatus shown in FIG. 30.

The left side as viewed on the drawing shows a processing space side, while the right side shows an exhaust pump side.

Numeral 6021 denotes a cooling medium passage (cooling means) disposed in the exhaust piping 6003 and processing chamber wall 6022, 6026 denotes an inlet of the cooling medium, 6027 denotes a cooling water outlet, and 6025 denotes O-ring (vacuum seal).

The insulating means 6024 (gap) is provided between the recovering means 6020 and the processing chamber wall 6022 or the exhaust piping 6003 to control the heat conduction to the processing chamber wall 6022 and exhaust piping 6003 from the high-temperature recovering means 6020. Separate from the source gas, H₂ gas or the like is introduced into the processing chamber 6022 to flow into the exhaust piping 6003 via the gap 6024.

FIG. 32 is a schematic view showing another embodiment of the insulating means. Instead of providing the gap between the chemical reaction product recovering means 6020 and the processing chamber 6022 or the exhaust piping 6003, a sintered body having a small thermal conductivity is disposed as an insulating body.

Since the heat insulating means is disposed as described above, the cooling means can be disposed in the processing chamber wall 6022 and exhaust piping 6023 in the vicinity of the high-temperature recovering means 6020 without impairing the recovery ability of the recovering means 6020. To prevent the O-ring 6025 from being broken by the heat, cooling medium (cooled water) is flown in the exhaust piping 6003 and the processing chamber 6022.

In order to prevent the heat generated in the filament as the chemical reaction causing means 6019 and the heat of the recovering means 6020 around the filament from being extended to the processing furnace 6017 and substrate 6008 by radiation or conduction, the heat insulating means 6023 is disposed between the by-product removing/recovering means 6018 and the processing furnace 6017. As the insulating means, for example, a sintered body having a small thermal conductivity can be inserted between the exhaust path constituting member and the processing space constituting member.

Means may be provided for controlling constant the temperature of a member of the processing furnace 6017 which receives the heat from the chemical reaction causing means 6019 and recovering means 6020. The temperature control means 6016 preferably comprises both heating means and cooling means. For example, the heating means is a heater, while the cooling means is a heat radiating plate or a cooling medium. Alternatively, a fluid (medium) with its temperature controlled may be circulated to exchange heat with the member.

For example, in the conditions for forming an amorphous silicon-based deposited film on the substrate by the plasma CVD process, the temperature of the processing furnace constituting member needs to be controlled in the range of about 200 to 350° C. If the temperature is lower than 200° C., powder of CVD by-product is stuck/deposited onto the processing space wall surface, or flies up, so that the by-product is included in the deposited film on the substrate, which produces a possibility that structural defects are caused and a desired film quality cannot be obtained. The upper limit of the control temperature is determined as a upper limit temperature at which the substrate temperature cannot be controlled to a desired temperature by the thermal radiation from the processing space constituting member. Since the processing space constituting member varies in quantity of heat necessary for controlling (heating and cooling) to the desired temperature depending on its distance from the chemical reaction causing means, when disposing the heating and cooling means, the layout and quantity of supply heat (quantity of incoming/outgoing heat) need to be considered. For example, the cooling ability of the cooling means needs to be relatively high in a region close to the chemical reaction causing means.

In the exhaust path 6003 to the pump (exhaust means) from the processing space 6015, the by-product removing/recovering means 6018 may be disposed inside the exhaust path close to the processing space, so that the by-product generated in the processing space is prevented from being stuck/deposited onto the members on the exhaust path.

In the conventional method of heating the trap, a heater or another heating source needs to be disposed outside the trap, which enlarges the removing/recovering mechanism. It is difficult to dispose the source directly behind the processing space.

In a method of disposing a heating coil inside the trap, or in a method of disposing parallel plate electrodes inside the trap to decompose the non-reacted gas by a glow discharge and deposit it in the trap, since the by-product removing/recovering rate (ability) is low, the mechanism itself is unavoidably enlarged, so that the mechanism cannot be disposed adjacent the processing space. Since the mechanism is large, it has to be installed outside the processing chamber. Further, in consideration of the operator's safety, the cooling means is disposed outside the mechanism, which further enlarges the mechanism and lowers the ability of the mechanism of removing/recovering the non-reacted gas and by-product.

In the apparatus of the present invention, as described above, the chemical reaction causing means for causing the chemical reaction in the non-reacted gas and/or the by-product during the processing is disposed in the exhaust path, the insulating means is disposed between the chemical reaction causing means or the chemical reaction product recovering means and the peripheral members, and the processing chamber, exhaust piping and other peripheral members are provided with the cooling means, so that the chemical reaction causing means and the chemical reaction product recovering means can be disposed in the exhaust path directly behind the processing space.

Since the portion serving as the chemical reaction product recovering means on the exhaust path is contained in the processing chamber in a low pressure atmosphere, the low pressure atmosphere exhibits a heat insulating effect, so that the temperature of the exhaust path wall (recovering means) can efficiently be raised, and the recovery effect can be enhanced.

Since the recovery effect is enhanced, the by-product removing/recovering region can be minimized.

In the embodiment of FIG. 30, the non-reacted gas and CVD by-product generated during the deposited film formation are removed as follows:

First, the deposited film is formed on the substrate 6008 in the processing furnace 6017 by the plasma CVD process by the following procedure. The substrate 6008 is fixed to the anode electrode 6009, a substrate inlet/outlet (not shown) of the processing chamber 6001 is closed, and air is exhausted by the exhaust pump 6002 to reduce the pressure. The substrate 6008 is heated to a temperature of a deposited film forming condition by the heater 6010 fixed to the anode substrate 6009. Into the discharge region 6015 of the processing chamber 6001, is supplied a gas mixture of a plurality of deposited film forming source gases (SiH₄, Si₂H₆, H₂, doping gas, etc.) fed in controlled flow rates by the gas flow rate controllers 6011 from gas cylinders (not shown) through the gas introducing valves 6012 and the gas introducing section 6013. A high frequency (13.56 MHz) is applied to the cathode electrode 6005 from the high-frequency power supply 6006, and the matching state is adjusted by the matching unit 6007 to cause a discharge in the discharge region 6015 between the cathode electrode 6005 and the anode electrode 6009. The gas in the chamber 6001 is exhausted via the exhaust piping 6003 by the exhaust pump 6002 and constantly replaced with a newly supplied gas. The pressure of the discharge region 6015 is monitored by the pressure gauge 6014. The pressure signal thereof is transmitted to a controller (not shown) of the conductance adjusting valve 6004 provided in the exhaust piping 6003, and the opening degree of the conductance adjusting valve 6004 is adjusted to keep constant the pressure in the discharge space 6015. The deposited film forming source gas is dissociated, ionized, and excited in the plasma in the discharge space 6015 to form an amorphous silicon semiconductor deposited film on the substrate 6008. When a plasma is to be generated in the processing space 6015, the filament 6019 as the chemical reaction causing means is energized, and the temperature of the exhaust path member 6020 around the filament as the chemical reaction product recovering means is sufficiently raised.

Cooling water is flown in the cooling means in the processing chamber 6022 and the exhaust path 6003 to cool the exhaust piping 6003 and processing chamber 6022. The non-reacted source gas exhausted from the discharge space (processing space) 6015, and CVD by-product generated in the discharge space are decomposed around the filament, and the chemical reaction products thereof are deposited and recovered as a film on the recovering means, i.e., the exhaust path wall 6020 around the filament. No CVD by-product reaches the exhaust piping, valve and pump on the exhaust pump side of the recovering means, or is deposited or accumulated thereon.

After the deposited film is formed on the substrate 6008, and the processing chamber 6001 is returned to the atmospheric pressure, the by-product removing/recovering means 6018 is removed from the processing chamber 6001 and recovered.

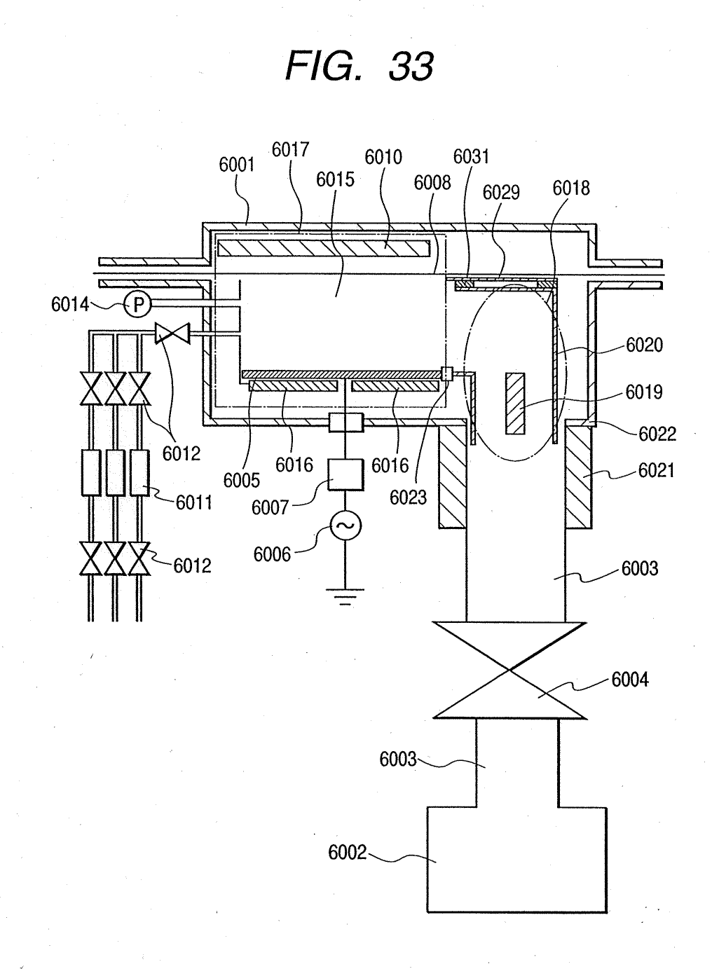

FIG. 33 shows an apparatus according to another embodiment of the present invention. In the apparatus, while a longitudinal substrate is continuously moved in the discharge space, the deposited film is formed by the plasma CVD process. The longitudinal substrate 6008 is wound onto a bobbin (not shown) and contained in a feed container (not shown on the left side). The substrate is passed through the processing chamber 6001 from the feed chamber and extended to a wind-up chamber (not shown on the right side). Disposed in the exhaust path (exhaust piping) 6003 to the exhaust means 6002 from the processing furnace 6017 is a chemical reaction causing means 6019 for causing a chemical reaction in the non-reacted source gas exhausted from the discharge space 6015 and by-product formed in the discharge space 6015. A voltage is applied to the filament from an external power supply. The exhaust path wall 6020 around the filament is recovering means for sticking/depositing and trapping the chemical reaction product generated by the chemical reaction. Disposed in the vicinity of the exhaust means side of the chemical reaction causing means 6019 of the exhaust path 6003 is water cooling means 6021 which cools the processing chamber member 6022 in the vicinity of the exhaust path 6003 and chemical reaction causing means 6019. Numeral 6029 is a heat insulating plate, which functions as a heat insulating means between the chemical reaction causing means or recovery means and the substrate.

Numeral 6031 denotes a support of an insulating plate, which also serves to prevent gas from leaking to the outside from the processing space.

The deposited film is formed on the substrate in the apparatus in the following procedure. One roll of bobbin with the longitudinal substrate wound thereto is set to the feed chamber, the substrate 6008 is extended to the wind-up chamber from the feed chamber via the processing chamber 6001, and air is then exhausted from the processing chamber 6001 to reduce the pressure. Thereafter, processing preparation is proceeded in the same manner as in the embodiment of FIG. 30. After the processing conditions are established, the substrate is continuously fed to form a deposited film on the substrate. After one roll of film is formed, the feeding of the substrate is stopped. In the same manner as in the embodiment of FIG. 30, the substrate 6008 is removed, thereby ending the processing. After the substrate 6008 is removed, the processing chamber 6001 is opened to remove the chemical reaction causing means 6019 and the chemical reaction product recovering means 6020.

The apparatus is constituted based on the following findings. In the apparatus, since the recovering means or exhaust path wall 6020 for recovering the chemical reaction product having a higher temperature than the processing temperature of the substrate 6008 exists in the feeding direction of the substrate 6008 in parallel with the substrate 6008, the substrate 6008 receives the heat radiated from the recovering means 6020 to raise the temperature, so that there is a possibility that the processing conditions (substrate processing temperature) cannot be controlled or the processed/deposited film is changed in properties. To solve the problem, a heat insulating plate 6029 is disposed between the recovering means (exhaust path wall 6020) and the substrate 6008, to suppress the rising of the temperature of substrate 6008. The insulating plate 6029 is not limited to one plate like in the embodiment, and a plurality of plates may be overlapped with gaps made thereamong to enhance the insulating effect.

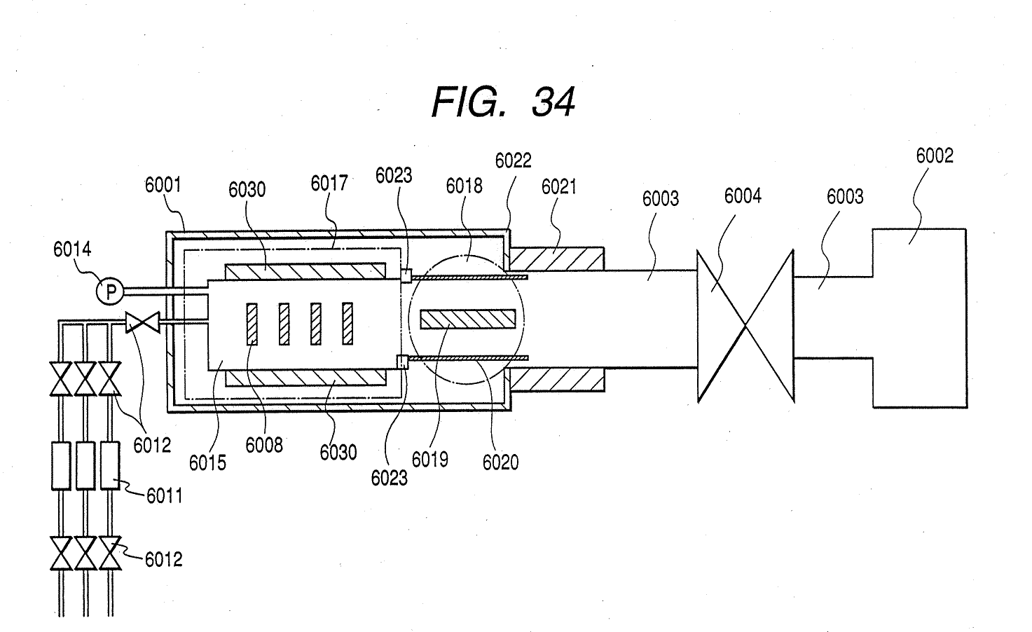

FIG. 34 shows an apparatus according to another embodiment of the present invention. The apparatus is an apparatus for forming a deposited film on a substrate by thermal CVD process.

The processing chamber 6001 contains the processing furnace 6017 for forming a deposited film on the substrate 6008 by the thermal CVD process. The substrate 6008 is supported and fixed in the processing furnace. Disposed immediately after the processing furnace on the exhaust path 6003 to the exhaust means 6002 from the processing furnace 6017 is a tungsten filament 6019 as the chemical reaction causing means for causing a chemical reaction in the non-reacted source gas exhausted from the processing space 6015 and the by-product formed in the discharge space 6015. A voltage can be applied to the filament from an external power supply. The exhaust path wall 6020 around the filament is the recovering means for sticking/depositing and trapping the chemical reaction product generated by the chemical reaction.

Disposed on the exhaust means side of the chemical reaction causing means 6019 of the exhaust path 6003 is by water cooling means 6021. Moreover, disposed between the chemical reaction causing means 6019 and the processing chamber member 6022 is heat insulating means 6023 formed of a sintered body having a low thermal conductivity. Numeral 6030 denotes a heater for heating the processing furnace, substrate and source gas.

A procedure for forming a crystalline silicon film on the substrate using the apparatus of FIG. 34 will be described.

After the substrate 6008 is fixed to the processing furnace 6017, substrate outlet/inlet ports (not shown) of the processing furnace 6017 and processing chamber 6001 are closed, and air is exhausted from the processing furnace 6017 by the exhaust pump 6002 to reduce the pressure. The processing furnace 6017 and substrate 6008 are heated to the temperature of the deposited film forming condition by the heater 6030. The filament 6019 as the chemical reaction causing means disposed on the exhaust path is energized to heat the filament and the exhaust path wall 6020 around the filament as the chemical reaction product recovering means. Water is flown to the cooling means 6021 to start cooling.

Into the processing space 6015 of the processing furnace 6017, a mixture of a plurality of deposited film forming source gases (SiH₄, Si₂H₆, H₂, doping gas, etc.) fed at controlled flow rates by gas flow rate controllers 6011 from gas cylinders (not shown) is supplied through gas introducing valves 6012. The source gas is preheated by the heater 6030, and introduced into the processing space 6015. The gas in the processing furnace 6017 is exhausted by the exhaust pump 6002 via the exhaust piping 6003, and constantly replaced with newly supplied gas. The pressure of the processing space 6015 is monitored by a pressure gauge 6014. The pressure signal thereof is transmitted to a controller (not shown) of the conductance adjusting valve 6004 provided in the exhaust piping 6003, and the opening degree of the conductance adjusting valve 6004 is then adjusted to control constant the pressure in the processing space 6015. The source gas is dissociated, ionized, and excited in the processing space 6015 to form a deposited film on the substrate 6008.

After completing the formation of the deposited film, the supply of the source gas is stopped, a purge gas (He, Ar or the like) is newly introduced therein to sufficiently replace the source gas remaining in the processing furnace 6017 and exhaust pump 6002. After the purging is completed, and the processing chamber 6001 is cooled, the pressure is returned to the atmospheric pressure, and the substrate 6008 is removed, thereby ending the processing.

The chemical reaction causing means 6019 and the chemical reaction product recovering means 6020 are removed and recovered from the processing chamber 6001.

### Example 1

The apparatus shown in FIG. 1 was used to form an amorphous silicon semiconductor film in the thickness of 1 μm on a glass substrate of a 30 cm square. As the deposited film forming source gas, SiH₄ and H₂ were used. Under the pressure of 1 Torr, a discharge was caused by RF. Used as the high-melting metal filament was tungsten filament. The heating temperature of the tungsten filament was set to 1800° C. The time for forming the deposited film once was one hour. This cycle was repeated 100 times, but no problem arose in pressure adjusting during the deposited film formation, and no operational defect of the conductance adjusting valve was generated. No problem arose also with the exhaust pump.

For comparison, the same process as described above was performed without supplying power to the tungsten filament. In this case, at the 25th cycle the conductance adjusting valve became unoperatable, and a large amount of CVD by-products were deposited in the trap 21 as powder.

### Example 2

The apparatus of FIG. 1 was used to form an amorphous silicon semiconductor film on a glass substrate of a 30 cm square. In this case, as metals used in the filament in the trap, tungsten, molybdenum, rhenium, and nickel chrome (Ni: 80%, Cr: 20%) alloy were used to check differences in effect. As the deposited film forming source gas, SiH₄ and H₂ were used, and the film forming rate of the deposited film on the substrate was adjusted to provide 20 Å/s. Moreover, the time for forming the deposited film in one cycle was one hour. Subsequently, the heating temperatures of the filaments were changed in the range of 300° C. to 2200° C. Results are shown in Table 2. The respective codes in the table indicate measurement results as follows:

A double circle means that in 100 cycles there was no film deposition onto the filament or no operational defect of the conductance adjusting valve.

A single circle means that in 100 cycles a slight film deposition to the filament was seen, a deposition of a by-product having a thickness of less than 10 mm was seen on a trap wall, but electric discharge was stabilized, and there was no operational defect of the conductance adjusting valve.

A triangle means that in 100 cycles a remarkable film deposition to the filament was seen, and the deposition of a by-product with a thickness of 10 mm or more was seen on the trap wall. The discharge was stabilized, but the by-product having a thickness of 10 mm or more was also deposited on the conductance adjusting valve, and there were some operational defects.

A cross means that in 100 cycles the conductance adjusting valve required cleaning, or the filament was molten.

As clearly seen from Table 2, when tungsten, molybdenum and rhenium are used as the filaments, by setting the heating temperature of the filament to 500° C. or more, a stabilized discharge can be maintained over a long time without blocking the conductance adjusting valve. Moreover, when the filament is heated to 1400° C. or more, the effect is further increased. Furthermore, even at 300° C., the conductance adjusting valve is not completely blocked off. If the conditions on which less by-products are generated are selected (e.g., the film forming rate of the deposited film is several Å/s or less), the valve sufficiently withstands the use. Moreover, among tungsten, molybdenum and rhenium, especially for the tungsten, no film deposition to the filament was seen even at 1000° C. It has been found that a high effect can be obtained even at a low temperature. On the other hand, it has been found that for the nickel chrome alloy broadly used usually as a heating wire, a sufficient effect cannot be obtained in the temperature range. This is because the maximum working temperature of the nickel chrome alloy is about 1200° C., higher temperatures cannot be used, and the alloy becomes brittle when heated to a high temperature in a reducing atmosphere. Therefore, in the reducing atmosphere containing H₂ like in the embodiment, the alloy instantly becomes brittle, which causes breaking of wire.

### Example 3

The apparatus of FIG. 1 was used to form an amorphous silicon semiconductor film. The procedure of Example 1 was repeated with the exception that the heating temperature of the tungsten filament was selected in the range of 1000° C. and 3500° C. to form the deposited film. Moreover, adjusting was made in such a manner that the film forming rate of the deposited film on the substrate was 50 Å/s. Results are shown in Table 3. The respective codes in the table indicate measurement results as follows:

A double circle means that in 100 cycles there was no film deposition onto the filament or no operational defect of the conductance adjusting valve, and the deposition rate of the film to the trap inner wall was not less than 10 μm/h.

A single circle means that in 100 cycle the deposition rate of the film to the trap inner wall was not less than 6 μm/h but less than 10 μm/h, or the film deposition rate was not less than 10 μm/h but the vacuum seal portion around the trap needed to be cooled.

A triangle means that in 100 cycles the deposition rate of the film to the trap inner wall was less than 6 μm/h and there was a film deposition to the filament.

A cross means that in 100 cycles the conductance adjusting valve required cleaning, or the filament was molten.

As clearly seen from Table 3, the temperature of the tungsten filament largely influences the film deposition on the trap. It has been confirmed that on the drastic film forming condition that the forming rate of the deposited film on the substrate is 50 Å/s or more, especially a temperature in the range of 1400° C. to a tungsten melting point of 3410° C. is effective. Subsequently, the material of the filament was changed to molybdenum and rhenium, similar results were obtained. Effects were confirmed in the range of 1400° C. to 2620° C. for molybdenum, and in the range of 1400° C. to 3180° C. for rhenium.

### Example 4

The apparatus of FIG. 5 was used, the high-melting metal filament was formed of tungsten, the heating temperature was set to 1800° C., and a process for depositing an nip-type semiconductor layer on one roll of 500 m long belt-like substrate with a reflective layer formed on a back surface thereof in ten hours was regarded as one cycle. The film deposition was repeated in 100 cycles, but the deposited film forming conditions (discharge conditions) of each deposited film forming chamber provided good reproducibility each cycle. The characteristics of a prepared photovoltaic element (photoelectric conversion efficiency, fill factor and the like) were also excellent, and better reproducibility than before was provided. Moreover, since the total amount of by-products sticking to the exhaust piping and conductance adjusting valve is less than before, the total amount of by-products scattered atmospheric pressure of the chamber. Therefore, the time elapsed until the pump oil change and overhaul become necessary can remarkably be lengthened (the frequency of oil change and overhaul can be reduced).

Furthermore, no deposition of powder of by-products was seen in the exhaust path extended to the exhaust pipe from the deposited film forming chamber, and a hard film was deposited on the metal plate 47. The replacement of the metal plate 47 was performed as the maintenance after the deposited film formation. Since the metal plate 47 with the film deposited thereon was attached so as to be easily detached, the maintenance was performed in a short time, and a film forming tact time was prevented from increasing.

### Example 6

The apparatus of FIG. 7 was used to form a microcrystalline silicon semiconductor film on a wafer substrate having a diameter of 15 cm. The high-melting metal filament in the trap was formed of tungsten, and heated to 500° C. for use. A source gas of Si₂H₆ was used, the pressure was kept at 2 Torr, and the substrate was heated to 500° C., thereby forming a deposited film on the substrate at the film forming rate of 5 Å/s. A deposited film forming time in one cycle was two hours, and the cycle was repeated 100 times, but there was no problem with the pressure adjusting during the deposited film formation, and no to reach the pump from the exhaust piping is reduced during the exhausting operation to reduce the atmospheric pressure of the chamber. Therefore, a time elapsed until the pump oil change and overhaul become necessary can remarkably be lengthened (the frequency of oil change and overhaul can be reduced).

### Example 5

The apparatus of FIG. 6 was used, the high-melting metal filament was formed of tungsten, the heating temperature was set to 1800° C., and the process for depositing an nip-type semiconductor layer on one roll of 500 m long belt-like substrate with a reflective layer formed on a back surface thereof in ten hours was regarded as one cycle. The film deposition was repeated in 100 cycles, but the deposited film forming conditions (discharge conditions) of each deposited film forming chamber provided good reproducibility each cycle. The characteristics of the prepared photovoltaic element (photoelectric conversion efficiency, fill factor and the like) were also excellent, and better reproducibility than before was provided. Moreover, since the total amount of by-products sticking to the exhaust piping and conductance adjusting valve is less than before, the total amount of by-products scattered to reach the pump from the exhaust piping is reduced during the exhausting operation to reduce the operational defect of the conductance adjusting valve was generated. Furthermore, no problem arose with the exhaust pump.

For comparison, the same process as described above was performed without supplying power to the tungsten filament. In this case, at the 22nd cycle, the conductance adjusting valve became unoperatable, and a large amount of CVD by-products were deposited as powder on the trap 21.

### Example 7

The apparatus of FIG. 8 was used to form a silicon oxide film on a stainless steel substrate of a 30 cm square. The high-melting metal filament in the trap was formed of tungsten, and heated to 500° C. for use. A source gas of Si₂H₆, N₂O was introduced, and ultraviolet rays were radiated from a light source to decompose the source gas, so that the silicon oxide film was deposited on the substrate. The deposited film was formed on the substrate at the film forming rate of 1 Å/s. The deposited film forming time in one cycle was two hours, and the cycle was repeated 200 times, but there was no problem with the pressure adjusting during the deposited film formation, and no operational defect of the conductance adjusting valve was generated. Furthermore, no problem arose with the exhaust pump.

For comparison, the same process as described above was performed without supplying power to the tungsten filament. In this case, at the 40th cycle, the conductance adjusting valve became unoperatable, and a large amount of CVD by-products were deposited as powder on the trap 21.

### Example 8

The apparatus of FIG. 1 was used to dry-etch an amorphous silicon film formed beforehand on a stainless steel substrate. The substrate with the amorphous silicon film formed thereon was placed in the deposited film forming chamber, an etching gas of SiF₄ was introduced, and RF power was applied to cause electric discharge. The RF power was controlled so as to provide an etching rate of 5 Å/s by the discharge. The high-melting metal filament in the activated trap was formed of tungsten, and heated to 500° C. for use. The deposited film forming time in one cycle was two hours, and the cycle was repeated 100 times, but there was no problem with the pressure adjusting during the deposited film formation, and no operational defect of the conductance adjusting valve was generated. Furthermore, no problem arose with the exhaust pump.

For comparison, the same process as described above was performed without supplying power to the tungsten filament. In this case, at the 60th cycle, the conductance adjusting valve became unoperatable, and a large amount of CVD by-products were deposited as powder on the trap 21.

### Example 9

The plasma CVD apparatus shown in FIG. 9 was used to conduct an experiment for demonstrating the effect of the present invention. For the heating unit 1007, as shown in FIG. 10A, the insulating plate 2000 formed of alumina ceramic (300 mm×150 mm, thickness of 5 mm) was wound with the heat generating member 2001 of a wire material having a diameter of 0.2 mm and containing 1% of phosphorus atoms (formed of any one of Cr, Mo, W, V, Nb, Ta, Ti, Zr, Hf) about five times in a plate longitudinal direction, and set in the exhaust pipe. As the processing substrate 1001, a substrate (50 mm×50 mm, thickness of 1 mm) formed of stainless steel (SUS304) was placed on the cathode electrode 1004, and the heater unit 1005 embedded in the lower portion of the cathode was used to set the stainless steel substrate to 300° C. In the example, in order to judge the effect of the heating unit more clearly, the following more drastic film forming conditions than usual were used. In the gas mixing unit 1002, silane (SiH₄) gas (flow rate of 200 sccm) and hydrogen (H₂) gas (flow rate of 200 sccm) were mixed, and the mixture gas was introduced to the reaction chamber 1000 through the gas introducing pipe 1009. Applied to both ends of the heat generating member was AC 100V from AC power supply 1015 via AC applying cable 1016. At this time, the value of an electric current flowing through the wire material was 5 A. Moreover, the temperature of the wire material was 1000° C. Thereafter, the conductance adjusting valve 1014 was adjusted to indicate the pressure in the reaction chamber of 1 Torr on the pressure gauge 1013. Subsequently, RF power of 1000 W was applied to the cathode electrode 1004 from the high-frequency power supply 1006 via the high-frequency applying cable to cause the electric discharge. The processing time, i.e., the discharge time was consecutive ten hours.

### Example 10

Experiments were conducted in the same heat generating member layout, apparatus structure and discharge conditions as those in Example 1, except that as the heating unit 1007 shown in FIG. 9, the heat generating member of the wire material containing 0% of phosphorus atoms was used. In Examples 9 and 10, after the discharge processing was continuously performed for ten hours, the substrate was replaced. Again the discharge conditions were established to continuously perform the discharge processing for ten hours, so that the procedure was repeated. Subsequently, to compare the life of the heat generating member, the number of times of the continuous discharge for ten hours repeated until the heat generating member was broken and became unusable was compared to evaluate durability. Additionally, the state of by-products sticking to the inner wall surface of the exhaust pipe 1003 was compared (after the heat generating member was broken) to evaluate the processing ability.

The state of the by-products sticking to the exhaust pipe inner wall surface was as follows:

In the evaluation of the durability, a circle indicates 11 cycles or more, a triangle indicates six to ten cycles, and a cross indicates zero to five cycles.

In the evaluation of the processing ability:

a double circle indicates that no polysilane powder was observed, and a hard film was stuck/deposited;

a circle indicates that a slight polysilane powder was observed, but a hard film was stuck/deposited; and

a triangle indicates a sticking/deposition with a proportion of about 30% of polysilane powder relative to 70% of a hard film.

As shown in Table 4, it has been proved that when the heat generating member containing phosphorus is used, the number of times of repeated use until the heat generating member is broken, i.e., the life is superior. Additionally, it has been proved from the state of the by-products sticking to the exhaust pipe inner wall surface that the use of the heat generating member containing phosphorus can produce superior results.

### Example 11

Experiments were conducted in the same manner as Example 9 except that heat generating members different in the content of phosphorus atoms were used to check the dependence of the heat generating member on the content of phosphorus atoms. Six types of wire materials with the phosphorus content of 0.01%, 0.05%, 0.1%, 0.5%, 1% and 5% (formed of any one of Cr, Mo, W, V, Nb, Ta, Ti, Zr and Hf) were prepared, and the diameter of each wire material was set to 0.2 mm.

In the same manner as in Examples 9 and 10, the number of times of the continuous discharge for ten hours repeated until the heat generating member was broken was compared. Additionally, the by-products sticking to the exhaust pipe inner wall surface were compared.

The criteria of the deposition state on the exhaust pipe inner wall surface are the same as those in Examples 9 and 10. As shown in Table 5, it has been proved that when the heat generating member containing 0.1% or more of phosphorus atoms is used, the number of times of repeated use until the heat generating member is broken, i.e., the life is superior. Additionally, it has been proved from the state of the by-products sticking to the exhaust pipe inner wall surface that the use of the heat generating member containing 0.1% or more of phosphorus atoms can produce superior results.

### Example 12

A tungsten wire material with a content of phosphorus atoms of 1% and a diameter of 0.2 mm was used, and AC voltage applied to the wire material was varied to variously change the temperature of the wire material or heat generating member, whereby the dependence of the heat generating member on the temperature was checked. The heat generating member layout, apparatus structure and discharge conditions were the same as those in Example 11. The temperatures of the heat generating member were of six types, 300° C., 500° C., 600° C., 800° C., 1000° C. and 1,200° C. In the same manner as in Example 1 and Comparative Example 1, the number of times of the continuous discharge for ten hours repeated until the heat generating member was broken was compared. Additionally, the by-products sticking to the exhaust pipe inner wall surface were compared.

The criteria of the deposition state onto the exhaust pipe inner wall surface are the same as those in Examples 9 and 10. As shown in Table 6, it has been proved that when the heat generating member of the present invention is used in the temperature range of the wire material or heat generating member of 500° C. or more, the number of times of repeated use until the heat generating member is broken, i.e., the life is superior. Additionally, it has been proved from the state of the by-products deposited on the exhaust pipe inner wall surface that the temperature of the heat generating member of 500° C. or more can produce superior results.

### Example 13

The plasma CVD apparatus shown in FIG. 9 was used to conduct an experiment for demonstrating the effect of the present invention. For the heating unit 1007, as shown in FIG. 10A, the insulating plate 2000 formed of alumina ceramic (300 mm×150 mm, thickness of 5 mm) was wound with the heat generating member 2001 of a wire material having a diameter of 0.2 mm and containing 1% of silicon atoms (formed of any one of Cr, Mo, W, V, Nb, Ta, Ti, Zr and Hf) about five times in the plate longitudinal direction, and set in the exhaust pipe. As the processing substrate 1001, a substrate (50 mm×50 mm, thickness of 1 mm) formed of stainless steel (SUS304) was placed on the cathode electrode 1004, and the heater unit 1005 embedded in the lower portion of the cathode was used to set the stainless steel substrate to 300° C. In the example, in order to judge the effect of the heating unit more clearly, the following more drastic film forming conditions than usual were used. In the gas mixing unit 1002, silane (SiH₄) gas (flow rate of 200 sccm) and hydrogen (H₂) gas (flow rate of 200 sccm) were mixed, and the mixture gas was introduced to the reaction chamber 1000 through the gas introducing pipe 1009. Applied to both ends of the heat generating member was AC 100V from AC power supply 1015 via AC applying cable 1016. At this time, the value of an electric current flowing through the wire material was 5 A. Moreover, the temperature of the wire material was 1000° C. Thereafter, the conductance adjusting valve 1014 was adjusted to indicate the pressure in the reaction chamber of 1 Torr on the pressure gauge 1013. Subsequently, RF power of 500 W was applied to the cathode electrode 1004 from the high-frequency power supply 1006 via the high-frequency applying cable to cause the electric discharge. The processing time, i.e., the discharge time was consecutive ten hours.

### Example 14

Experiments were conducted in the same heat generating member layout, apparatus structure and discharge conditions as those in Example 13, except that as the heating unit 1007 shown in FIG. 9, the heat generating member of the wire material containing 0% of silicon atoms was used. In Examples 13 and 14, after the discharge processing was continuously performed for ten hours, the substrate was replaced. Again the discharge conditions were established to continuously perform the discharge processing for ten hours, so that the procedure was repeated. Subsequently, to compare the life of the heat generating member, the number of times of the continuous discharge for ten hours repeated until the heat generating member was broken and became unusable was compared to evaluate the durability. Additionally, the state of by-products deposited on the inner wall surface of the exhaust pipe 1003 was compared (after the heat generating member was broken) to evaluate the processing ability.

In the example, the state of the by-products deposited on the exhaust pipe inner wall surface was as follows:

In the evaluation of the durability, a circle indicates 11 cycles or more, a triangle indicates six to ten cycles, and a cross indicates zero to five cycles.

In the evaluation of the processing ability:

a double circle indicates that no polysilane powder was observed, and a hard film was stuck/deposited;

a circle indicates that a slight polysilane powder was observed, but a hard film was stuck/deposited; and

a triangle indicates a sticking/deposition with a proportion of about 30% of polysilane powder relative to 70% of a hard film.

As shown in Table 7, it has been proved that when the heat generating member containing silicon is used, the number of times of repeated use until the heat generating member is broken, i.e., the life is superior. Additionally, it has been proved from the state of the by-products deposited on the exhaust pipe inner wall surface that the use of the heat generating member containing silicon can produce superior results.

### Example 15

Experiments were conducted in the same manner as Example 13 except that heat generating members different in the content of silicon atoms were used to check the dependence of the heat generating member on the content of silicon atoms. Six types of tungsten wire materials with the silicon content of the heat generating member 0.01%, 0.05%, 0.1%, 0.5%, 1% and 5% (formed of any one of Cr, Mo, W, V, Nb, Ta, Ti, Zr and Hf) were prepared, and the diameter of each wire material was set to 0.2 mm.

In the same manner as in Examples 13 and 14, the number of times of the continuous discharge for ten hours repeated until the heat generating member was broken was compared. Additionally, the by-products deposited on the exhaust pipe inner wall surface were compared.

The criteria of the deposition state on the exhaust pipe inner wall surface are the same as those in Examples 13 and 14. As shown in Table 8, it has been proved that when the heat generating member containing 0.1% or more of silicon atoms is used, the number of times of repeated use until the heat generating member is broken, i.e., the life is superior. Additionally, it has been proved from the state of the by-products deposited on the exhaust pipe inner wall surface that the use of the heat generating member containing 0.1% or more of silicon atoms can produce superior results.

### Example 16

A tungsten wire material with a content of silicon atoms of 1% and a diameter of 0.2 mm was used, and AC voltage applied to the wire material was varied to variously change the temperature of the wire material or heat generating member, whereby the dependence of the heat generating member on the temperature was checked. The heat generating member layout, apparatus structure and discharge conditions were the same as those in Example 13. The temperatures of the heat generating member were of six types, 300° C., 500° C., 600° C., 800° C., 1000° C. and 1,200° C. In the same manner as in Examples 13 and 14, the number of times of the continuous discharge for ten hours repeated until the heat generating member was broken was compared. Additionally, the by-products deposited on the exhaust pipe inner wall surface were compared.

The criteria of the deposition state onto the exhaust pipe inner wall surface are the same as those in Examples 13 and 14. As shown in Table 9, it has been proved that when the heat generating member of the present invention is used in the temperature range of the wire material or heat generating member of 500° C. or more, the number of times of repeated use until the heat generating member is broken, i.e., the life is superior. Additionally, it has been proved from the state of the by-products deposited on the exhaust pipe inner wall surface that the temperature of the heat generating member of 500° C. or more can produce superior results.

### Example 17

In the example, the deposited film forming apparatus by the plasma CVD process of the present invention constructed as shown in FIGS. 11 to 13 was used to form an amorphous silicon deposited film on the glass substrate. The plasma CVD chamber 3003 was a region having a width of 500 mm, length of 850 mm and height of 40 mm. Disposed on the exhaust side of the plasma CVD chamber 3003 was the exhaust duct 3004. For the high-melting metal filament (hereinafter referred to as the filament) 3006, as shown in FIG. 13, a tungsten wire 3101 was wound at a pitch of 3 mm in a spiral shape around a high-melting metal filament support 3102 comprised of alumina ceramics.

In the exhaust duct 3004, the filament 3006 was placed at an interval L1, L2 of 1 cm from an exhaust duct wall surface.

The film forming process was proceeded as follows:

First, the vacuum container 3001 was evacuated/exhausted to 1 Pa or less by the exhaust means 3013. Subsequently, 133 sccm of argon gas was introduced, and the open degree of the pressure adjusting valve 3011 inside the exhaust piping 3005 was adjusted, whereby the inner pressure of the plasma CVD chamber 3003 was maintained at 133 Pa.

Subsequently, the substrate heater 3007 and plasma CVD chamber heater 3008 in the vacuum container 3001 were heated/controlled to provide a predetermined temperature. This state was left to stand for two hours. After the temperature of the plasma CVD chamber 3003 was stabilized, the argon gas was stopped, and 80 sccm of source gas of SiH₄ and 1600 sccm of diluting hydrogen gas were flown from the gas supply means 3002.

Subsequently, the power controllers 3014 were turned on to apply power of 3000 W to the filaments 3006. After ten minutes elapsed, RF power (120 W) was supplied to generate plasmas in the plasma CVD chamber 3003, so that the amorphous silicon film was deposited on the glass substrate.

After six hours elapsed, the supply of RF power was stopped, then the supply of power to the filaments 3006 and the supply of source and diluting gases and heater power were stopped. Subsequently, the vacuum container and exhaust means were purged to return the inside of the apparatus to the atmospheric pressure with N₂ gas.

Furthermore, the aforementioned process was repeated again. After the deposited film formation for 12 hours in total, the apparatus was open to the atmosphere.

Thereafter, it was confirmed that the state of the deposited amorphous silicon film was excellent without any deposition of by-product powder.

Moreover, while in the conventional apparatuses, pressure fluctuation was caused by the powder deposited on the exhaust valve during the film formation, in this example such phenomenon was eliminated. Furthermore, film-like deposit stuck to the exhaust duct wall surface, and no powder deposition was seen on the exhaust piping and pressure adjusting valve inner surfaces behind the filaments 3006 (downstream in the gas flow direction). The amount of recovered powder was substantially zero gram.

### Example 18

Under the same conditions as in Example 17, the film forming time was changed to 30 minutes to form a deposited film. Thereafter, aluminum electrodes were vacuum-evaporated on the deposited amorphous silicon film, and a photo/dark conductivity ratio was measured to evaluate film properties. It was confirmed that an excellent film quality with SN ratio (δₚ/δ_{d}: value obtained by dividing photoconductivity by dark conductivity) of 2×10⁵ or more was obtained.

### Example 19

For the intervals between the filaments 3006 and the exhaust duct wall surfaces 3015a, 3015b, each of L1 and L2 was varied to 6 cm from 1 cm. The deposition state of chemical reaction products of the non-reacted gas and by-product exhausted from the plasma CVD chamber was confirmed. The apparatus structure was the same as that of Example 17 except that the interval L2 between the filaments 3006 and the exhaust duct wall surface 3015a was variable. For the processing conditions, in the same manner as Example 17, 80 sccm of source gas of SiH₄ and 1600 sccm of diluting hydrogen gas were introduced. However, during the processing, the deposited film forming time was three hours. Moreover, the apparatus was operated under the same conditions as in Example 17.

Results are shown in Table 10.

In the table, the respective codes indicate the following. The chemical reaction state of by-products was judged by visual observation.

A cross indicates that there is no film formation, and there is powder sticking/deposition.

A triangle indicates that there are film formation and powder deposition.

A single circle indicates that there is film formation, and a slight amount of powder is deposited.

A double circle indicates that there is film formation, but no powder deposition.

### Example 20

The flow rates of SiH₄ gas and diluting hydrogen gas were 240 sccm and 4800 sccm, respectively, RF power of 350 W was applied, and the other conditions were the same as those of Example 19, whereby examination was made.

Results are shown in Table 11.

As seen from the results of Tables 10 and 11, when the chemical reaction causing means of filaments are used to deposit/collect the non-reacted exhaust gas and by-product as films, the interval of the filaments and the exhaust duct wall surface needs to be 5 cm or less, preferably 3 cm or less, more preferably 1 cm or less.

### Example 21

In this example, the deposited film forming apparatus by the plasma CVD process of the present invention constructed as shown in FIGS. 11, 13, 14, 16 was used to form an amorphous silicon deposited film on the glass substrate. The plasma CVD chamber 3003 was a region having a width of 500 mm, length of 850 mm and height of 50 mm. Disposed on the exhaust side of the plasma CVD chamber 3003 was the exhaust duct 3004 as a reaction chamber. For the heat generating member 3006, as shown in FIG. 13, the filament formed by winding the tungsten wire 3101 around the heat generating member support 3102 comprised of alumina ceramics was used.

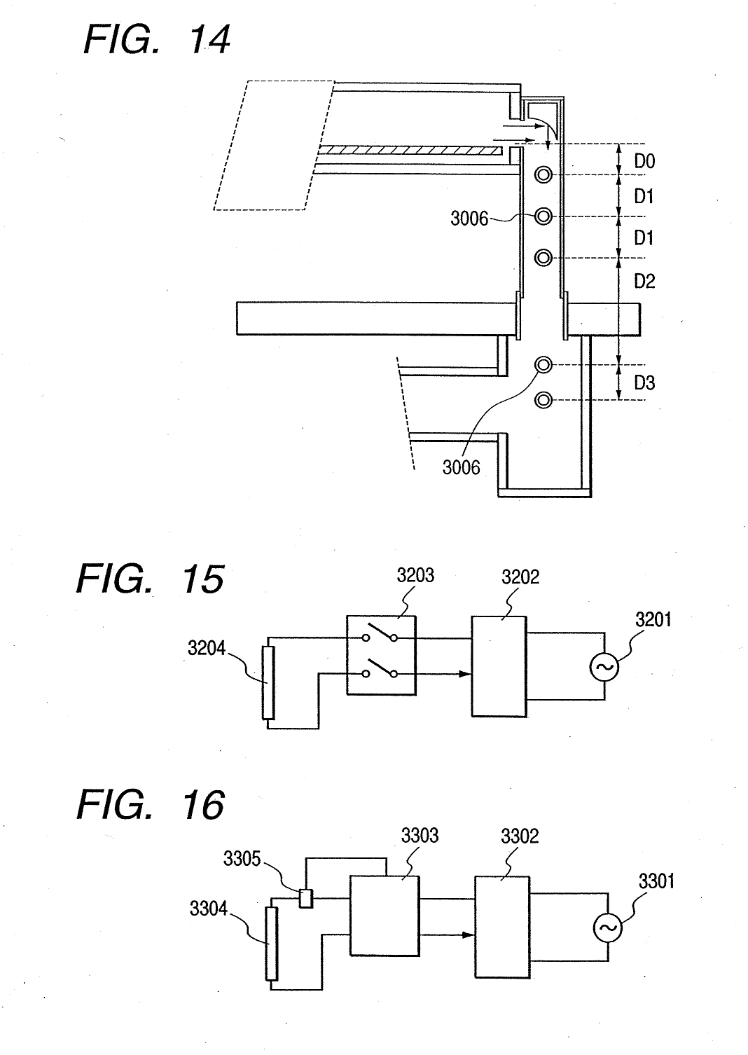

In the exhaust duct 3004, as shown in FIG. 14, three tungsten filaments are arranged at intervals of D1=25 mm from a position 10 mm from an air outlet (interval D0), an interval D2 of 200 mm is further set, and two tungsten filaments are arranged at an interval D3 of 30 mm.

The film forming processing was proceeded as follows:

First, the vacuum container 3001 was evacuated/exhausted to 1 Pa or less by the exhaust means 3013. Subsequently, 133 sccm of argon gas was introduced, and the open degree of the pressure adjusting valve 3011 inside the exhaust piping 3005 was adjusted, whereby the inner pressure of the plasma CVD chamber 3003 was maintained at 133 Pa.

Subsequently, the substrate heater 3007 and plasma CVD chamber heater 3008 in the vacuum container 3001 were heated/controlled to provide a substrate temperature of 250° C. This state was left to stand for two hours. After the temperature of the plasma CVD chamber 3003 was stabilized, the argon gas was stopped, and 80 sccm of source gas of SiH₄ and 1600 sccm of diluting hydrogen gas were flown from the gas supply means 3002.

Subsequently, the heat generating member current density controllers 3014 were turned on to apply power to the heat generating members 3006. After five minutes, the current density was gradually raised until each heat generating member 3006 obtained a current density of 50 A/mm². After ten minutes elapsed, RF power (120 W) was applied to generate a plasma in the plasma CVD chamber 3003, so that the amorphous silicon film was deposited on the glass substrate. During the deposited film processing, the current density of the heat generating member was controlled to be constant at 50 A/mm² to suppress the current density change of the heat generating member.

After six hours elapsed, the supply of RF power was stopped, and the current density of the heat generating member 3006 was gradually decreased. After five minutes, the power supply was stopped, and the supply of source and diluting gases and heater power was stopped. Subsequently, the vacuum container and exhaust means were purged to set the inside of the apparatus to the atmospheric pressure with N₂ gas.

Furthermore, the above-mentioned process was repeated again. After the deposited film formation for twelve hours in total, the apparatus was opened to the atmosphere.

Thereafter, when the state of the deposited amorphous silicon film was observed, the excellent film without any by-product powder deposition was confirmed.

Moreover, while in the conventional apparatuses, the pressure fluctuation was caused by the powder deposited on the exhaust valve during the film formation, in this example such phenomenon was eliminated. Furthermore, the deposited film was formed on the exhaust duct wall surface, but no powder deposition was found on the inner surfaces of the exhaust piping and pressure adjusting valve behind the filaments 3006 (downstream in the gas flow direction).

### Example 22

Under the same conditions as in Example 21, the film forming time was changed to 30 minutes, and a deposited film was formed. Thereafter, aluminum electrodes were vacuum-deposited on the deposited amorphous silicon film, and the photo/dark conductivity ratio was measured to evaluate film properties. It was confirmed that an excellent film quality with SN ratio (δₚ/δ_{d}: value obtained by dividing photoconductivity by dark conductivity) of 2×10⁵ or more was obtained.

### Example 23

The density of currents supplied to the filaments 3006 was varied within the range of 1 to 800 A/mm², the film forming pressure was varied within the range of 66 to 266 Pa, the flow rate of the source gas of SiH₄ or diluting hydrogen gas was varied, and the deposited film forming time was set to three hours to form an amorphous silicon deposited film. The other conditions were the same as those of Example 21, and the ability of processing the exhaust gas was evaluated. This cycle of film formation was repeatedly performed until the filaments 3006 were broken, and the filament durability was evaluated.

Tables 12-1, 12-2 show the deposited film processing conditions and by-product chemical reaction state. The respective codes in Table have the following meanings. The chemical reaction state of by-products was judged by visual observation.

For results of processing ability evaluation:

a cross indicates a remarkable powder deposition;

a triangle indicates a considerable powder deposition;

a circle indicates a slight powder deposition;

a double circle indicates no powder deposition; and

a dash indicates that judgment could not be made because of experiment discontinuance.

For results of durability evaluation:

a cross indicates that the filament was broken within one cycle;

a triangle indicates that the filament was broken in two to 20 cycles;

a circle indicates that the filament was broken in 21 to 50 cycles; and

a double circle indicates that the filament was not broken after completion of 50 cycles.

As a result, at the filament current density of less than 5 A/mm², the chemical reaction of the non-reacted gas and by-product was insufficient, a large amount of by-product powder was deposited in the reaction chamber and exhaust means, and the processing ability was insufficient.

Moreover, at the filament current density exceeding 500 A/mm², the filaments were broken, and the durability was insufficient for performing the deposited film processing for a long time.

### Example 24

The apparatus of FIG. 11 was used, the current densities of first and second steps (groups) of filaments 3006 were provided with different current density distributions, and the effect was confirmed under the conditions (1) and (2):

(1) The current densities of all filaments were set to 50 A/mm².

(2) The current density of the first group of filaments was in the range of 20 to 40 A/mm², while that of the second group was 50 A/mm².

The film forming conditions and results are shown in Table 13. The film forming apparatus was operated in the same manner as Example 22. In case of a small amount of diluting hydrogen or another case, when the current density of the first filament group was excessively large, by-products were raised (accumulated) in the front of the first filament group, the exhaust gas stagnated, and powder was easily deposited. In this case, when the current density of the first filament group was lowered (the current density of the rear step filament group was 50 A/mm²), the raised state of by-products deposited on the front side of the first group was eliminated to provide excellent results.

As described above, when the filament current density is provided with an inclination in the gas flow direction, the chemical reaction of non-reacted gas and by-products can gradually be caused to control the generation of by-product powder.

In Table 13, a cross indicates that there were powder deposition and breakage of heat generating members, while a circle indicates that there was neither powder deposition nor broken heat generating member.

### Example 25

While 200 sccm of SiH₄ gas and 3000 sccm of H₂ gas were introduced, the pressure was set to 133 Pa. A heat generating member current density controller shown in FIG. 15 and the apparatus of FIG. 11 were used to process a deposited film. In FIG. 15, numeral 3201 denotes a 200 W power supply, 3202 denotes a transformer/Slidac, 3203 denotes a relay/electromagnetic switch, and 3204 denotes a heat generating member. A time for one deposited film processing was set to one hour, a deposited film processing stop and cooling time was set to 30 minutes or more, and the process was repeated. In the apparatus of FIG. 15 in which the supply of power to tungsten filaments is repeatedly performed by turning on/off a relay contact, a rapid change of filament temperature, fluctuation of filament current density and the like are caused. Moreover, since the filament current density was raised during the deposited film processing, at the 16th cycle the filaments were broken.

To solve the problem, a heat generating member current density controller shown in FIG. 16 was used. The heat generating member current density controller was turned on to apply power to the heat generating member 3006 or filaments. After five minutes each filament of the heat generating member 3006 provided a predetermined current density value. Such control was performed to gradually raise the current density. In FIG. 16 numeral 3301 denotes a 200 W power supply, 3302 denotes a transformer/Slidac, 3303 denotes a current adjusting unit, 3304 denotes a heat generating member, and 3305 denotes a current sensor. Moreover, when the supply of power to the filaments was stopped, the current density was controlled to be 0 A/mm² five minutes after the current density started to be lowered. Furthermore, the increase of the current density was suppressed or controlled to maintain a predetermined current density.

As a result, even after 30 times of deposited film processing cycles, the filaments were not broken.

As described above, when the rapid change of filament current density and the current density fluctuation during the deposited film processing are suppressed, the life of the filament heat generating member can be lengthened.

### Example 26

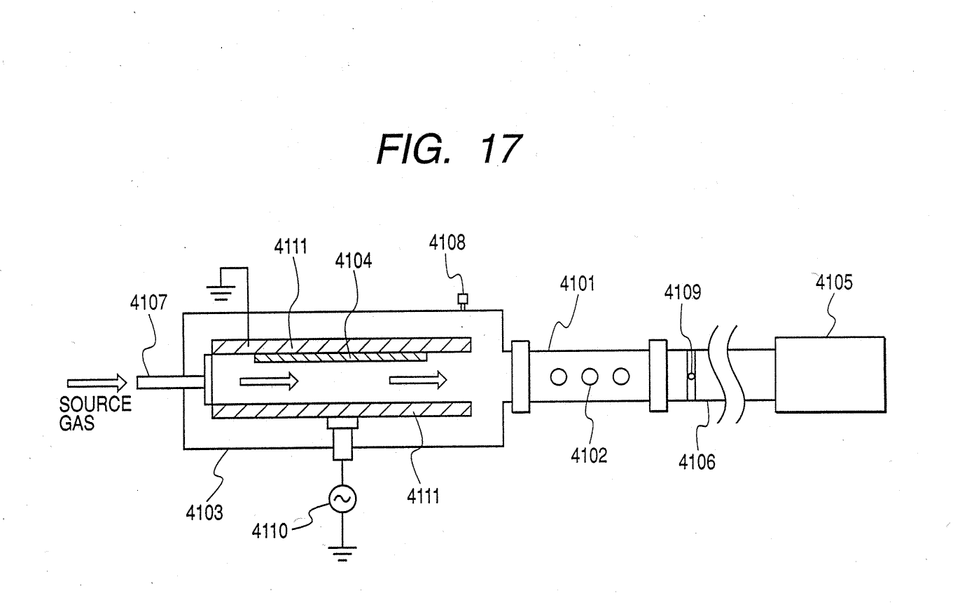

FIG. 17 shows a deposited film forming apparatus by high-frequency plasma CVD process used in Example 26. In FIG. 17, numeral 4101 denotes a trap, and 4102 denotes tungsten filaments.

In the above-mentioned constitution, CVD by-products and non-reacted gas generated during the deposited film formation are removed as follows:

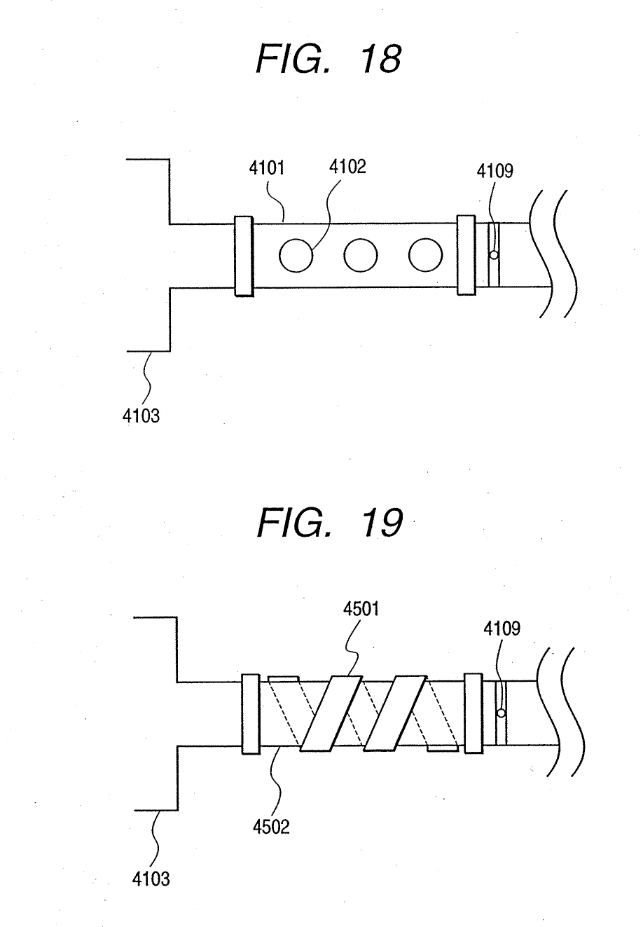

For example, a functional deposited film is formed on a substrate 4104 by a processing container 4103 by the plasma CVD according to the general procedure for preparing the amorphous silicon semiconductor film. Exhausting is performed to reduce the pressure by an exhaust pump 4105. First, before a plasma is generated in the processing container 4103, power is supplied to linear tungsten filaments 4102 each having a circular arc shape from a filament power supply (not shown) via a controller (not shown) to heat to a desired temperature. Since air is exhausted from the processing container 4103 by an exhaust piping 4106 and exhaust pump 4105, the non-reacted gas and CVD by-products in the processing container 4103 reach the trap (type A) 4101 provided in an exhaust path, are decomposed by the tungsten filaments 4102, and deposited as hard films on an inner wall of the trap (type A) 4101. FIG. 18 is an enlarged schematic view of a trap of FIG. 17 provided with spiral tungsten filaments 4102. By using the trap (type A) shown in FIG. 18, the mean velocity of gas of the region having the chemical reaction causing means can be faster than the mean velocity of the processing (film forming) region.

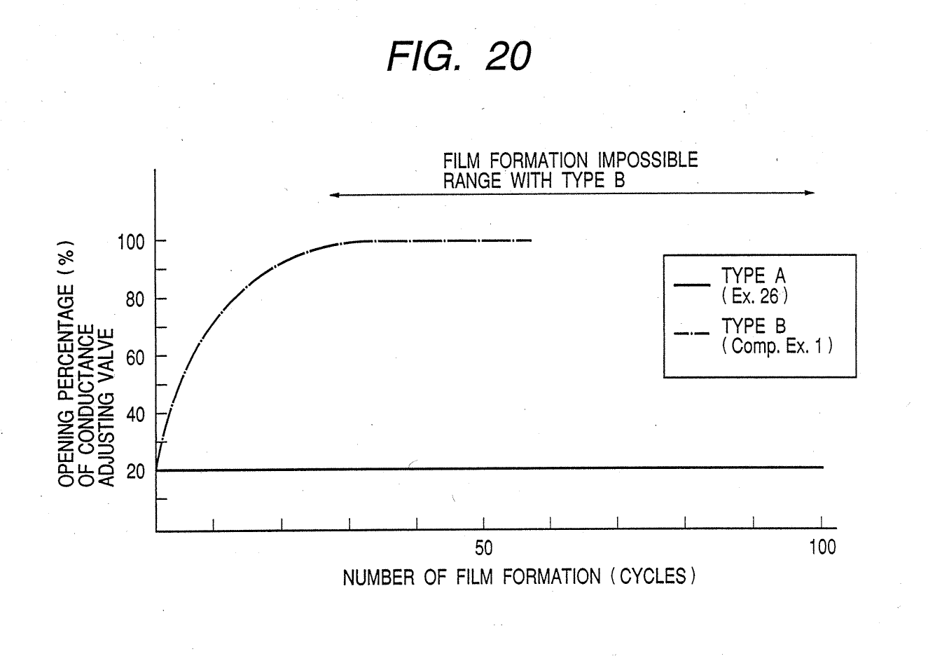

The apparatus shown in FIG. 17 was used to form an amorphous silicon semiconductor film in the thickness of 1 micron on a glass substrate of a 30 cm square. For the deposited film forming source gas, SiH₄ and H₂ were used. The source gas was introduced via a gas introducing pipe 4107, and the pressure was adjusted to 1 Torr by a vacuum gauge 4108 and conductance adjusting valve 4109. Thereafter, a high-frequency power was introduced from a high-frequency power supply 4110 to generate a high-frequency plasma between electrodes 4111. The heating temperature of the tungsten filament 4102 was set to 800° C. A time for forming a deposited film once was one hour. As shown in FIG. 20, the cycle was repeated 100 times, but there was no problem with pressure adjusting during the deposited film formation, and no operational defect of conductance adjusting valve 4109 was generated. Moreover, the exhaust pump had no operational defect.

### Comparative Example 1

For comparison, in the same deposited film forming apparatus as in Example 26, instead of the trap (type A) 4101, a trap (type B) 4502 with a tape heater 4501 wound around the outer periphery of the exhaust piping 4106 as shown in FIG. 19 was used to conduct an experiment. The trap (type B) 4502 shown in FIG. 19 is constituted in such a manner that the gas velocity of the trap (type B) portion 4501 is equal to the gas velocity of the processing (film forming) region. When an experiment similar to the experiment conducted in Example 26 was conducted with the trap (type B) 4502 shown in FIG. 19, as shown in FIG. 20, at the 25th cycle a large amount of CVD by-products are deposited as powder in the trap (type B) 4502. Even when the conductance adjusting valve 4109 is fully open in 100%, the predetermined pressure cannot be maintained, and the experiment cannot be continued.

### Example 27

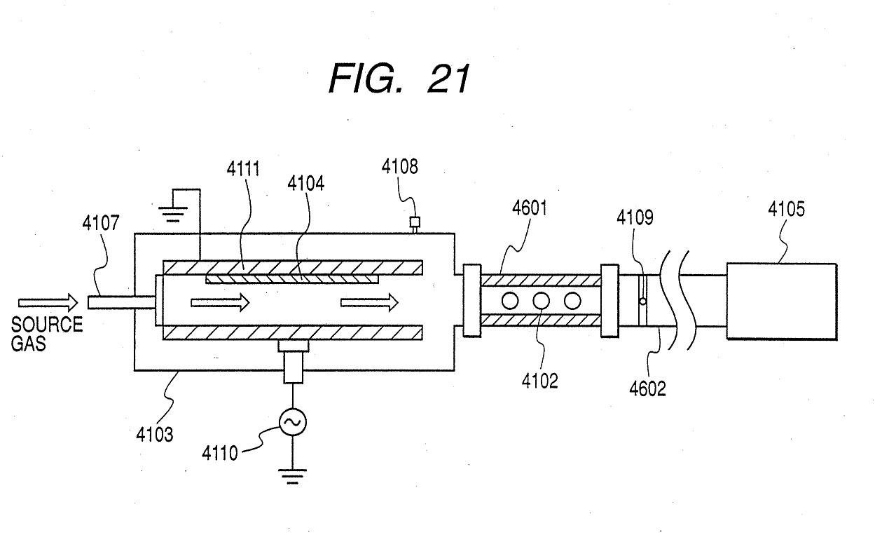

FIG. 21 shows a deposited film forming apparatus by the high-frequency plasma CVD process used in Example 27. In FIG. 21, numeral 4601 denotes a trap (type C), and 4102 denotes tungsten filaments.

In the example, in the deposited film forming apparatus similar to that Example 26, instead of the trap (type A) 4101, the trap (type C) 4601 shown in FIG. 21 was used to conduct an experiment. For the trap (type C) 4601 shown in FIG. 21, since the sectional area of the trap (type C) 4601 is smaller than that of the exhaust piping 4602, the gas velocity of the trap (type C) 4601 can be made larger than the gas velocity of the processing (film forming) region. When the trap (type C) 4601 shown in FIG. 21 was used to conduct an experiment similar to the experiment conducted in Example 26, in the same manner as Example 26, there was no problem with pressure adjusting during the deposited film formation, and no operational defect of the conductance adjusting valve 4109 arose. Moreover, no operational defect of the exhaust pump was caused.

### Example 28

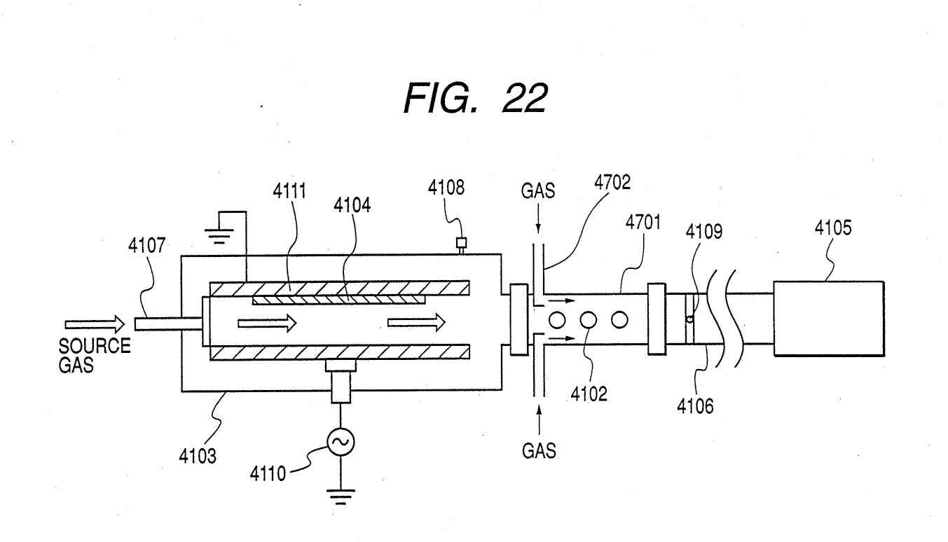

FIG. 22 shows a deposited film forming apparatus by the high-frequency plasma CVD process used in Example 28. In FIG. 22, numeral 4701 denotes a trap (type D), and 4102 denotes tungsten filaments.

In the example, in the deposited film forming apparatus similar to Example 26, instead of the trap (type A) 4101, the trap (type D) 4701 shown in FIG. 22 was used to conduct an experiment. For the trap (type D) 4701 shown in FIG. 22, since a diluting gas (helium, argon, hydrogen and the like) is introduced into a diluting gas introducing pipe 4702 from the side of the processing (film forming) container side of the trap (type D) 4701, the gas velocity of the trap (type D) 4701 can be made larger than the gas velocity of the processing (film forming) region. When the trap (type D) 4701 shown in FIG. 22 was used to conduct an experiment similar to the experiment conducted in Example 26, in the same manner as Example 26, there was no problem with the pressure adjusting during the deposited film formation, and no operational defect of the conductance adjusting valve 4109 arose. Moreover, no operational defect of the exhaust pump was caused.

### Example 29

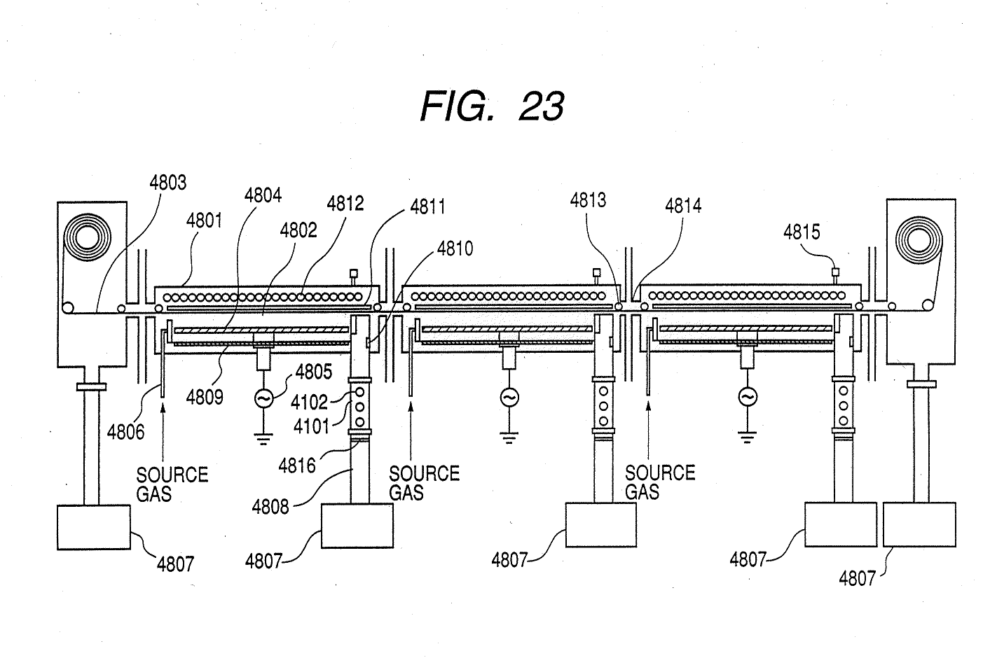

FIG. 23 is a schematic sectional view of a functional deposited film forming apparatus by the high-frequency plasma CVD process mentioned in the other embodiments of the present invention.

In the example, in the functional deposited film forming apparatus by the plasma CVD process of a roll-to-roll system in which processing containers used in Example 26 are interconnected via gas gates 4814, a trap is mounted in an exhaust path connecting a deposited film forming chamber of each deposited film forming processing container and an exhaust pump.

Each component and function in the deposited film formation of FIG. 23 will be described.

A deposited film forming chamber 4802 is provided inside a deposited film forming processing container 4801, and a high-frequency power is supplied to between an electrically grounded belt-like substrate 4803 and a discharge electrode 4804 from a high-frequency power supply 4805, whereby a plasma is formed in the deposited film forming chamber 4802, and a silicon-based non-monocrystalline semiconductor is formed on a lower face (surface) of the belt-like substrate 4803. The deposited film forming chamber 4802 is provided with a source gas introducing pipe 4806 connected to a source gas supply system (not shown) and an exhaust piping 4808 connected to an exhaust pump 4807 to form a gas flow parallel with the moving direction of the belt-like substrate 4803. Moreover, the pressure of the deposited film forming chamber 4802 is measured by a vacuum gauge 4815, the open degree of a conductance adjusting valve 4816 is adjusted, and the pressure in the deposited film forming processing container 4801 is controlled to be constant.

The deposited film forming chamber 4802 is provided with a sheath heater 4809 to heat the deposited film forming chamber 4802, so that the amount of CVD by-products deposited on an inner wall of the deposited film forming chamber 4802 is reduced. The exhaust gas path is provided with a deposited film forming chamber external exhaust hole 4810 in such a manner that external gas (gate gas flown from a gas gate 4814, gas discharged via the inner wall of the deposited film forming processing container 4801 and the like) of the deposited film forming chamber 4802 is exhausted to the exhaust pipe 4808 without passing through the deposited film forming chamber 4802 to prevent impurities from being included into the deposited film.

Moreover, plasma leakage guards 4811 are provided on an inlet, outlet and opposite ends in the width direction of the belt-like substrate 4803 in an upper section of the deposited film forming chamber 4802 to prevent the plasma inside the chamber from leaking to the outside.

The upper face (back surface) of the belt-like substrate 4803 in the deposited film forming processing container is provided with a lamp heater 4812 fixed to an openable/closable lid of the deposited film forming processing container 4801 to heat the belt-like substrate 4803 to a predetermined temperature from the back surface, so that the temperature is kept at a constant temperature during the deposited film formation.

Support rollers 4813 for rotating/supporting the back surface of the belt-like substrate 4803 are provided in the vicinity of the inlet and outlet of the deposited film forming processing container 4801 to linearly extend and support the belt-like substrate 4803 from its back surface in the deposited film forming processing container 4801 in such a manner that the distance from the discharge electrode 4804 is kept constant. Additionally, the support rollers 4813 have therein permanent magnets (not shown) which have a high Curie point and generate a magnetic force of a degree not to influence the plasma. When the belt-like substrate is formed of a ferrite stainless steel or another magnetic body, the support rollers 4813 closely abut on the belt-like substrate 4803.

A trap (type A) 4101 is provided in the exhaust path connecting the deposited film forming chamber and exhaust pipe. The tungsten filaments 4102 are linearly arranged inside the trap (type A) 4101. Power is supplied to the tungsten filaments 4102 from a power supply (not shown) connected via a controller (not shown). A deposited film was formed using this apparatus similar to that used in Example 26 with the exception that the position of provision of the trap (type A) 4101 was changed.

The deposited film was formed on one roll of 500 m belt-like substrate 4803 for ten hours in one cycle, and the process was repeatedly performed 100 cycles. The deposited film forming conditions (discharge conditions) of each deposited film forming processing container 4801 provided good reproducibility in each cycle, the characteristics (photoelectric conversion efficiency, fill factor and the like) of a prepared photovoltaic element were also excellent, and better reproducibility than the conventional process was obtained. Since the deposition of CVD by-products was hardly seen in the exhaust path (excluding the trap) connecting the deposited film forming chamber 4802 and exhaust pump 4807, no by-product was taken into the deposited film on the substrate, which contributed to enhancement of the characteristics of the deposited film.

Since the total amount of CVD by-products deposited on the exhaust piping 4808 and conductance adjusting valve 4816 is smaller than in the conventional apparatuses, the total amount of CVD by-products scattered from the exhaust piping 4808 and reaching the exhaust pump 4807 is decreased during the exhaust operation to reduce the pressure of the deposited film forming container 4801 from the atmospheric pressure to a low pressure. Therefore, the time elapsed until the oil change and overhaul of the exhaust pump 4807 are required can largely be extended (the frequency of oil change and overhaul can be reduced).

### Example 30

The plasma processing apparatus shown in FIG. 24 was used to form a deposited film of amorphous silicon semiconductor on a glass substrate of a 150 mm square. For the plasma processing conditions, the source gas formed by mixing 10 sccm of SiH₄ and 200 sccm of H₂ was introduced via the gas introducing section 5010, the pressure inside the processing chamber 5001 was kept at 1 Torr, the substrate temperature was kept at 250° C., and RF high frequency of 13.56 MHz, 50 W was applied to the cathode electrode 5005 via the high-frequency introducing section 5007. As the exhaust means 5002, a rotary pump and a mechanical booster pump were used. For the exhaust piping 5003, a piping with a shape like a prism of 20 mm×200 mm was sufficiently cleaned for use. For the chemical reaction causing means 5013a to 5013c, three molybdenum wires each having a diameter of 1 mm and length of 500 mm were wound in spiral coils each having a diameter of 5 mm, and arranged in such a manner that the coil longitudinal direction was perpendicular to the drawing of FIG. 24. A DC power of 200 W was applied to each coil to perform heating. The chemical reaction causing means 5013a to 5013c were arranged in positions 8 mm to 14 mm distant from the end of the discharge region 5012 toward the exhaust means 5002.

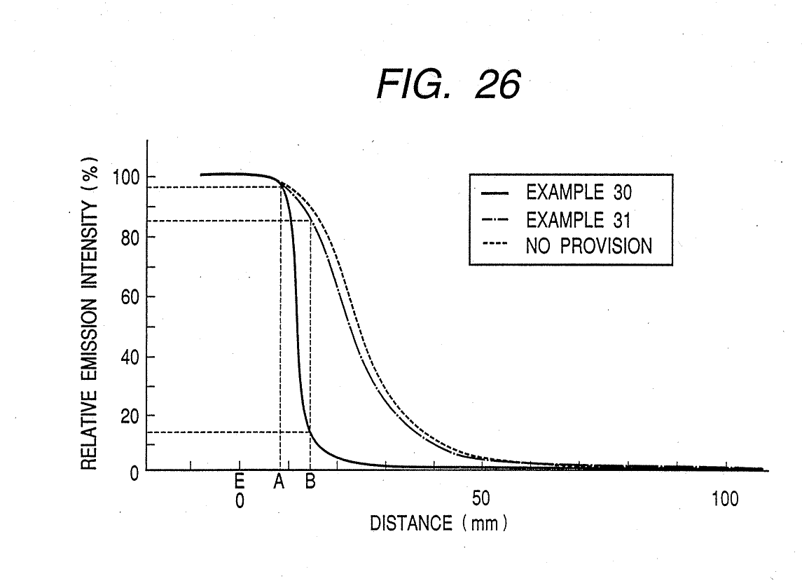

FIG. 26 shows measurement values of plasma emission intensity. The ordinate indicates a relative emission intensity in which the emission intensity in point E as the end of the discharge region 5012 is 100%, while the abscissa indicates a distance in which the point E on the measurement line 5014 is zero. Discrete measurement values are spline-interpolated and plotted. For the emission intensity, the light from quartz fibers provided in the plasma processing chamber 5001 and exhaust pipe 5003 was measured using a momentary multi spectrophotometer as an integrated intensity within the wavelength range of 400 nm to 800 nm. The measurement values of relative emission intensity are shown in FIG. 26. The solid line indicates an emission intensity by this example, and the dotted line indicates an emission intensity when no chemical reaction causing means 5013a to 5013c is provided. The minus side of the distance means the emission intensity inside the discharge region 5012, which is equivalent in intensity to the point E.

Relative intensity values measured at points A and B are shown in table 14. When no chemical reaction causing means 5013a to 5013c is installed, the intensity is moderately decreased as the distance toward the exhaust means from the point E is increased. This means that the plasma is extended from the discharge region 5012. On the other hand, in the example, the emission intensity was reduced before and after the chemical reaction causing means 5013a to 5013c to about 15% (reduction of about 85%). Table 1 shows evaluation results based on the relative intensity, reduction percentage and by-product deposition degree in the positions 8 mm (point A) and 14 mm (point B) distant from the point E.

In this example, the plasma processing time per one cycle was one hour, and the trial was repeated 100 times, but no operational defect of conductance adjusting valve 5004 or exhaust means 5002 arose, and there was no problem with the pressure adjusting of the plasma processing chamber 5001. FIG. 29 shows a change in opening percentage of the conductance adjusting valve 5004 with the number of trials. The solid line indicates this example, in which the opening percentage underwent no change until the end of all the cycles.

The non-uniformity in plane of the amorphous silicon film obtained in each trial was within 2%, and good reproducibility was obtained. The electric conductivity and carrier transportability uniformity were excellent.

Moreover, since no by-product with a large volume like polysilane or the like was deposited on the wall surface of the exhaust piping 5003, and a hard silicon film being thin was deposited, the maintenance after the trial was facilitated, and the trial could be further continued without performing the maintenance. Moreover, neither oil deterioration nor viscosity increase was seen in the rotary pump.

### Example 31

For comparison, the chemical reaction causing means 5013a and 5013c of FIG. 24 were removed, only 5013b was used, and the trial was made in the same manner as Example 30. Specifically, only one molybdenum wire was disposed, and DC power of 300 W was applied. The other plasma processing conditions are the same as those of Example 30. The relative emission intensity is shown by a dashed line of FIG. 26, and the values at the points A and B are shown in Table 14. A slight reduction is seen before and after the chemical reaction causing means 5013b, but the reduction percentage is only about 11%, and the reduction percentage (at least 50%) of the present invention is not satisfied. In Example 31, trials were also repeated, but the opening percentage of conductance adjusting valve 5004 tended to increase. A dashed line of FIG. 29 shows a change in opening percentage. From about the 23rd trial, the opening percentage was 100%. Thereafter, since the chamber pressure was raised, a desired pressure could not be kept. Therefore, the trials were discontinued at the 30th trial.

Even in the first trial, the deposition of polysilane powder was observed on the wall surface of the exhaust piping 5003. When maintenance was performed after the trials, the exhaust piping 5003 was substantially blocked off.

Moreover, for the thickness of amorphous silicon film obtained in the fifth trial, the edge portion of the substrate was thinner, and there was a 10% non-uniformity in plane. Moreover, the deposited film surface obtained in the 20th trial indicated polysilane deposition, and the film turned white. Furthermore, rotary pump oil contained polysilane and had its viscosity raised.

### Example 32

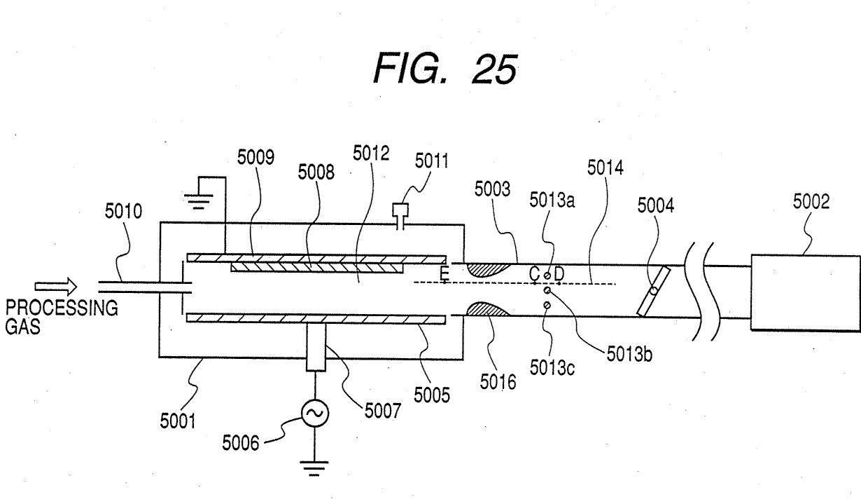

Furthermore, for comparison, as shown in FIG. 25, only the positions of the chemical reaction causing means 5013a to 5013c were changed toward the exhaust means, and trials were made in the same manner as Example 30. Specifically, the chemical reaction causing means 5013a to 5013c were arranged in positions 44 mm to 50 mm distant from the end of the discharge region 5012. The other conditions are the same as those of Example 30.

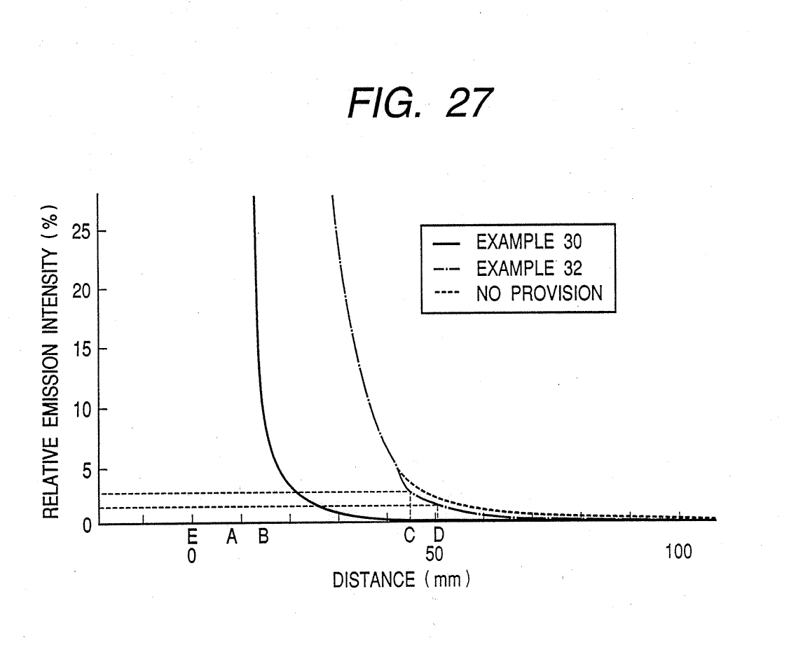

The relative emission intensity is shown by a dashed line of FIG. 27, and the values in positions 44 mm (point C) and 50 mm (point D) from the point E are shown in Table 14. A slight reduction is seen before and after the chemical reaction causing means 5013a to 5013c, but the reduction percentage is about 48%, which is slightly less than the preferable reduction percentage. For the conductance adjusting valve 5004, as shown by a dashed line of FIG. 29, there is a less inclination than Example 31, but the opening percentage tends to increase while the trials are repeated. From about the 70th trial, the opening percentage was 100%. Thereafter, the pressure could not be kept even at the opening percentage of 100%. Therefore, the trials were discontinued at the 75th trial.

When maintenance was performed after the trials, as shown in FIG. 25, the by-products 5016 (polysilane) were deposited to substantially block off the exhaust piping 5003.

### Example 33

In the same manner as Example 30, the plasma processing apparatus shown in FIG. 24 was used to form a deposited film of amorphous silicon semiconductor on a glass substrate with a 30 cm square. To accelerate the deposition rate, 50 sccm of SiH₄ and 300 sccm of H₂ were introduced, and RF high frequency of 150 W was applied. Moreover, DC power of 500 W was applied to each of the chemical reaction causing means 5013a to 5013c. The other conditions are the same as those of Example 30.

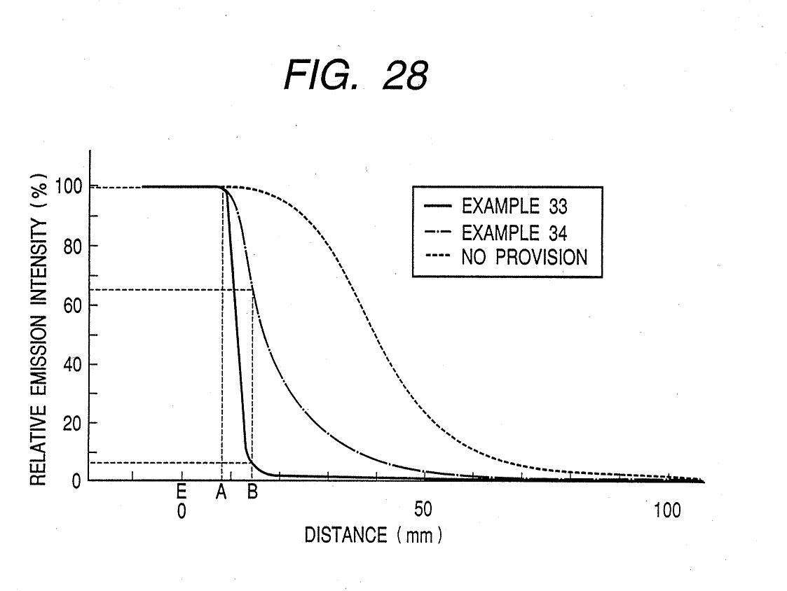

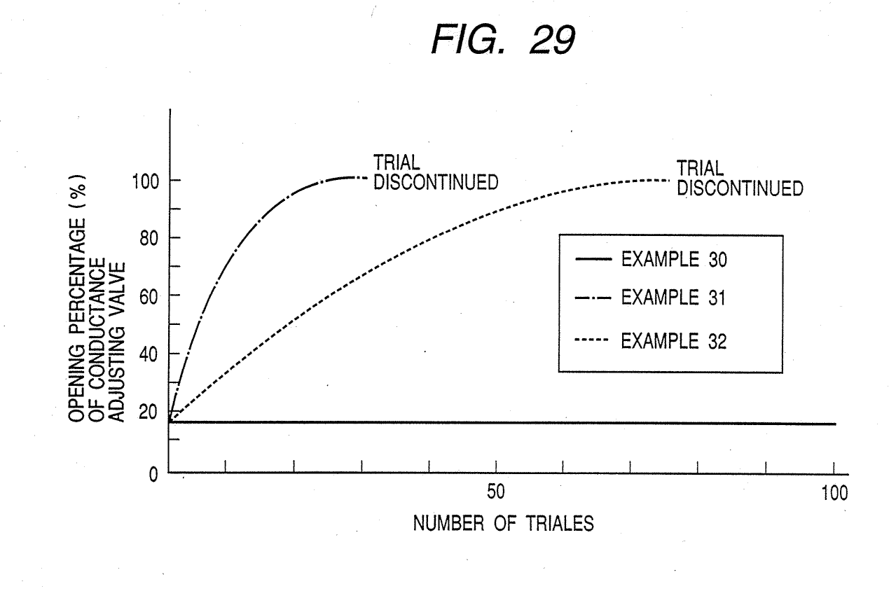

The relative emission intensity is shown by a solid line of FIG. 28, and values in the points A and B are shown in Table 14. The reduction percentage of the emission intensity reached about 94% before and after the chemical reaction causing means 5013a to 5013c, and the preferable reduction percentage is sufficiently satisfied. Moreover, the broken line shows the intensity when the chemical reaction causing means 5013a to 5013c were not provided. When comparing with the case where the chemical reaction causing means 5013a to 5013c are not provided in Example 30 (broken line of FIG. 27), it can be seen that since the plasma processing conditions are changed, the plasma is further extended toward the exhaust means.

In the example, trials were repeated 100 times, but no operational defect of conductance adjusting valve 5004 or exhaust means 5002 arose, and there was no problem with the pressure adjusting of the plasma processing chamber 5001.

As described above, it can be seen that even when the plasma processing (deposition) rate is increased, the present invention can be effective by sufficiently decreasing the emission intensity before and after the chemical reaction causing means 5013a to 5013c.

The non-uniformity in plane of the amorphous silicon film obtained in each trial was within 3%, and the electric conductivity and carrier transportability uniformity were excellent.

Moreover, no by-product with a large volume was deposited on the wall surface of the exhaust pipe 5003, and a hard silicon film was thinly deposited. Therefore, the maintenance after the trials was also facilitated.

### Example 34

In this example, for the chemical reaction causing means 5013a to 5013c, the arrangement was the same as Example 30 (but instead three molybdenum wires which were linear and not wound in spiral coil shape were arranged between the points A and B), and the plasma processing conditions were the same as those of Example 33 which was larger in processing rate than Example 30. The relative emission intensity is shown by a dashed line of FIG. 28, and the values at the points A and B are shown in Table 14. A reduction is seen before and after the chemical reaction causing means 5013a to 5013c, but the reduction percentage was about 33% and did not reach the preferable reduction percentage.

From about the 35th trial, the opening percentage of the conductance adjusting valve 5004 was 100%. Thereafter, since the chamber pressure was raised, the desired pressure could not be kept, and the trials were discontinued at the 40th trial. When maintenance was performed after the trials, the exhaust piping 5003 was substantially blocked off.

### Example 35

The apparatus shown in FIG. 24 was used to dry etch an amorphous silicon film formed beforehand on a glass substrate. The substrate with the amorphous silicon film formed thereon was set on the substrate holder 5009, 20 sccm of SiF₄ as an etching gas was introduced from the gas introducing section 5010, and RF power was supplied to the cathode electrode 5005 to cause electric discharge. The RF power was controlled to provide an etching rate of 5 Å/s by the discharge. The structure, arrangement and applied power of the chemical reaction causing means 5013a to 5013c are the same as those of Example 30. The relative emission intensity before and after the chemical reaction causing means 5013a to 5013c, reduction percentage and evaluation results are shown in Table 14.

The deposited film forming time in one trial was two hours, and the trial was repeated 100 times, but there was no problem with the pressure adjusting during the plasma processing. No operational defect of the conductance adjusting valve arose. Moreover, no problem arose with the exhaust pump.

### Comparative Example 2

For comparison, the same process as Example 35 was performed without supplying power to the molybdenum wires constituting the chemical reaction causing means 5013a to 5013c. At the 60th trial, the conductance adjusting valve became unoperatable, and a large amount of by-product powder was deposited in the exhaust piping 5003.

### Example 36

The apparatus shown in FIG. 30 was used to form an amorphous silicon semiconductor film in a 1 μm thickness on a glass substrate of a 40 cm square. For the processing conditions, the deposited film forming source gas of SiH₄, H₂ was used, and RF discharge was caused under the pressure of 2 Torr. The substrate temperature was 250° C. The filaments as the chemical reaction causing means were energized, and the temperature of the exhaust path wall as the recovering means of chemical reaction products generated by the chemical reaction causing means around the filaments was 550° C.

The deposited film forming rate was set to 10 Å/sec, and the trial was repeated 100 times. The same apparatus was used to repeat the trial 100 times at each of the film forming rates of 15 and 20 Å/sec. In the vacuum seal portion in the vicinity of the recovering means, a thermocouple was disposed to monitor the temperature.

### Comparative Example 3

As the comparative example, the same process as described above was performed while the removing/recovering means of non-reacted gas and CVD by-products was removed.

The trial results are shown in Table 15.

In this example, through 100 trials, the substrate temperature was constantly controlled to provide 250° C. during the deposited film formation. The temperature of the vacuum seal portion was kept at 120° C., at which O-rings manufactured by Biton can be used satisfactory. There was not occurred any leakage such as accompanied by gradual increase of pressure due to breakage of the vacuum seal portion.

No problem arose with the pressure adjusting during the deposited film formation, and no operational defect of the conductance adjusting valve occurred. Furthermore, no problem was caused with the operation of the exhaust pump. When each section was overhauled after the processing, no CVD by-product powder was deposited on the exhaust path connecting the processing space and the exhaust pump. On the exhaust path wall around the filaments, the product generated by the chemical reaction of the CVD by-products was deposited as a film. On the exhaust piping wall and valve surface on the side of the exhaust pump from the exhaust path wall around the filaments, the member materials were exposed as such and there was no deposit. Moreover, CVD by-products were hardly deposited in the pump.

In the comparative example, in 20 and some trials, the pressure could not be adjusted and the trials were discontinued. When each section was overhauled, a large amount of CVD by-product powder was deposited in the exhaust path, and the exhaust path was blocked off near the discharge space.

On the other hand, in this example, it can be seen that the non-reacted source gases exhausted from the discharge space and/or the CVD by-products are substantially completely removed/recovered by the removing/recovering means.

### Example 37

### R to R

The apparatus of FIG. 33 was used to form a 1 μm thick amorphous silicon semiconductor film on a stainless steel substrate having a width of 40 cm and length of 1000 m while the substrate was continuously fed. The feeding rate was set to 1 m/min. For the processing conditions, SiH₄ and H₂ were used as the deposited film forming source gas, and RF discharge was raised under the pressure of 2 Torr. The substrate temperature was 220° C. The filaments as the chemical reaction causing means were energized, and the temperature of the exhaust path wall as the recovering means of chemical reaction products generated by the chemical reaction causing means around the filaments was 550° C. The deposited film forming rate was 20 Å/sec.

The substrate on the recovering means was placed in contact with the thermocouple to monitor the temperature. The substrate was fed toward the exhaust port provided with the recovering means from the source gas supply port distant from the recovering means, and substrate temperatures near the discharge space inlet, middle and outlet were also monitored. By changing the number of insulating plates between the recovering means and the substrate outside the discharge space, the insulating effect and substrate temperature were checked. The insulating plate was formed of a 2 mm thick stainless steel, and the insulating plates were arranged at intervals of 1 mm.

Trial results are shown in Table 16.

It was confirmed by visual observation that a case where no insulating plate was provided and a case where one or two insulating plates were provided are different from each other in color of deposited film on the substrate. There was no difference between two and three insulating plates. Moreover, the film thickness also varied.

When no insulating plate was provided between the recovering means and the substrate, the substrate temperature on the recovering means was raised by 200° C. or more from the processing temperature of 220° C. Furthermore, the substrate temperature on the discharge region could not be controlled to be 220° C., and reached 300° C. When the insulating plate was disposed between the recovering means and the substrate, the substrate temperatures on the recovering means and discharge region were both lowered. On the processing conditions of this example, the substrate temperature in the discharge region could be controlled to 220° C. as desired by two insulating plates. When three insulating plates were disposed, the substrate temperature on the recovering means was substantially the same as that in the discharge region.

It is believed that the processing temperature of the substrate in the discharge region and the temperature of the substrate exposed to the recovering means have an influence on the quality of the deposited film on the substrate. It can be seen that the controllability of the substrate processing temperature can largely be enhanced by the insulating plate.

### Example 38

The apparatus of FIG. 34 was used to form a highly crystalline silicon film on a silicon wafer. As the source gas Si₂H₆ and H₂ were used, and the processing furnace and source gas were heated. The substrate was heated to a temperature of 600° C., and under the pressure of 10 Torr, 5000 Å of deposited film was formed on the substrate at the film forming rate of 10 Å/sec by thermal CVD. The filaments on the exhaust path were energized, and the exhaust path wall as the recovering means of the chemical reaction products around the filaments was set to 600° C. Water was passed in the cooling means to perform cooling.

The substrates were replaced, and the trial was repeated 50 times.

For comparison, without disposing the removing/recovering means of by-products and non-reacted gas, 50 times of trials were performed under the same conditions.

As a result of the trials, in the example, 50 trials could be made without any problem.

In the comparative example, during the seventh trial, the pressure control became impossible, and the trials were discontinued. Each section of the apparatuses used in the example and the comparative example was overhauled and inspected. In the apparatus of the comparative example, CVD by-products were deposited on the exhaust path connecting the exhaust port of the processing furnace and the exhaust pump, and the exhaust path was substantially blocked. In the apparatus of the example, no deposition of CVD by-products was seen on the exhaust path connecting the processing furnace and exhaust pump, while the by-products were subjected to chemical reactions around the filaments and deposited as a film on the exhaust path wall. The ability of the apparatus of the present invention of removing/recovering CVD by-products was confirmed.

According to the present invention, the by-product powder is prevented from being deposited on the exhaust piping and conductance adjusting valve, so that the lowering in exhaust conductance or the operational defect of the conductance adjusting valve can be improved.

Moreover, since the by-product is pyrolytically decomposed and deposited as a hard film, powder is prevented from entering the original deposited film or another processing object and impairing the film quality. The optimum conditions can be produced in the chamber, and a high-quality thin film, especially amorphous or microcrystalline semiconductor thin film can be formed. Therefore, a high-quality silicon-based amorphous thin film useful as a member constituting a photovoltaic element or the like can be formed with good reproducibility.

Furthermore, according to the apparatus of the present invention, the amount of non-reacted gases and/or by-products flowing into the exhaust pump can largely be reduced, and the maintenance cycle of the exhaust pump can largely be extended.

TABLE 1

| | Filament Temperature (° C.) | | | | |
|---|---|---|---|---|---|
| | 1200 | 1400 | 1600 | 1800 | 2000 |
| Deposition | 2.1 | 6.5 | 9.7 | 11.4 | 12.8 |
| Rate (μm/h) | | | | | |
| Filament | 1160 | 1420 | 1650 | 1880 | 2200 |
| Power (W) | | | | | |
| Film | 1.0 | 1.0 | 1.0 | 1.0 | 1.0 |
| Forming | | | | | |
| Chamber | | | | | |
| Pressure | | | | | |
| (Torr) | | | | | |
| RF | 150 | 150 | 150 | 150 | 150 |
| Deischarge | | | | | |
| Power (W) | | | | | |
| Source Gas | SiH₄: | SiH₄: | SiH₄: | SiH₄: | SiH₄: |
| Flow Rate | 150 | 150 | 150 | 150 | 150 |
| (sccm) | H₂: | H₂: | H₂: | H₂: | H₂: |
| | 1500 | 1500 | 1500 | 1500 | 1500 |

TABLE 2

| | Filament Heating Temperature (° C.) | | | | |
|---|---|---|---|---|---|
| | 300 | 500 | 1000 | 1400 | 2200 |
| Tungsten | Δ | ◯ | ⊚ | ⊚ | ⊚ |
| Molybdenum | Δ | ◯ | ◯ | ⊚ | ⊚ |
| Rhenium | Δ | ◯ | ◯ | ⊚ | ⊚ |
| Nickel Chrome | X | Δ | X | X | X |
| (Ni: 80%, Cr: 20%) | | | | | |

TABLE 3

| Filament | Results of Cycle by |
|---|---|
| Temperature | Heating Temperature of |
| (° C.) | Tungsten Filament |
| 1000 | X |
| 1300 | Δ |
| 1400 | ◯ |
| 2000 | ⊚ |
| 3400 | ◯ |
| 3500 | X |

TABLE 4

| Example No. | | | | | | | | | |
|---|---|---|---|---|---|---|---|---|---|
| (Content | Material | | | | | | | | |
| of P) | Cr | Mo | W | V | Nb | Ta | Ti | Zr | Hf |
| Example 9 | ◯ | ◯ | ◯ | ◯ | ◯ | ◯ | ◯ | ◯ | ◯ |
| (0.1%) | ⊚ | ◯ | ⊚ | ◯ | ◯ | ◯ | ⊚ | ◯ | ◯ |
| Example 10 | ◯ | X | ◯ | X | Δ | ◯ | Δ | X | X |
| (0%) | Δ | X | ◯ | X | X | Δ | ◯ | X | X |

Note:
In each item of the table, an upper code indicates an evaluation result of durability, while a lower code indicates an evaluation result of processing ability.

TABLE 5

| P | | | | | | | | | |
|---|---|---|---|---|---|---|---|---|---|
| Content | Material | | | | | | | | |
| (%) | Cr | Mo | W | V | Nb | Ta | Ti | Zr | Hf |
| 0 | ◯ | X | ◯ | X | Δ | ◯ | Δ | X | X |
| | Δ | X | ◯ | X | X | Δ | ◯ | X | X |
| 0.01 | ◯ | Δ | ◯ | X | Δ | ◯ | Δ | X | Δ |
| | Δ | X | ◯ | X | X | Δ | ◯ | X | X |
| 0.05 | ◯ | Δ | ◯ | Δ | Δ | ◯ | Δ | Δ | Δ |
| | Δ | Δ | ◯ | X | Δ | Δ | ◯ | Δ | Δ |
| 0.1 | ◯ | ◯ | ◯ | ◯ | ◯ | ◯ | ◯ | ◯ | ◯ |
| | ⊚ | ◯ | ⊚ | ◯ | ◯ | ◯ | ⊚ | ◯ | ◯ |
| 0.5 | ◯ | ◯ | ◯ | ◯ | ◯ | ◯ | ◯ | ◯ | ◯ |
| | ⊚ | ◯ | ⊚ | ◯ | ◯ | ◯ | ⊚ | ◯ | ◯ |
| 1 | ◯ | ◯ | ◯ | ◯ | ◯ | ◯ | ◯ | ◯ | ◯ |
| | ⊚ | ◯ | ⊚ | ◯ | ◯ | ◯ | ⊚ | ◯ | ◯ |
| 5 | ◯ | ◯ | ◯ | ◯ | ◯ | ◯ | ◯ | ◯ | ◯ |
| | ⊚ | ◯ | ⊚ | ◯ | ◯ | ◯ | ⊚ | ◯ | ◯ |

Note:
In each item of the table, an upper code indicates an evaluation result of durability, while a lower code indicates an evaluation result of processing ability.

TABLE 6

| Heating | Repeating Times of | State of |
|---|---|---|
| Member | Continuous Discharge | Deposition on |
| Temperature | for 10 Hours | Exhaust Pipe |
| (° C.) | (times) | Inner Wall |
| 300 | 6 | X |
| 500 | 8 | ◯ |
| 600 | 10 | ◯ |
| 800 | 11 | ◯ |
| 1000 | 10 | ◯ |
| 1200 | 9 | ◯ |

TABLE 7

| Example No. | Material | | | | | | | | |
|---|---|---|---|---|---|---|---|---|---|
| (Si Content) | Cr | Mo | W | V | Nb | Ta | Ti | Zr | Hf |
| Example 13 | ◯ | ◯ | ◯ | ◯ | ◯ | ◯ | ◯ | ◯ | ◯ |
| (0.1%) | ◯ | ◯ | ⊚ | ◯ | ◯ | ⊚ | ◯ | ◯ | ◯ |
| Example 14 | ◯ | Δ | ◯ | X | Δ | ◯ | Δ | X | X |
| (0%) | Δ | Δ | ◯ | X | X | ◯ | Δ | X | X |

Note:
In each item of the table, an upper code indicates an evaluation result of durability, while a lower code indicates an evaluation result of processing ability.

TABLE 8

| P | | | | | | | | | |
|---|---|---|---|---|---|---|---|---|---|
| Content | Material | | | | | | | | |
| (%) | Cr | Mo | W | V | Nb | Ta | Ti | Zr | Hf |
| 0 | ◯ | Δ | ◯ | X | Δ | ◯ | Δ | X | X |
| | Δ | Δ | ◯ | X | X | ◯ | Δ | X | X |
| 0.01 | ◯ | Δ | ◯ | Δ | Δ | ◯ | Δ | X | Δ |
| | Δ | Δ | ◯ | X | X | ◯ | Δ | X | X |
| 0.05 | ◯ | ◯ | ◯ | Δ | ◯ | ◯ | ◯ | Δ | ◯ |
| | Δ | Δ | ◯ | Δ | Δ | ◯ | Δ | Δ | Δ |
| 0.1 | ◯ | ◯ | ◯ | ◯ | ◯ | ◯ | ◯ | ◯ | ◯ |
| | ◯ | ◯ | ⊚ | ◯ | ◯ | ⊚ | ◯ | ◯ | ◯ |
| 0.5 | ◯ | ◯ | ◯ | ◯ | ◯ | ◯ | ◯ | ◯ | ◯ |
| | ◯ | ◯ | ⊚ | ◯ | ◯ | ⊚ | ◯ | ◯ | ◯ |
| 1 | ◯ | ◯ | ◯ | ◯ | ◯ | ◯ | ◯ | ◯ | ◯ |
| | ◯ | ◯ | ⊚ | ◯ | ◯ | ⊚ | ◯ | ◯ | ◯ |
| 5 | ◯ | ◯ | ◯ | ◯ | ◯ | ⊚ | ◯ | ◯ | ◯ |
| | ◯ | ◯ | ⊚ | ◯ | ◯ | ⊚ | ◯ | ◯ | ◯ |

Note:
In each item of the table, an upper code indicates an evaluation result of durability, while a lower code indicates an evaluation result of processing ability.

TABLE 9

| | Repeating Times of | |
|---|---|---|
| Heating | Continuous | State of |
| Member | Discharge for 10 | Deposition on |
| Temperature | Hours | Exhaust Pipe |
| (° C.) | (times) | Inner Wall |
| 300 | 6 | X |
| 500 | 8 | ◯ |
| 600 | 9 | ◯ |
| 800 | 11 | ◯ |
| 1000 | 10 | ◯ |
| 1200 | 10 | ◯ |

TABLE 10

L1

| L2 | 1 | 2 | 3 | 4 | 5 | 6 |
|---|---|---|---|---|---|---|
| 1 | ≈0 | ≈0 | ≈0 | ≈0 | 0.1 | 0.4 |
| | ⊚ | ⊚ | ⊚ | ⊚ | ◯ | Δ |
| 2 | ≈0 | ≈0 | ≈0 | 0.1 | 0.1 | 0.5 |
| | ⊚ | ⊚ | ⊚ | ◯ | ◯ | Δ |
| 3 | ≈0 | ≈0 | ≈0 | 0.1 | 0.1 | 0.6 |
| | ⊚ | ⊚ | ⊚ | ◯ | ◯ | Δ |
| 4 | ≈0 | 0.1 | 0.1 | 0.1 | 0.2 | 0.7 |
| | ⊚ | ◯ | ◯ | ◯ | ◯ | X |
| 5 | 0.1 | 0.1 | 0.1 | 0.2 | 0.3 | 0.8 |
| | ◯ | ◯ | ◯ | ◯ | ◯ | X |
| 6 | 0.4 | 0.5 | 0.6 | 0.7 | 0.8 | 1.2 |
| | Δ | Δ | Δ | X | X | X |

Note:
In each item of the table, an upper code indicates an evaluation result of amount (g) of recovered powder, while a lower code indicates an evaluation result of chemical reaction state of by-products.

TABLE 11

L1

| L2 | 1 | 2 | 3 | 4 | 5 | 6 |
|---|---|---|---|---|---|---|
| 1 | ≈0 | 0.1 | 0.4 | 0.6 | 0.8 | 1.2 |
| | ⊚ | ◯ | Δ | Δ | X | X |
| 2 | 0.1 | 0.1 | 0.4 | 0.7 | 0.8 | 1.3 |
| | ◯ | ◯ | Δ | X | X | X |
| 3 | 0.4 | 0.4 | 0.4 | 0.7 | 0.9 | 1.5 |
| | Δ | Δ | Δ | X | X | X |
| 4 | 0.6 | 0.7 | 0.7 | 0.8 | 1.0 | 1.7 |
| | Δ | X | X | X | X | X |
| 5 | 0.8 | 0.8 | 0.9 | 1.0 | 1.2 | 2.0 |
| | X | X | X | X | X | X |
| 6 | 1.2 | 1.3 | 1.5 | 1.7 | 2.0 | 2.4 |
| | X | X | X | X | X | X |

Note:
In each item of the table, an upper code indicates an evaluation result of amount (g) of recovered powder, while a lower code indicates an evaluation result of chemical reaction state of by-products.

TABLE 12-1
Evaluation of Processing Ability

| Film | Heat Generating Member Current Density | | | | | | | | |
|---|---|---|---|---|---|---|---|---|---|
| Forming | (A/mm²) | | | | | | | | |
| Condition | 1 | 5 | 20 | 50 | 100 | 150 | 200 | 500 | 800 |
| SiH₄: 80 sccm | Δ | ◯ | ⊚ | ⊚ | ⊚ | ⊚ | ⊚ | ⊚ | — |
| H₂: 1600 sccm | | | | | | | | | |
| Pressure: 66 Pa | | | | | | | | | |
| SiH₄: 240 sccm | X | Δ | ◯ | ⊚ | ⊚ | ⊚ | ⊚ | ⊚ | — |
| H₂: 4800 sccm | | | | | | | | | |
| Pressure: 133 Pa | | | | | | | | | |
| SiH₄: 300 sccm | X | X | Δ | ◯ | ⊚ | ⊚ | ⊚ | ⊚ | — |
| H₂: 6000 sccm | | | | | | | | | |
| Pressure: 266 Pa | | | | | | | | | |

TABLE 12-2
Evaluation of Filament Durability

| Film | Heat Generating Member Current Density | | | | | | | | |
|---|---|---|---|---|---|---|---|---|---|
| Forming | (A/mm²) | | | | | | | | |
| Condition | 1 | 5 | 20 | 50 | 100 | 150 | 200 | 500 | 800 |
| SiH₄: 80 sccm | ⊚ | ⊚ | ⊚ | ⊚ | ⊚ | ⊚ | ⊚ | ◯ | X |
| H₂: 1600 sccm | | | | | | | | | |
| Pressure: 66 Pa | | | | | | | | | |
| SiH₄: 240 sccm | ⊚ | ⊚ | ⊚ | ⊚ | ⊚ | ⊚ | ⊚ | ◯ | X |
| H₂: 4800 sccm | | | | | | | | | |
| Pressure: 133 Pa | | | | | | | | | |
| SiH₄: 300 sccm | ⊚ | ⊚ | ⊚ | ⊚ | ⊚ | ⊚ | ◯ | Δ | X |
| H₂: 6000 sccm | | | | | | | | | |
| Pressure: 266 Pa | | | | | | | | | |

TABLE 13

| | (1) | (2) |
|---|---|---|
| SiH₄ Flow Rate (sccm) | 100 | 100 |
| Hydrogen Flow Rate (sccm) | 500 | 500 |
| Pressure (Pa) | 133 | 133 |
| Heat Generating Member 1 | 50 | 20 to 40 |
| Current Density (A/mm²) | | |
| Heat Generating Member 2 | 50 | 50 |
| Current Density (A/mm²) | | |
| By-product State | X | ◯ |
| Heat Generating Member | ◯ | ◯ |
| State | | |

TABLE 14

| | |
|---|---|
| Relative | |
| Emission | Reduction |
| Intensity (%) | Percentage |

| | A or C | B or D | (%) | Evaluation |
|---|---|---|---|---|
| Example 30 | 96 | 14 | 85 | ◯ |
| Example 31 | 96 | 85 | 11 | X |
| Example 32 | 2.5 | 1.3 | 48 | Δ |
| Example 33 | 99 | 6 | 94 | ◯ |
| Example 34 | 99 | 66 | 33 | X |
| Example 35 | 90 | 8 | 91 | ◯ |
| Comparative | 90 | 75 | 17 | X |
| Example 2 | | | | |

TABLE 15
(Example 36)

| Film | | State of | State of |
|---|---|---|---|
| Forming | | Circumference | Exhaust |
| Rate | Repeatable | of | Piping, |
| (Å/sec) | Trials | Filaments | Valve, Pump |
| 10 | 100 | No blocking | No deposit |
| 15 | 100 | No blocking | No deposit |
| 20 | 100 | Slightly | No deposit |
| | | blocked | |

(Comparative Example 3)

| Film | | State of |
|---|---|---|
| Forming | | Exhaust |
| Rate | Repeatable | Piping, |
| (Å/sec) | Trials | Valve, Pump |
| 10 | 25 | Blocked by |
| | | deposited |
| | | powder |
| 15 | 24 | Blocked by |
| | | deposited |
| | | powder |
| 20 | 24 | Blocked by |
| | | deposited |
| | | powder |

TABLE 16

| | Discharge | Discharge | Discharge | |
|---|---|---|---|---|
| | Region | Region | Region | |
| | Inlet- | Middle- | Outlet- | Substrate |
| | Side | Portion | Side | Temperature |
| Number | Substrate | Substrate | Substrate | on |
| of Insulating | Temperature | Temperature | Temperature | Recovery |
| Plates | (° C.) | (° C.) | (° C.) | Means (° C.) |
| 0 (nil) | 220 | 240 | 300 | 420 |
| 1 | 220 | 220 | 250 | 360 |
| 2 | 220 | 220 | 220 | 260 |
| 3 | 220 | 220 | 220 | 210 |

1.-55. (canceled)

56. A processing apparatus comprising:
(a) a processing chamber for processing a substrate or a film therein;
(b) an exhaust means for exhausting a gas from the processing chamber;
(c) a conductance adjusting valve for controlling a pressure of the processing chamber; and
(d) a trap comprising a high-melting metal filament provided in an exhaust path connecting the processing chamber and the conductance adjusting valve;
wherein the trap causes a chemical reaction in at least one of a non-reacted gas and a by-product exhausted from the processing chamber and a mean velocity of the gas at the trap is higher than a mean velocity of the gas in the processing chamber.

57. The processing apparatus according to claim 56, wherein a wall of the trap has a double structure, and the trap and the wall of the trap are detachable.

58. The processing apparatus according to claim 56, wherein the high-melting metal filament comprises at least one of the tungsten, molybdenum, and rhenium.

59. The processing apparatus according to claim 57, wherein the high-melting metal filament comprises at least one of tungsten, molybdenum and rhenium.
